(19) United States
(12) Patent Application Publication
(10) Pub. No.: US 2025/0324834 A1
(43) Pub. Date: Oct. 16, 2025

(54) Wiring Substrate and Method for Manufacturing the Same, Light-Emitting Substrate and Display Apparatus

(71) Applicants: BEIJING BOE TECHNOLOGY DEVELOPMENT CO., LTD., Beijing (CN); BOE TECHNOLOGY GROUP CO., LTD., Chaoyang District, Beijing (CN)

(72) Inventors: Mengping Li, Beijing (CN); Jiaxiang Zhang, Beijing (CN); Qi Qi, Beijing (CN); Zhanfeng Cao, Beijing (CN)

(21) Appl. No.: 18/881,659

(22) PCT Filed: Dec. 18, 2023
(86) PCT No.: PCT/CN2023/139657

§ 371 Date: Jan. 6, 2025

(51) Int. Cl. H10H 29/49; G02F 1/1335; G02F 1/13357; H10H 29/01

(52) U.S. Cl. CPC H10H 29/49; H10H 29/012; G02F 1/133603; G02F 1/133612

(57) ABSTRACT

A wiring substrate and a method for manufacturing the same, a light-emitting substrate and a display apparatus are provided. The wiring substrate includes a substrate, a plurality of signal lines and a plurality of dummy conductive patterns. The substrate has a first surface. The plurality of signal lines are located on the first surface. The plurality of signal lines are arranged at intervals in a first direction and extend in a second direction, and the first direction intersects the second direction. The plurality of dummy conductive patterns are located on the first surface. At least part of the plurality of dummy conductive patterns are located in a same layer as the plurality of signal lines. A dummy conductive pattern is disposed between two adjacent signal lines, and the dummy conductive pattern is insulated from the two adjacent signal lines.

### CROSS-REFERENCE TO RELATED APPLICATION

This application is the United States national phase of International Patent Application No. PCT/CN2023/139657, filed Dec. 18, 2023, the disclosure of which is hereby incorporated by reference in its entirety.

### BACKGROUND OF THE INVENTION

### Field of the Invention

The present disclosure relates to the field of display technologies, and in particular, to a wiring substrate and a method for manufacturing the same, a light-emitting substrate and a display apparatus.

### Description of Related Art

Light-emitting diodes (LEDs), sub-millimeter light-emitting diodes (mini LEDs) or micro light-emitting diodes (micro LEDs) are active self-luminous components. A size of the mini LED is approximately in a range of 80 μm to 500 μm, inclusive; and a size of the micro LED is approximately less than 80 μm.

The above various of LEDs may be applied in backlighting and direct display. In a case of being applied in backlighting, a large number of densely distributed LEDs may achieve local dimming in a small range. Compared with traditional backlight design, better brightness uniformity and higher color contrast may be realized within a smaller mixing distance, thereby achieving ultra-thin, high color rendering and power saving of terminal products.

### SUMMARY OF THE INVENTION

In an aspect, a wiring substrate is provided. The wiring substrate includes a substrate, a plurality of signal lines and a plurality of dummy conductive patterns. The substrate has a first surface. The plurality of signal lines are located on the first surface. The plurality of signal lines are arranged at intervals in a first direction and extend in a second direction; and the first direction intersects the second direction. The plurality of dummy conductive patterns are located on the first surface. At least part of the plurality of dummy conductive patterns are located in a same layer as the plurality of signal lines. A dummy conductive pattern is disposed between two adjacent signal lines, and the dummy conductive pattern is insulated from the two adjacent signal lines.

In some embodiments, the wiring substrate further includes a plurality of pad units and a plurality of connection lines. The plurality of pad units are located on the first surface, and a pad unit includes multiple device pad groups. The plurality of connection lines are located on the first surface. The connection lines include first connection lines and second connection lines, the pad unit and a signal line are configured to be connected by a first connection line, and the multiple device pad groups in a same pad unit are configured to be connected by a second connection line. The plurality of connection lines are arranged in a plurality of columns. In the second direction, the dummy conductive pattern is disposed between two adjacent connection lines in a same column, and the dummy conductive pattern is insulated from the connection lines.

In some embodiments, the multiple device pad groups in the pad unit are arranged in an array and connected in series and/or in parallel.

In some embodiments, the wiring substrate further includes a plurality of driver chips disposed on the first surface, and a driver chip is configured to control at least one pad unit.

In some embodiments, the second connection line includes a plurality of connection sub-segments, a connection sub-segment is located between two adjacent device pad groups, and the connection sub-segment connects the two adjacent device pad groups. At least part of the dummy conductive pattern is located in a region surrounded by a same second connection line.

In some embodiments, the plurality of connection sub-segments include a plurality of first connection sub-segments and a second connection sub-segment located between two adjacent first connection sub-segments. The first connection sub-segments extend in the second direction, and the second connection sub-segment extends in the first direction. In the first direction, the dummy conductive pattern is located between the two adjacent first connection sub-segments of a same second connection line; and/or in the second direction, the dummy conductive pattern is located between the second connection sub-segment and the first connection line that are adjacent.

In some embodiments, the dummy conductive pattern is located between the two adjacent first connection sub-segments of the same second connection line in the first direction includes at least one first dummy conductive portion; and the first dummy conductive portion extends in the second direction. In the first direction, the two adjacent first connection sub-segments and the first dummy conductive portion are arranged at equal intervals.

In some embodiments, in the first direction, projections of the two adjacent first connection sub-segments and the first dummy conductive portion in the second direction at least partially overlap.

In some embodiments, in the second direction, in a case where the dummy conductive pattern is located between the second connection sub-segment and the first connection line that are adjacent, the second connection sub-segment and the first connection line that are adjacent belong to two adjacent connection lines. The dummy conductive pattern located between the second connection sub-segment and the first connection line that are adjacent includes at least one second dummy conductive portion; and the second dummy conductive portion extends in the second direction. In the first direction, the two adjacent signal lines and the second dummy conductive portion are arranged at equal intervals.

In some embodiments, projections of the second dummy conductive portion and the first connection sub-segments in the second direction are at least partially staggered.

In some embodiments, the dummy conductive pattern includes at least one third dummy conductive portion. The third dummy conductive portion extends in the first direction; the third dummy conductive portion is located between the second connection sub-segment and the first connection line that are adjacent; and the second connection sub-segment and the first connection line that are adjacent belong to two adjacent connection lines in the second direction. In the second direction, the second connection sub-segment and the first connection line that are adjacent, and the third dummy conductive portion are arranged at equal intervals.

In some embodiments, the dummy conductive pattern includes at least one fourth dummy conductive portion. The fourth dummy conductive portion extends in the first direction; the fourth dummy conductive portion is located between the second connection sub-segment and the first connection line that are adjacent; and the second connection sub-segment and the first connection line that are adjacent belong to a same connection line. In the second direction, the second connection sub-segment and the first connection line, and the fourth dummy conductive portion are arranged at equal intervals.

In some embodiments, the dummy conductive pattern includes at least one dummy conductive portion; and the plurality of signal lines, the plurality of connection lines and the dummy conductive portion are disposed in a same layer.

In some embodiments, in the second direction, in a case where a plurality of dummy conductive portions are disposed between two adjacent connection lines, at least two dummy conductive portions are connected.

In some embodiments, the wiring substrate has a peripheral region, and the peripheral region includes a first blank region and a second blank region. The wiring substrate further includes a plurality of alignment patterns located on the first surface, and at least part of the plurality of alignment patterns are located in the first blank region and the second blank region.

In some embodiments, the wiring substrate further has a display region, and the peripheral region is located on at least one side of the display region. The wiring substrate further includes an annular electrostatic release line located on the first surface. The annular electrostatic release line includes a first electrostatic release sub-segment, a second electrostatic release sub-segment and a third electrostatic release sub-segment that are electrically connected in sequence. The first electrostatic release sub-segment and the third electrostatic release sub-segment are located at two opposite sides of the display region in the first direction, and the second electrostatic release sub-segment is located on a side of the display region away from the peripheral region.

In another aspect, a method for manufacturing a wiring substrate is provided. The method includes: providing a substrate, the substrate having a first surface; and forming a plurality of signal lines and a plurality of dummy conductive patterns simultaneously on the first surface using a same patterning process, wherein the plurality of signal lines are arranged at intervals in a first direction and extend in a second direction, the first direction intersects the second direction; a dummy conductive pattern is disposed between two adjacent signal lines, and the dummy conductive pattern is insulated from the two adjacent signal lines.

In some embodiments, forming the plurality of signal lines and the plurality of dummy conductive patterns simultaneously on the first surface using the same patterning process, includes: forming a seed layer on the first surface; forming a photoresist layer on the seed layer, wherein the photoresist layer has a plurality of first openings and a plurality of second openings, the first openings correspond to signal lines to be formed, and the second openings correspond to dummy conductive patterns to be formed; and forming the signal lines in the first openings and the dummy conductive patterns in the second openings simultaneously using an electroplating process.

In yet another aspect, a light-emitting substrate is provided. The light-emitting substrate includes a wiring substrate and a plurality of light-emitting devices. The wiring substrate is the wiring substrate as described in any of the above embodiments. The plurality of light-emitting devices are disposed on the wiring substrate.

In yet another aspect, a display apparatus is provided. The display apparatus includes the light-emitting substrate and a display panel. The light-emitting substrate is the light-emitting substrate as described in any of the above embodiments. The display panel is located on a light-exit side of the light-emitting substrate.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art may obtain other drawings according to these drawings. In addition, the accompanying drawings to be described below may be regarded as schematic diagrams, but are not limitations on an actual size of a product and a method to which the embodiments of the present disclosure relate.

FIG. 1 is a structural diagram of a display apparatus, in accordance with some embodiments;

FIG. 2 is a structural diagram of another display apparatus, in accordance with some embodiments;

FIG. 3 is a structural diagram of yet another display apparatus, in accordance with some embodiments;

FIG. 4 is a top view of a wiring substrate, in accordance with some embodiments;

FIG. 5 is a top view of another wiring substrate, in accordance with some embodiments;

FIG. 6 is a structural diagram of a wiring substrate, in accordance with some embodiments;

FIG. 7 is a structural diagram of another wiring substrate, in accordance with some embodiments;

FIG. 8 is a top view of yet another wiring substrate, in accordance with some embodiments;

FIG. 9 is a top view of yet another wiring substrate, in accordance with some embodiments;

FIG. 10 is a top view of yet another wiring substrate, in accordance with some embodiments;

FIG. 11 is a top view of yet another wiring substrate, in accordance with some embodiments;

FIG. 12 is a top view of yet another wiring substrate, in accordance with some embodiments;

FIG. 13 is a top view of yet another wiring substrate, in accordance with some embodiments;

FIG. 14 is a top view of yet another wiring substrate, in accordance with some embodiments;

FIG. 15 is a top view of yet another wiring substrate, in accordance with some embodiments;

FIG. 16 is a partial enlarged view of a wiring substrate, in accordance with some embodiments;

FIG. 17 is a top view of yet another wiring substrate, in accordance with some embodiments;

FIG. 18 is a partial enlarged view of another wiring substrate, in accordance with some embodiments;

FIG. 19 is a partial enlarged view of yet another wiring substrate, in accordance with some embodiments;

FIG. 20 is a top view of yet another wiring substrate, in accordance with some embodiments;

FIG. 21 is a partial enlarged view of yet another wiring substrate, in accordance with some embodiments;

FIG. 22 is a partial enlarged view of yet another wiring substrate, in accordance with some embodiments;

FIG. 23 is a top view of yet another wiring substrate, in accordance with some embodiments;

FIG. 24 is a top view of yet another wiring substrate, in accordance with some embodiments;

FIG. 25 is a top view of yet another wiring substrate, in accordance with some embodiments;

FIG. 26 is a top view of yet another wiring substrate, in accordance with some embodiments;

FIG. 27 is a top view of yet another wiring substrate, in accordance with some embodiments;

FIG. 28 is a top view of yet another wiring substrate, in accordance with some embodiments;

FIG. 29 is a top view of yet another wiring substrate, in accordance with some embodiments;

FIG. 30 is a partial enlarged view of yet another wiring substrate, in accordance with some embodiments;

FIG. 31 is a partial enlarged view of yet another wiring substrate, in accordance with some embodiments;

FIG. 32 is a partial enlarged view of yet another wiring substrate, in accordance with some embodiments;

FIG. 33 is a partial enlarged view of yet another wiring substrate, in accordance with some embodiments;

FIG. 34 is a partial enlarged view of yet another wiring substrate, in accordance with some embodiments;

FIG. 35 is a partial enlarged view of yet another wiring substrate, in accordance with some embodiments;

FIG. 36 is a partial enlarged view of yet another wiring substrate, in accordance with some embodiments;

FIG. 37 is a partial enlarged view of yet another wiring substrate, in accordance with some embodiments;

FIG. 38 is a partial enlarged view of yet another wiring substrate, in accordance with some embodiments;

FIG. 39 is a partial enlarged view of yet another wiring substrate, in accordance with some embodiments;

FIG. 40 is a partial enlarged view of yet another wiring substrate, in accordance with some embodiments;

FIG. 41 is a top view of yet another wiring substrate, in accordance with some embodiments;

FIG. 42 is a top view of yet another wiring substrate, in accordance with some embodiments;

FIG. 43 is a top view of yet another wiring substrate, in accordance with some embodiments;

FIG. 44 is a top view of yet another wiring substrate, in accordance with some embodiments;

FIG. 45 is a top view of yet another wiring substrate, in accordance with some embodiments;

FIG. 46 is a top view of yet another wiring substrate, in accordance with some embodiments;

FIG. 47 is a partial enlarged view of yet another wiring substrate, in accordance with some embodiments;

FIG. 48 is a partial enlarged view of yet another wiring substrate, in accordance with some embodiments;

FIG. 49 is a top view of yet another wiring substrate, in accordance with some embodiments;

FIG. 50 is a top view of yet another wiring substrate, in accordance with some embodiments;

FIG. 51 is a partial enlarged view of yet another wiring substrate, in accordance with some embodiments;

FIG. 52 is a partial enlarged view of a wiring substrate in the related art;

FIG. 53 is a partial enlarged view of yet another wiring substrate, in accordance with some embodiments;

FIGS. 54A to 54N are each a comparison chart of the first experiment, in accordance with some embodiments;

FIG. 55 is a line chart of the first experiment, in accordance with some embodiments;

FIGS. 56A to 56N are each a comparison chart of the second experiment, in accordance with some embodiments;

FIG. 57 is a line chart of the second experiment, in accordance with some embodiments;

FIG. 58 is a flow chart of a method for manufacturing a wiring substrate, in accordance with some embodiments;

FIGS. 59A to 59B are each a diagram showing a structure corresponding to each step in a method for manufacturing a wiring substrate, in accordance with some embodiments;

FIG. 60 is a flow chart of another method for manufacturing a wiring substrate, in accordance with some embodiments;

FIG. 61 is a diagram showing another structure corresponding to each step in a method for manufacturing a wiring substrate, in accordance with some embodiments;

FIGS. 62A to 62B are each a diagram showing another structure corresponding to each step in a method for manufacturing a wiring substrate, in accordance with some embodiments;

FIG. 63 is a diagram showing another structure corresponding to each step in a method for manufacturing a wiring substrate, in accordance with some embodiments;

FIG. 64 is a diagram showing another structure corresponding to each step in a method for manufacturing a wiring substrate, in accordance with some embodiments;

FIGS. 65A to 65C are each a diagram showing another structure corresponding to each step in a method for manufacturing a wiring substrate, in accordance with some embodiments;

FIG. 66 is a structural diagram of a motherboard substrate, in accordance with some embodiments;

FIG. 67 is a structural diagram of a mask, in accordance with some embodiments;

FIG. 68 is a partial enlarged view of yet another wiring substrate, in accordance with some embodiments;

FIG. 69 is a structural diagram of a first alignment pattern and a dummy conductive block, in accordance with some embodiments;

FIG. 70 is a structural diagram of a compensation alignment pattern and a dummy conductive block, in accordance with some embodiments;

FIG. 71 is a structural diagram of a cutting alignment pattern and a dummy conductive block, in accordance with some embodiments;

FIG. 72 is a structural diagram of a second alignment pattern and a dummy conductive block, in accordance with some embodiments;

FIG. 73 is a structural diagram of a baffle alignment pattern and a dummy conductive block, in accordance with some embodiments;

FIG. 74 is a structural diagram of an alignment pattern, in accordance with some embodiments;

FIG. 75 is a structural diagram of another alignment pattern, in accordance with some embodiments;

FIG. 76 is a structural diagram of yet another alignment pattern, in accordance with some embodiments;

FIG. 77 is a structural diagram during processing of a wiring substrate, in accordance with some embodiments;

FIG. 78 is a structural diagram during processing of another wiring substrate, in accordance with some embodiments;

FIG. 79 is a structural diagram during processing of yet another wiring substrate, in accordance with some embodiments;

FIG. 80 is a structural diagram during processing of yet another wiring substrate, in accordance with some embodiments;

FIG. 81 is a structural diagram during processing of yet another wiring substrate, in accordance with some embodiments;

FIG. 82 is a structural diagram during processing of yet another wiring substrate, in accordance with some embodiments;

FIG. 83 is a structural diagram during processing of yet another wiring substrate, in accordance with some embodiments;

FIG. 84 is a partial enlarged view of yet another wiring substrate, in accordance with some embodiments;

FIG. 85 is a structural diagram of the third experiment, in accordance with some embodiments;

FIG. 86 is a structural diagram of the third experiment, in accordance with some embodiments;

FIG. 87 is a bar chart, in accordance with some embodiments; and

FIG. 88 is another bar chart, in accordance with some embodiments.

### DESCRIPTION OF THE INVENTION

Technical solutions in some embodiments of the present disclosure will be described clearly and completely with reference to the accompanying drawings below. Obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed as open and inclusive, i.e., “including, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, features defined with “first” or “second” may explicitly or implicitly include one or more of the features. In the description of the embodiments of the present disclosure, the term “a plurality of” or “the plurality of” means two or more unless otherwise specified.

In the description of some embodiments, the expressions “coupled” and “connected” and derivatives thereof may be used. The term “connection” should be understood in a broad sense. For example, the “connection” may be a fixed connection, a detachable connection, or of an integrated structure; it may be a direct connection or an indirect connection by an intermediate medium.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

In addition, the use of the phrase “based on” is meant to be open and inclusive, since a process, step, calculation or other action that is “based on” one or more of the stated conditions or values may, in practice, be based on additional conditions or values exceeding those stated.

The term such as “parallel”, “perpendicular” or “equal” as used herein includes a stated condition and a condition similar to the stated condition. A range of the similar condition is within an acceptable range of deviation. The acceptable range of deviation is determined by a person of ordinary skill in the art in view of measurement in question and errors associated with the measurement of a particular quantity (i.e., limitations of the measurement system). For example, the term “parallel” includes absolute parallelism and approximate parallelism, and an acceptable range of deviation of the approximate parallelism may be a deviation within 5°; the term “perpendicular” includes absolute perpendicularity and approximate perpendicularity, and an acceptable range of deviation of the approximate perpendicularity may also be a deviation within 5°; and the term “equal” includes absolute equality and approximate equality, and an acceptable range of deviation of the approximate equality may be a difference between two equals being less than or equal to 5% of either of the two equals.

Exemplary embodiments are described herein with reference to sectional views and/or plane views as idealized exemplary drawings. In the accompanying drawings, thicknesses of layers and sizes of regions are enlarged for clarity. Variations in shapes relative to the accompanying drawings due to, for example, manufacturing technologies and/or tolerances may be envisaged. Therefore, the exemplary embodiments should not be construed to be limited to the shapes of regions shown herein, but to include deviations in the shapes due to, for example, manufacturing. For example, an etched region shown in a rectangular shape generally has a feature of being curved. Therefore, the regions shown in the accompanying drawings are schematic in nature, and their shapes are not intended to show actual shapes of the regions in an apparatus, and are not intended to limit the scope of the exemplary embodiments.

Some embodiments of the present disclosure provide a display apparatus. The display apparatus may be any apparatus that displays images whether in motion (such as a video) or fixed (such as a still image), and regardless of text or image. More specifically, it is expected that the display apparatus in the embodiments may be implemented in or associated with a variety of electronic devices. The variety of electronic devices may include (but are not limit to), for example, mobile telephones, wireless devices, personal digital assistants (PDAs), hand-held or portable computers, global positioning system (GPS) receivers/navigators, cameras, MPEG-4 Part 14 (MP4) video players, video cameras, game consoles, watches, clocks, calculators, TV monitors, flat-panel displays, computer monitors, car displays (e.g., odometer displays), navigators, cockpit controllers and/or displays, camera view displays (e.g., display of rear view camera in vehicles), electronic photos, electronic billboards or signs, projectors, architectural structures, packaging and aesthetic structures (e.g., displays for displaying an image of a piece of jewelry), etc.

For example, the display apparatus is a liquid crystal display (LCD).

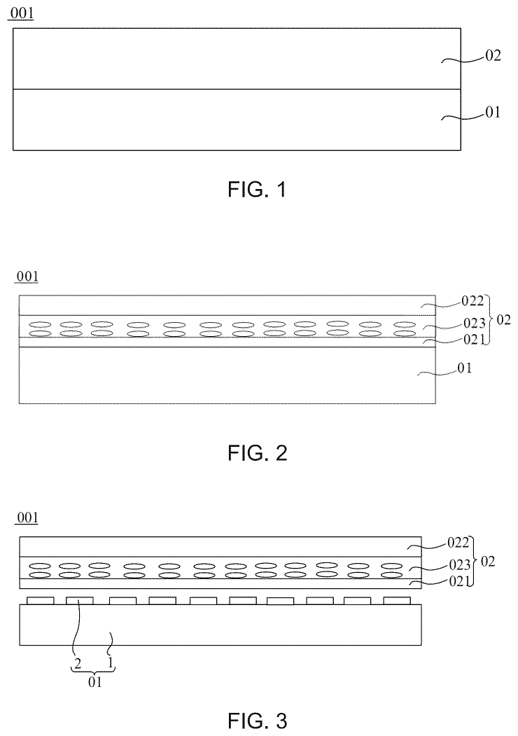

In this case, as shown in FIG. 1, in some embodiments, the display apparatus 001 includes a light-emitting substrate 01 and a display panel 02. The display panel 02 is located on a light-exit side of the light-emitting substrate 01.

The light-emitting substrate 01 is used to constitute a backlight module and provide backlight for the display panel 02. For example, the backlight provided by the light-emitting substrate 01 is white light or blue light, which is not specifically limited in the present disclosure. For example, the light-exit side of the light-emitting substrate 01 refers to a side from which the light-emitting substrate 01 emits light.

The display panel 02 is used to display images. For example, as shown in FIG. 2, the display panel 02 includes an array substrate 021, a color film substrate 022 and a liquid crystal layer 023. The array substrate 021 is located on the light-exit side of the light-emitting substrate 01. The color film substrate 022 is located on a side of the array substrate 021 away from the light-emitting substrate 01. The liquid crystal layer 023 is located between the array substrate 021 and the color film substrate 022.

For example, the array substrate 021 may include a plurality of transistors and a plurality of pixel electrodes. The plurality of transistors may be arranged in an array. The plurality of transistors and the plurality of pixel electrodes are electrically connected in one-to-one correspondence, and the transistors are used to transmit pixel voltages to the corresponding pixel electrodes.

In addition, the color film substrate 022 may include a variety of color filters. For example, in a case where the backlight provided by the light-emitting substrate 01 is white light, the color filters may include red filters, green filters and blue filters. The red filter may only transmit red light in the incident light, the green filter may only transmit green light in the incident light, and the blue filter may only transmit blue light in the incident light. As another example, in a case where the backlight provided by the light-emitting substrate 01 is blue light, the color filters may include red filters and green filters.

The liquid crystal layer 023 includes a plurality of liquid crystal molecules. For example, an electric field may be generated between a pixel electrode and a common electrode, and liquid crystal molecules may deflect due to action of the electric field.

For example, the display panel 02 further includes the common electrode. The common electrode may receive a common voltage. The common electrode may be provided in the color film substrate 022. Alternatively, the common electrode may be provided in the array substrate 021. The specific limitation is not made in the present disclosure.

With the above provision, during operation of the display apparatus 001, the light-emitting substrate 01 may emit light, and the light will sequentially pass through the array substrate 021, the liquid crystal layer 023 and the color film substrate 022, thereby achieving image display.

Specifically, when light reaches the liquid crystal layer 023, the liquid crystal molecules will deflect due to the action of the electric field generated between the pixel electrode and the common electrode, so as to change the amount of light passing through the liquid crystal molecules, so that the light exiting through the liquid crystal molecules reaches a preset brightness. Then, when the light passes through the color film substrate 022, the light will pass through filters of different colors, and light of different colors, such as red light, blue light and green light, will exit. The lights of various colors cooperate with each other to achieve display.

In some embodiments, as shown in FIG. 3, the light-emitting substrate 01 includes a wiring substrate 1 and a plurality of light-emitting devices 2, and the plurality of light-emitting devices 2 are disposed on the wiring substrate 1. The wiring substrate 1 provides circuit connection for the light-emitting devices 2 when carrying the light-emitting devices 2 as a carrier of the light-emitting devices 2, so as to ensure that the light-emitting devices 2 can work normally.

The light-emitting devices 2 may be micro LEDs or mini LEDs.

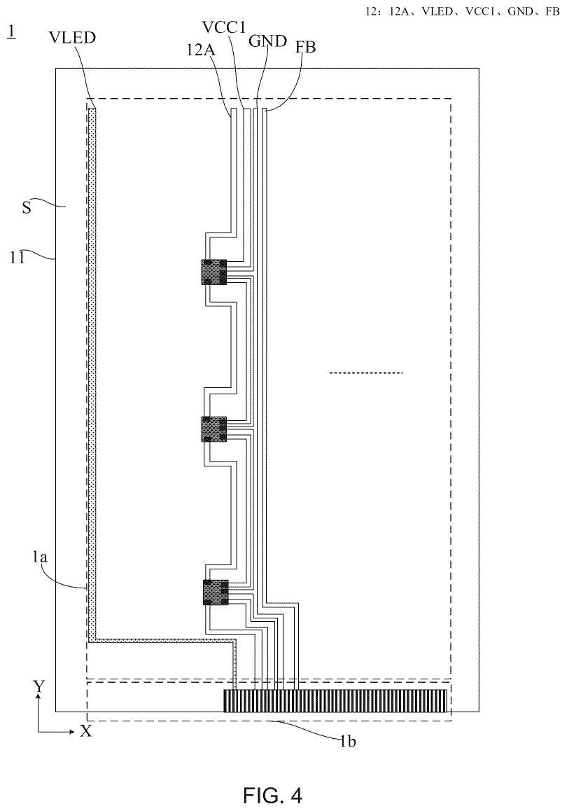

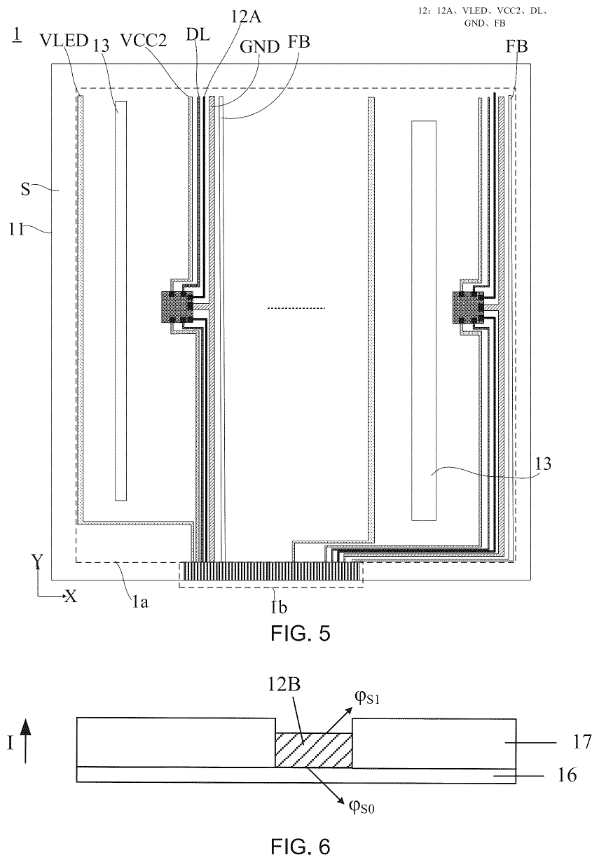

In some embodiments, as shown in FIGS. 4 and 5, the wiring substrate 01 includes a substrate 11 and a plurality of signal lines 12.

In some examples, the substrate 11 may be a substrate 11 made of an inorganic material, or a substrate 11 made of an organic material, or a substrate 11 formed by stacking and compositing organic and inorganic materials.

For example, the material of the substrate 11 is a glass material such as soda-lime glass, quartz glass or sapphire glass, or a metal material such as stainless steel, aluminum or nickel.

For example, the material of the substrate 11 may alternatively be polymethyl methacrylate (PMMA), polyvinyl alcohol (PVA), polyvinyl phenol (PVP), polyether sulfone (PES), polyimide, polyamide, polyacetal, polycarbonate (PC), polyethylene terephthalate (PET), polyethylene naphthalate (PEN) or a combination thereof.

The substrate 11 has a first surface S. The plurality of signal lines 12 are located on the first surface S. The plurality of signal lines 12 are arranged at intervals in a first direction X, and all extend in a second direction Y. The first direction X and the second direction Y intersect. The light-emitting device 2 is electrically connected (e.g., indirectly electrically connected) to signal lines 12, and the signal lines 12 can provide corresponding electrical signals to the light-emitting device 2.

An included angle between the first direction X and the second direction Y may be 80°, 85°, 90° or 95°.

In some examples, as shown in FIG. 4, the wiring substrate 1 includes a display region 1a and a peripheral region 1b. The peripheral region 1b is located on a side of the display region 1a, and the peripheral region 1b and the display region 1a are arranged in the second direction Y. The signal lines 12 extend from the display region 1a to the peripheral region 1b.

The shape of the display region 1a may vary. For example, the shape of the display region 1a is a rectangle or a circle. For convenience of illustration, the description is made below by taking an example where the display region 1a is in a rectangle shape.

It can be understood that the wiring substrate 1 includes signal lines for transmitting different types of signals. As shown in FIG. 4, in some wiring substrates 1, two adjacent signal lines 12 may be a first signal line VLED and an addressing signal line 12A; alternatively, two adjacent signal lines 12 may be an addressing signal line 12A and a first voltage line VCC1; alternatively, two adjacent signal lines 12 may be a first voltage line VCC1 and a second signal line GND; alternatively, two adjacent signal lines 12 may be a second signal line GND and a feedback signal line FB.

As shown in FIG. 5, in some other wiring substrates 1, two adjacent signal lines 12 may be a first signal line VLED and a second voltage line VCC2; alternatively, two adjacent signal lines 12 may be a second voltage line VCC2 and a data signal line DL; alternatively, two adjacent signal lines 12 may be a data signal line DL and an addressing signal line 12A; alternatively, two adjacent signal lines 12 may be an addressing signal line 12A and a second signal line GND; alternatively, two adjacent signal lines 12 may be a second signal line GND and a feedback signal line FB.

When an electric signal is transmitted by a signal line 12, the electric signal may have loss due to a resistance of the signal line 12. The higher the resistance of the signal line 12, the greater the loss of the electric signal passing through per unit length of the signal line 12, and the greater the power consumption. Therefore, during actual manufacture, it is necessary to reduce the resistance of the signal line 12 as much as possible. In some examples, the material of the signal line 12 may include copper, silver, aluminum, or the like. The calculation formula of the resistance is as following:

$$R = \frac{ρ l}{s 1} . \qquad ( 1 )$$

Where R represents a resistance of the signal line 12; ρ represents a resistivity of the material of the signal line 12; l represents a length of the signal line 12; and s1 represents a cross-sectional area of the signal line 12.

It can be seen according to the formula that the resistance of the signal line 12 is related to the resistivity of the material of the signal line 12, the length of the signal line 12 and the cross-sectional area of the signal line 12 in a direction perpendicular to a length direction of the signal line 12. After a product size is determined, the length of the signal line 12 is determined accordingly. After the material used for the signal line 12 is determined, the resistivity of the material of the signal line 12 is also a constant. Therefore, the only variable that affects the resistance of the signal line 12 is the cross-sectional area of the signal line 12. The larger the cross-sectional area of the signal line 12, the lower the resistance of the signal line 12; and the smaller the cross-sectional area of the signal line 12, the higher the resistance of the signal line 12.

The cross-sectional area of the signal line 12 is related to a line width and a line thickness of the signal line 12. Since wiring space on the wiring substrate 1 is limited and there is a minimum safe distance between two adjacent signal lines 12, the line width of the signal line 12 is difficult to change. Therefore, the variable that affects the resistance of the signal line 12 is basically the line thickness of the signal line 12, that is, the thickness of the signal line 12. The larger the thickness of the signal line 12, the lower the resistance of the signal line 12; and the smaller the thickness of the signal line 12, the higher the resistance of the signal line 12.

Therefore, it can be seen combined with the above analysis that when designing and forming the signal line 12, it is necessary to increase the thickness of the signal line 12 as much as possible to reduce the resistance of the signal line 12, so as to reduce the signal loss and reduce the power loss.

The signal lines 12 may be formed by various processes.

In some cases, a first copper layer may be formed on the substrate 11 by sputtering, and then a photoresist is applied by coating on the first copper layer to form a first photoresist layer. The first photoresist layer is then exposed and developed to form a plurality of first openings in the first photoresist layer. The developed first photoresist layer is then used as a mask to etch and remove portions of the first copper layer corresponding to the first openings, and then the first photoresist layer is peeled off to form the signal lines 12. However, the thickness of the signal lines 12 formed by sputtering is generally less than or equal to 3.6 μm. Therefore, it cannot well meet the requirement of high thickness of the signal lines 12, and it is difficult to meet the requirement of low resistance of the signal line 12.

In some other cases, the signal lines 12 may be formed on the substrate 11 by electroplating. The electroplating process is a technology that obtains a metal layer on a substrate by reducing metal ions at a cathode due to action of an external electric field through migration of positive and negative ions in an electrolyte solution containing metal ions. For example, in a case where the metal ions in the electrolyte solution are copper ions, the obtained metal layer is a copper film layer. The electrolyte solution is stored in a receiving tank of an electroplating equipment. The receiving tank is also provided with an anode structure therein. When an electroplating process is carried out, a carrier loaded with the substrate is placed in the receiving tank, and the carrier and the anode structure are provided opposite to each other. The carrier is connected to a negative output terminal of the power supply, and the negative output terminal of the power supply is electrically connected to a seed layer on the substrate. The anode structure is connected to a positive output terminal of the power supply, so that an electric field is generated between the anode structure and the substrate. Furthermore, the metal ions in the electrolyte adhere to the substrate to form a metal layer with a specific thickness. The electroplating process may produce the signal lines 12 with a wide optional thickness range, for example, greater than or equal to 6 μm. Therefore, it may well meet the requirement of high thickness of the signal lines 12, so as to ensure the requirement of low resistance of the signal lines 12.

In the specific implementation of the electroplating process, there are two routes.

In the first route: a second copper layer (also called a seed layer) is formed on the substrate 11 by sputtering, and a thickness of the second copper layer is in a range of 0.1 μm to 0.3 μm, inclusive; then, the substrate 11 is placed in an electrolyte solution, and the second copper layer is clamped by a clamp to energize the second copper layer, so as to electroplate to deposit a third copper layer on the second copper layer, a thickness of the third copper layer is greater than or equal to 6 μm; then, a photoresist is applied by coating on the third copper layer to form a second photoresist layer, and the second photoresist layer is exposed and developed to form a plurality of second openings in the second photoresist layer; then, the developed second photoresist layer is used as a mask to etch portions of the second copper layer and the third copper layer corresponding to the second openings, and then, the second photoresist layer is peeled off to form the signal lines 12. However, since a sum of the thicknesses of the second copper layer and the thicknesses of the third copper layer is relatively large, it takes a long time to etch the second copper layer and the third copper layer, resulting in an excessively large etching bias and reducing the production capacity, which makes it difficult to meet mass production requirements. Therefore, a high-speed etching solution is generally used to etch the second copper layer and the third copper layer. However, since the high-speed etching solution is expensive, the etching cost will increase.

In the second route: a seed layer 16 is formed on the substrate 11 by sputtering, the seed layer 16 may have a stacked structure consisting of a molybdenum niobium (MoNb) layer and a third copper layer, and the molybdenum niobium layer is located between the third copper layer and the substrate 11, where a thickness of the molybdenum niobium layer is about 300 angstroms, and a thickness of the third copper layer is in a range of 0.3 μm to 1.0 μm, inclusive; then, a photoresist is applied by coating on the seed layer 16 to form a third photoresist layer, and the third photoresist layer is exposed and developed to form a plurality of openings (e.g., the first openings 171 hereinafter) in the third photoresist layer; then, copper (with a thickness greater than or equal to 6 μm) is electroplated in the first openings 171 to form routing sub-patterns 12Z in the first openings 171; and then, the third photoresist layer is stripped off, and the seed layer 16 is etched using the routing sub-patterns 12Z as a mask, so that the routing sub-patterns 12Z and portions of the seed layer 16 below the routing sub-patterns 12Z form the signal lines 12.

Specifically, the seed layer 16 is clamped by a carrier to energize negative electricity to the seed layer 16; and the substrate 11 is placed in the electrolyte solution in the receiving tank, and positive electricity is energized to a copper block in the electrolyte solution. Thus, copper ions of the metal copper block will undergo an oxidation reaction to be converted into copper ions and enter the electrolyte solution. Due to action of an electric field between the cathode and the anode, the copper ions move into the first openings 171 and are reduced to copper simple substance to be deposited in the first openings 171.

In this process route, an object of the etching process is the seed layer 16, and the thickness of the seed layer 16 is much smaller than 6 μm. Therefore, the etching cost and etching bias may be reduced, and thus the second process route may effectively reduce the cost compared with the first process route.

Further, a thickness uniformity of the signal lines 12 in the second process route of electroplating is studied in two aspects.

In an aspect, during electroplating, areas of bottom surfaces (surfaces of the signal lines to be plated opposite to the first surface S of the substrate 11) of different signal lines to be plated may be different due to line widths of the signal lines to be plated and other factors. Therefore, in different regions with unit areas of the first surface S, ratios of areas of the bottom surfaces of the signal lines to be plated to the unit areas are not the same. In some regions with unit areas, areas of bottom surfaces of signal lines to be plated account for large proportions, while in some regions with unit areas, areas of bottom surfaces of signal lines to be plated account for small proportions. In this way, during electroplating, the relationship of the current density, the current and the cross-sectional area of the signal line to be plated in the direction perpendicular to the current direction is as following:

$$J = {I}_{1} / {s}_{2} . \qquad ( 2 )$$

Where J represents a current density; I₁ represents a current along a thickness direction of the signal line to be plated, and a value of I₁ may be controlled by an equipment, that is, I₁ may have a fixed value; s₂ represents a cross-sectional area (an area of the bottom surface of the signal line to be plated) of the signal line to be plated in a direction perpendicular to a thickness direction thereof. The signal line to be plated refers to an intermediate state presented by the signal line 12 during forming the signal line 12 with a specific thickness in a specific region by electroplating.

It can be seen according to the above relationship that during electroplating, the larger the area of the bottom surface of the signal line to be plated per region with a unit area, the less the current density on the signal line to be plated. Similarly, the smaller the area of the bottom surface of the signal line to be plated per region with a unit area, the greater the current density on the signal line to be plated. The current density is directly proportional to an efficiency of electroplating. Therefore, the larger the current density, the higher the electroplating efficiency, and the thicker the signal line 12; and the smaller the current density, the lower the electroplating efficiency, and the thinner the signal line 12.

In summary, a difference of areas of bottom surfaces of the signal lines to be plated in different regions with unit areas will affect a difference of current densities on the signal lines to be plated in different regions with unit areas, and affect the thickness uniformity between the signal lines 12 finally formed in different regions with unit areas.

In another aspect, the inventors cite the Butler-Volmer equation to assist in verifying that during electroplating, the current density on the signal line to be plated will be affected by the proportion of the area of the bottom surface of the signal line to be plated per region with a unit area, and it is concluded that the difference of the areas of the bottom surfaces of the signal lines to be plated in different regions with unit areas will affect the thickness uniformity of the signal lines 12.

Specifically, the Butler-Volmer equation is as following:

$${i}_{loc} = {i}_{0} [ exp ( \frac{{α}_{a} z F η}{RT} ) - exp ( - \frac{{α}_{c} z F η}{RT} ) ] ; \\ or \qquad ( 3 )$$

$${i}_{loc} = {i}_{0} [ exp ( \frac{{α}_{a} z F ( E - {E}_{eq} )}{RT} ) - exp ( - \frac{{α}_{c} z F ( E - {E}_{eq} )}{RT} ) ] . \qquad ( 4 )$$

According to the formula (3) and the formula (4), a formula (5) can be obtained:

$$η = E - {E}_{eq} . \qquad ( 5 )$$

Where i_{loc} represents a current density of the signal line to be plated, and a unit is A/m²; i₀ represents an exchange current density; η represents an activation overpotential of metal ions in the electrolyte solution; E_{eq} represents an equilibrium potential of the metal ions in the electrolyte solution; T represents a thermodynamic temperature; αₐ represents a charge transfer coefficient in a cathode direction; α_{c} represents a charge transfer coefficient in an anode direction; z represents the number of electrons involved in an electrode reaction process; F represents the Faraday constant; R represents a gas constant; and E represents a potential of the seed layer 16 and the signal line to be plated.

During actual electroplating, quantitative control of values of i₀, αₐ, z, F, R and T may be achieved by debugging the electroplating equipment and controlling the electroplating process. This shows that the size of the value is only related to the size of the value.

The value of n is related to E and E_{eq}, the value of E_{eq} is also a constant, and the potential of the electrolyte solution is 0.34 V. Therefore, the value of n is only related to E. Combined with the actual electroplating process, a formula (6) may be obtained:

$$E = {φ}_{s} - {φ}_{l} . \qquad ( 6 )$$

The formula (6) is substituted into the formula (5) to obtain a formula (7):

$$η = {φ}_{s} - {φ}_{l} - {E}_{eq} . \qquad ( 7 )$$

Where φₛ represents a potential difference between a surface of the signal line to be plated away from the seed layer 16 and the seed layer 16; and φₗ represents a potential of the electrolyte solution.

It can be seen according to the formula (7) that the value of n is mainly affected by φₛ and φₗ. Next, the values of φₛ and φₗ are studied.

By studying the specific electroplating process, the following formula (8) can be obtained:

$${φ}_{l} = \frac{{xI}_{tot}}{σ {L}_{bath} \cdot {W}_{bath}} . \qquad ( 8 )$$

Where σ represents a conductivity of the electrolyte solution; L_{bath}·W_{bath} represents a product of a length and a width of the receiving tank; x represents a distance between the seed layer 16 and an anode copper metal; Iₜₒₜ represents a current passing through the seed layer 16; φₛ represents a potential of the seed layer 16 and the signal line to be plated; and φₗ represents an electrode potential of the electroplating copper solution.

It can be seen combined with the above formula (8) that the value of σmay be controlled by adjusting components and/or ratio of the electrolyte solution, the value of Iₜₒₜ may be controlled by adjusting the magnitude of the current passing through the seed layer 16, the value of x may be controlled by adjusting a distance between the seed layer 16 and the anode structure, and the value of L_{bath}·W_{bath} may be determined by the size of the receiving tank. Therefore, the value of φₗ may be adjusted to a constant value.

Therefore, it can be obtained that the value of η is only related to φₛ, and φₛ represents a potential of the seed layer 16 and the signal line to be plated. Since the thickness of the signal line to be plated changes constantly during electroplating, the potential of the signal line to be plated will also change, and thus the value of φₛ will also change.

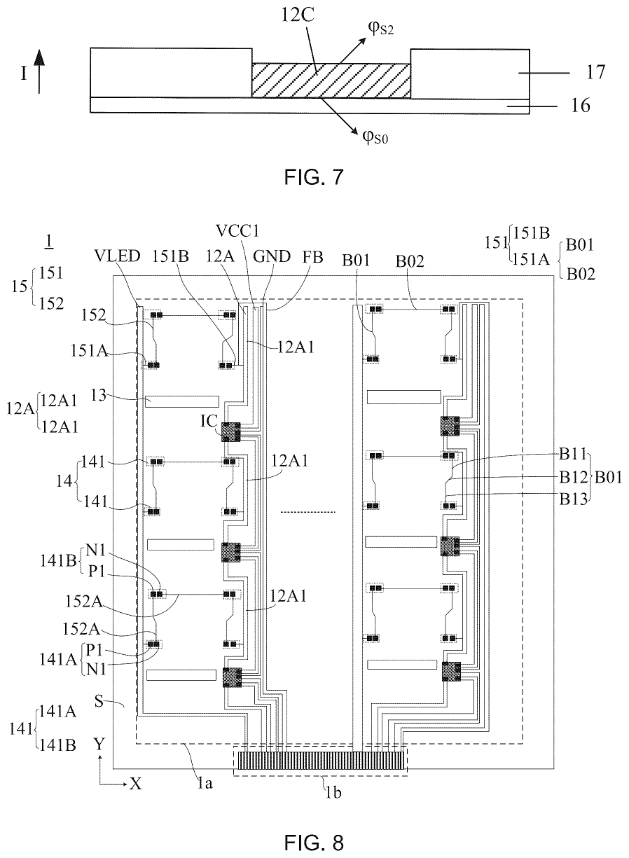

Next, the value of φₛ is studied. For convenience of research, two signal lines to be plated with different areas of bottom surfaces are selected in different regions with unit areas. The structure shown in FIG. 6 is a first signal line 12B to be plated, and the structure shown in FIG. 7 is a second signal line 12C to be plated. The value of φₛ₁₀ of the first signal line to be plated and the seed layer 16 and the value of φₛ₂₀ of the second signal line to be plated and the seed layer 16 are studied. The photoresist layer 17 has an opening, and a signal line is formed in the opening after the electroplating process is performed.

For the first signal line to be plated, it can be seen that a potential difference between a surface of the first signal line to be plated away from the seed layer 16 and the seed layer 16 is φₛ₁₀.

$${φ}_{s 10} = {φ}_{s 1} - {φ}_{s 0} . \qquad ( 9 )$$

Where φₛ₁ represents a potential on the surface of the first signal line 12B to be plated away from the seed layer 16, and φₛ₀ represents a potential on the seed layer 16.

The relationship of a potential difference, a resistance and a current is as following:

$${φ}_{s 10} = {I}_{tot} ( R 0 + R 1 ) . \qquad ( 10 )$$

Where R0 represents a resistance of the seed layer 16 and R0 is a constant value; and R1 represents a resistance of the first signal line to be plated. It can be seen from the above that the value of φₛ₁₀ is related to the resistance of the first signal line to be plated.

For the second signal line to be plated, it can be seen that a potential difference between a surface of the second signal line to be plated away from the seed layer 16 and the seed layer 16 is φₛ₂₀.

$${φ}_{s 20} = {φ}_{s 2} - {φ}_{s 0} . \qquad ( 11 )$$

Where φₛ₂ represents a potential on the surface of the second signal line 12C to be plated away from the seed layer 16, and φₛ₀ represents a potential on the seed layer 16.

The relationship of a potential difference, a resistance and a current is as following:

$${φ}_{s 20} = {I}_{tot} ( R 0 + R 2 ) . \qquad ( 12 )$$

Where R0 represents a resistance of the seed layer 16 and R0 is a constant value; and R2 represents a resistance of the second signal line to be plated. It can be seen from the above that the value of φₛ₂₀ is related to the resistance of the second signal line to be plated.

The formula (13) is as following:

$$R = ρ l / S . \qquad ( 13 )$$

Where R represents a resistance of a conductor (the first signal line to be plated or the second signal line to be plated); ρ represents a resistivity of the conductor; l represents a length of the conductor (a dimension from left to right in FIG. 6 or 7); and S represents a cross-sectional area of the conductor perpendicular to the length direction.

The formula (13) is substituted into the formula (10) to obtain a formula (14).

$${φ}_{s 10} = {I}_{tot} ( R 0 + ρ l / {S}_{1} ) . \qquad ( 14 )$$

Where S₁ represents a cross-sectional area (an area of a bottom surface) of the first signal line to be plated perpendicular to the length direction. It can be obtained combined with the formula (14) and the formula (4) that the area of the bottom surface of the first signal line to be plated will affect the current density on the first signal line to be plated.

Similarly, the formula (13) is substituted into the formula (12) to obtain a formula (15).

$${φ}_{s 20} = {I}_{tot} ( R 0 + ρ l / {S}_{2} ) . \qquad ( 15 )$$

Where S₂ represents a cross-sectional area (an area of a bottom surface) of the second signal line to be plated perpendicular to the length direction. It can be obtained combined with the formula (15) and the formula (4) that the area of the bottom surface of the second signal line to be plated will affect the current density on the second signal line to be plated.

On this basis, by subtracting the formula (14) from the formula (15), a potential difference between the first signal line to be plated and the second signal line to be plated may be obtained as:

$${φ}_{s 10} - {φ}_{s 20} = {I}_{tot} ( \frac{ρ l}{{S}_{1}} - \frac{ρ l}{{S}_{2}} ) = {I}_{tot} ρ l ( S 1 - S 2 ) / S 1 S 2. \qquad ( 16 )$$

It can be seen combined with the formula (16) and the formula (4) that the potential difference between the first signal line to be plated and the second signal line to be plated is affected by a difference between an area of the bottom surface of the first signal line to be plated and an area of the bottom surface of the second signal line to be plated. It can be seen according to the formulas (4) and (7) that the potential on the first signal line to be plated will affect the current density on the first signal line to be plated, and the potential on the second signal line to be plated will affect the current density on the second signal line to be plated. Therefore, the difference between the area of the bottom surface of the first signal line to be plated and the area of the bottom surface of the second signal line to be plated will affect a difference between the current density on the first signal line to be plated and the current density on the second signal line to be plated.

On this basis, a uniformity of the current densities of the signal lines to be plated (the first signal line to be plated and the second signal line to be plated) may be calculated by the formula (17).

$$Unif ( {i}_{loc} ) = \frac{[ Max ( {i}_{loc} ) - Min ( {i}_{loc} ) ]}{2 {I}_{avg}} . \qquad ( 17 )$$

Where Unif (i_{loc}) represents a uniformity of the current densities of the signal lines to be plated (the first signal line to be plated and the second signal line to be plated); Max (i_{loc}) represents a current density at a point with the largest current density in the selected test points on the signal line to be plated; Min (i_{loc}) represents a current density at a point with the smallest current density in the selected test points on the signal line to be plated; and I_{avg} represents an average value of the current densities of all the selected test points on the signal line to be plated.

It can be seen that the uniformity of the current density on the first signal line to be plated and the current density on the second signal line to be plated will be affected by the difference between the current density on the first signal line to be plated and the current density on the second signal line to be plated. The greater the difference between the current density on the first signal line to be plated and the current density on the second signal line to be plated, the worse the uniformity of the current density on the first signal line to be plated and the current density on the second signal line to be plated. The less the difference between the current density on the first signal line to be plated and the current density on the second signal line to be plated, the better the uniformity of the current density on the first signal line to be plated and the current density on the second signal line to be plated.

On this basis, it can be concluded that the difference between the area of the bottom surface of the first signal line to be plated and the area of the bottom surface of the second signal line to be plated will affect the uniformity of the current density on the first signal line to be plated and the current density on the second signal line to be plated. The greater the difference between the area of the bottom surface of the first signal line to be plated and the area of the bottom surface of the second signal line to be plated, the worse the uniformity of the current density on the first signal line to be plated and the current density on the second signal line to be plated, and the worse the thickness uniformity of different signal lines 12 formed after the electroplating is finished. The less the difference between the area of the bottom surface of the first signal line to be plated and the area of the bottom surface of the second signal line to be plated, the better the uniformity of the current density on the first signal line to be plated and the current density on the second signal line to be plated, and the better the thickness uniformity of different signal lines 12 formed after the electroplating is finished.

It can be concluded combined with the above two inferences that in a region with a unit area, the greater the difference between the area of the bottom surface of the first signal line to be plated and the area of the bottom surface of the second signal line to be plated, the worse the thickness uniformity of different signal lines 12 formed; and the less the difference between the area of the bottom surface of the first signal line to be plated and the area of the bottom surface of the second signal line to be plated, the better the thickness uniformity of different signal lines 12 formed.

Based on this, as shown in FIG. 5, the wiring substrate 1 further includes a plurality of dummy conductive patterns 13, and the plurality of dummy conductive patterns 13 are located on the first surface S of the substrate. At least part of the plurality of dummy conductive patterns 13 are provided in the same layer as the plurality of signal lines 12. A dummy conductive pattern 13 is provided between two adjacent signal lines 12, and the dummy conductive pattern 13 is insulated from the two adjacent signal lines 12. The light-emitting device 2 is electrically connected to signal lines 12.

With the above provision, in a process of forming the signal lines 12 by electroplating, the dummy conductive patterns 13 are formed simultaneously. The positions of the dummy conductive patterns to be plated are reasonably set, and the number of the dummy conductive patterns 13 to be plated are reasonably set. As a result, in a region with a unit area, if areas of bottom surfaces of two adjacent signal lines to be plated have a large difference, the dummy conductive patterns to be plated may be provided, so that the current densities on the two adjacent signal lines to be plated are close, the electroplating efficiencies are close, and thus the thicknesses of the two adjacent signal lines 12 are close, thereby improving the thickness uniformity of the two adjacent signal lines 12.

The dummy conductive pattern to be plated refers to an intermediate state presented by the dummy conductive pattern 13 during forming the dummy conductive pattern 13 with a specific thickness in a specific region by electroplating.

It can be understood that the material of the dummy conductive patterns 13 is consistent with the material of the signal lines 12. For example, the signal lines 12 and the dummy conductive patterns 13 are both made of copper.

In some examples, before the dummy conductive patterns 13 are formed by electroplating, exposure, development and other operations need to be performed on the third photoresist layer using a mask to form second openings, so that the dummy conductive patterns 13 are formed in the second openings.

In some examples, the dummy conductive pattern 13 is insulated from the two adjacent signal lines 12, which may mean that the dummy conductive pattern 13 is not in contact with the two adjacent signal lines 12. Of course, any other suitable insulation methods are not excluded.

For example, a dummy conductive pattern 13 is at least provided between two adjacent signal lines 12 having different line widths. The “two adjacent signal lines 12 having different line widths” may refer to a first signal line VLED and an addressing signal line 12A that are adjacent, an addressing signal line 12A and a first voltage line VCC1 that are adjacent, a first voltage line VCC1 and a second signal line GND that are adjacent, a second signal line GND and a feedback signal line FB that are adjacent, or the like.

For example, in the wiring substrate 1 shown in FIG. 5, a dummy conductive pattern 13 is provided between a first signal line VLED and a second voltage line VCC2 that are adjacent, and line widths of the first signal line VLED and the second voltage line VCC2 are different.

It can be understood that in addition to the plurality of signal lines 12 mentioned above, the first surface S of the substrate 11 is also provided thereon with a plurality of connection lines 15 for connecting the light-emitting devices 2 and the signal lines 12. The connection lines 15 and the signal lines 12 cooperate with each other to achieve signal transmission, thereby ensuring the normal work of the light-emitting devices 2.

In some embodiments, as shown in FIG. 8, the wiring substrate 1 further includes a plurality of pad units 14 and a plurality of connection lines 15. The plurality of pad units 14 are located on the first surface S, and the pad unit 14 includes multiple device pad groups 141. The plurality of connection lines 15 are located on the first surface S and located in the display region 1a. The connection lines 15 include first connection lines 151 and second connection lines 152. The pad unit 14 and the signal line 12 are configured to be connected by a first connection line 151; and the multiple device pad groups 141 in the same pad unit 14 are configured to be connected by a second connection line 152. The plurality of connection lines 15 are arranged in a plurality of columns. The light-emitting device 2 is connected to a device pad group 141.

The provision of the connection line 15 and the device pad group 141 may allow a signal to be transmitted between the signal line 12, the first connection line 151, and the second connection line 152. When the signal passes through the second connection line 152, the signal can be transmitted to the light-emitting device 2 through the device pad group 141, so as to achieve control of the light-emitting device 2.

For example, the number of the device pad groups 141 in a pad unit 14 is four, six or nine, which may be set depending on specific needs.

The multiple device pad groups 141 in a pad unit 14 may be connected in series. Alternatively, the multiple device pad groups 141 in a pad unit 14 may be connected in parallel. Alternatively, the multiple device pad groups 141 in a pad unit 14 may be connected in a series plus parallel manner. The embodiments of the present disclosure are described by taking an example where the multiple device pad groups 141 in a pad unit 14 are connected in series.

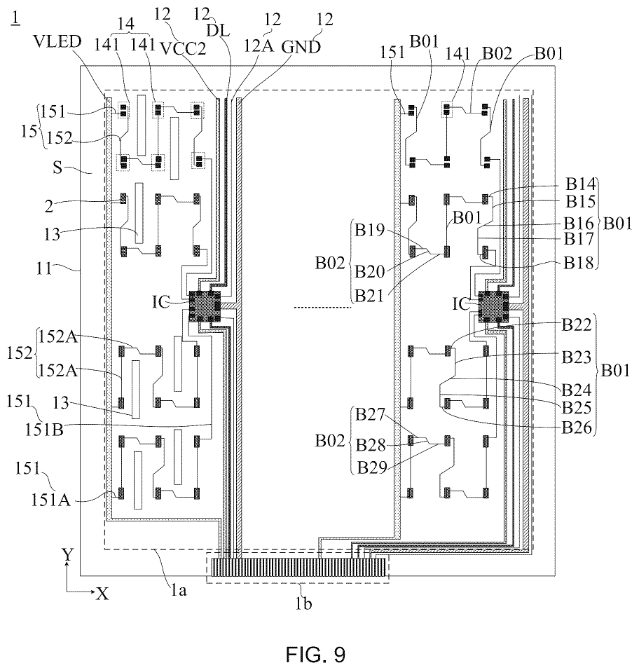

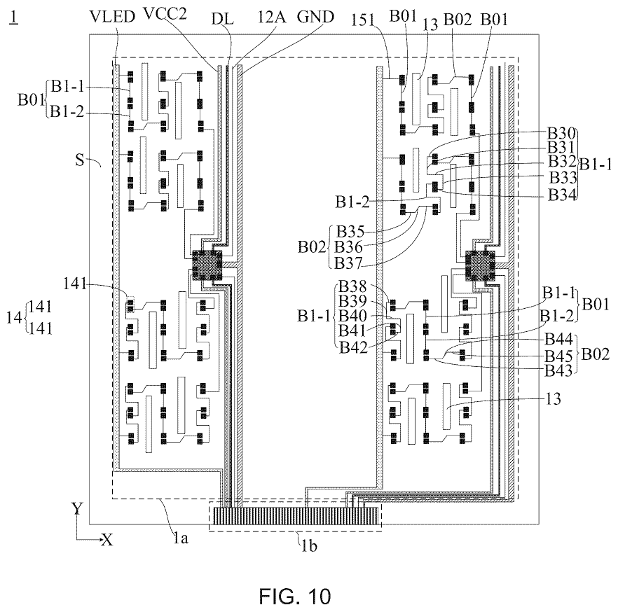

Further, the multiple device pad groups 141 in a pad unit 14 are arranged in an array of n×m. For example, as shown in FIG. 8, in a case where the pad unit 14 includes four device pad groups 141, the four device pad groups 141 are arranged in a 2×2 array. As another example, as shown in FIG. 9, in a case where the pad unit 14 includes six device pad groups 141, the six device pad groups 141 are arranged in a 2×3 array. As another example, as shown in FIG. 10, in a case where the pad unit 14 includes nine device pad groups 141, the nine device pad groups 141 are arranged in a 3×3 array.

Further, the multiple device pad groups 141 in each pad unit 14 have the same arrangement. Each device pad group 141 includes the same number of pads, and pads in different device pad groups 141 are arranged in the same manner. For example, as shown in FIG. 8, each device pad group 141 in the pad unit 14 includes an anode pad P1 and a cathode pad N1, and the anode pad P1 and the cathode pad N1 are spaced apart in the first direction X. As another example, as shown in FIG. 10, each device pad group 141 in the pad unit 14 includes an anode pad P1 and a cathode pad N1, and the anode pad P1 and the cathode pad N1 are spaced apart in the second direction Y.

It will be explained that the pad unit 14 and the signal line 12 are configured to be connected by the first connection line 151, which may mean that as shown in FIG. 8, the pad unit 14 is connected to the first signal line VLED by the first connection line 151, or the pad unit 14 is connected to the addressing signal line 12A by the first connection line 151.

As shown in FIG. 8, a connection line 15 includes two first connection lines 151, and the two first connection lines 151 are a first sub-segment 151A and a second sub-segment 151B. An input end of the first sub-segment 151A is connected to the first signal line VLED, and an output end of the first sub-segment 151A is connected to the pad unit 14. An input end of the second sub-segment 151B is connected to the pad unit 14, and an output end of the second sub-segment 151B is connected to the addressing signal line 12A.

It can be understood that the input end of the first sub-segment 151A and the input end of the second sub-segment 151B refer to signal input ends, and the output end of the first sub-segment 151A and the output end of the second sub-segment 151B refer to signal output ends. The signal is transmitted from the first signal line VLED to the addressing signal line 12A.

In some embodiments, as shown in FIG. 8, the wiring substrate 1 further includes a plurality of driver chips IC, and the driver chips IC are disposed on the first surface S. For example, the plurality of driver chips IC are arranged in multiple column in the first direction X, and arranged in multiple rows in the second direction Y.

A driver chip IC may control a pad unit 14 or multiple pad units 14, which may be selected specifically depending on the type of the driver chip IC.

Further, the pad unit 14 includes an input end and an output end. The input end of the pad unit 14 is connected to the first signal line VLED, and the output end of the pad unit 14 is connected to the driver chip IC. In a pad unit 14, a device pad group 141 closest to the driver chip IC in the multiple device pad groups 141 connected in series serves as an initial device pad group 141, and a pad in the initial device pad group 141 serves as the output end of the pad unit 14 which is electrically connected to the driver chip IC. Starting from the initial device pad group 141, all the device pad groups 141 in the pad unit 14 are connected in series, and the last device pad group 141 is directly connected to the first signal line VLED.

For example, as shown in FIG. 8, in a case where the pad unit 14 includes four device pad groups 141, a driver chip IC may control a pad unit 14, or control multiple pad units 14 synchronously. In the relevant embodiments and drawings of the present disclosure regarding the pad unit 14 including four device pad groups 141, the description and illustration are made by an example of the driver chip IC controlling a pad unit 14.

For example, as shown in FIG. 8, the driver chip IC may be connected to the addressing signal line 12A, the first voltage line VCC1, and the second signal line GND. The first voltage line VCC1 may provide a power signal and a data signal for the driver chip IC simultaneously. The second signal line GND is used to ground the driver chip IC.

The addressing signal line 12A includes a plurality of addressing signal sub-segments 12A1. In a column of driver chips, any two adjacent driver chips IC are electrically connected by an addressing signal sub-segment 12A1. The last driver chip IC in a column of driver chips IC is connected to an end of the feedback signal line FB by an addressing signal sub-segment 12A1, and the other end of the feedback signal line FB extends into the peripheral region 1b.

It can be understood that multiple light-emitting devices 2 are connected in series by the multiple device pad groups 141 in a pad unit 14 and multiple second connection lines 152. An end of the multiple light-emitting devices 2 connected in series is connected to the first signal line VLED by a first sub-segment 151A, and the other end of the multiple light-emitting devices 2 connected in series may be directly connected to the driver chip IC by a second sub-segment 151B, or the other end of the multiple light-emitting devices 2 connected in series may be connected to the addressing signal line 12A by a second sub-segment 151B.

For example, a driver chip IC may control a pad unit 14, or as shown in FIG. 9, control multiple pad units 14 synchronously. A pad unit 14 may include multiple device pad groups 141. In the relevant embodiments and drawings of the present disclosure regarding the pad unit 14 including six or nine device pad groups 141, the description and illustration are made by an example of the driver chip IC controlling four pad units 14.

In this case, as shown in FIG. 9, the driver chip IC is connected to the addressing signal line 12A, the second voltage line VCC2, the data signal line DL and the second signal line GND. The second signal line GND is used to ground the driver chip IC; the second voltage line VCC2 is used to provide a power signal for the driver chip IC; and the data signal line DL provides a data signal for the driver chip IC.

In a column of driver chips, any two adjacent driver chips IC are electrically connected by an addressing signal sub-segment 12A1. The last driver chip IC in a column of driver chips IC is connected to an end of the feedback signal line FB by an addressing signal sub-segment 12A1, and the other end of the feedback signal line FB extends into the peripheral region 1b.

In this case, multiple light-emitting devices 2 are connected in series by the multiple device pad groups 141 in a pad unit 14 and multiple second connection lines 152. An end of the multiple light-emitting devices 2 connected in series is connected to the first signal line VLED by a first sub-segment 151A, and the other end of the multiple light-emitting devices 2 connected in series may be directly connected to the driver chip IC by a second sub-segment 151B.

The connection lines 15 are also formed by electroplating, and thus the thickness uniformity also needs to be considered during electroplating.

Based on this, as shown in FIG. 8, in the second direction Y, a dummy conductive pattern 13 is provided between two adjacent connection lines 15 in the same column, and the dummy conductive pattern 13 is insulated from the connection lines 15.

It can be understood that different connection lines 15 are located in different wiring spaces on the wiring substrate. Therefore, during electroplating, there is a difference in electric field density at positions where different connection lines 15 are located, resulting in uneven thickness between different connection lines 15.

With the above provision, in a process of forming the connection lines 15 by electroplating, the dummy conductive patterns 13 are formed simultaneously. In a case where there is a difference in space on the wiring substrate between two adjacent connection lines 15 to be plated, by reasonably setting the positions of the dummy conductive patterns 13 to be plated and reasonably setting the number of the dummy conductive patterns 13 to be plated, in regions where the two connection lines 15 to be plated are located respectively, proportions of areas of bottom surfaces of metal patterns to be plated (including the signal line 12, the dummy conductive pattern 13 and the connection line 15) are close, so that current densities on the two adjacent connection lines 15 to be plated are close, the electroplating efficiencies are close, and the thicknesses of the two adjacent connection lines 15 are close. Thus, the thickness uniformity of the two adjacent connection lines 15 may be improved, thereby improving yield of the wiring substrate 1 and ensuring reliability of the wiring substrate 1.

The connection line 15 to be plated refers to an intermediate state presented by the connection line 15 during forming the connection line 15 with a specific thickness in a specific region by electroplating.

In some examples, the connection line 15 and the signal line 12 are disposed in the same layer, that is, the connection line 15 and the signal line 12 are located in the same conductive layer, and the connection line 15 and the signal line 12 are formed simultaneously by a single electroplating process.

It can be understood that the width of the connection line 15 is smaller than that of the signal line 12. During forming the connection line 15 and the signal line 12 by electroplating, the metal ions have a relatively great density at a location where the signal line 12 is formed, and a deposition rate of the metal ions is rather fast.

In the present embodiments, a dummy conductive pattern 13 is provided between two adjacent connection lines 15. During electroplating, the density of metal ions at positions where the two adjacent connection lines 15 to be plated are located increases, so that the current densities on the connection line 15 to be plated and the signal line 12 to be plated are close, the electroplating efficiencies are close, and thus the thicknesses of the connection line 15 and the signal line 12 are close. Thus, the thickness uniformity of the connection line 15 and the signal line 12 may be improved, thereby improving the yield of the wiring substrate 1 and ensuring the reliability of the wiring substrate 1.

Further, in a case where the connection lines 15 and the signal lines 12 are disposed in the same layer, the dummy conductive pattern 13 may be located not only between two adjacent signal lines 12 but also between two adjacent connection lines 15. Thus, the thickness uniformity of the connection lines 15 may be improved, and the thickness uniformity of the connection lines 15 and the signal lines 12 may also be improved.

For example, in a case where a driver chip IC controls a pad unit 14, and the pad unit 14 includes four device pad groups 141, the dummy conductive pattern 13 may be located not only between the first signal line VLED and the addressing signal line 12A, but also located between two adjacent connection lines 15.

As another example, in a case where a driver chip IC controls four pad units 14, and a pad unit 14 includes six or nine device pad groups 141, the dummy conductive pattern 13 may be located not only between the first signal line VLED and the second voltage line VCC2, but also located between two adjacent connection lines 15.

A pad unit 14 includes multiple device pad groups 141. As shown in FIG. 9, a connection sub-segment 152A is used to make each two device pad groups 141 in the multiple device pad groups 141 electrically connected (including series connection or parallel connection), that is, two ends of the connection sub-segment 152A are respectively connected to two different device pad groups 141 in the same pad unit 14. A plurality of connection sub-segments 152A in the same pad unit 14 constitute a second connection line 152.

It will be noted that an insulating layer is formed on a side of the connection line 15 and the signal line 12 away from the substrate 11, and the insulating layer is used to isolate the connection line 15 and the signal line 12 from moisture and oxygen. The insulating layer has a plurality of via holes, and the via hole exposes a portion of the connection line 15, or the via hole also exposes a portion of the signal line 12. Portions of two adjacent connection sub-segments 152A exposed by via holes constitute a device pad group 141.

To facilitate understanding that the connection sub-segment 152A connects two device pad groups 141, as shown in FIG. 8, the two device pad groups 141 respectively connected to the two ends of the same connection sub-segment 152A are named a first device pad group 141A and a second device pad group 141B. The first device pad group 141A includes an anode pad P1 and a cathode pad N1, and the second device pad group 141B includes an anode pad P1 and a cathode pad N1. In this case, the connection sub-segment 152A connects two adjacent device pad groups 141, which means that an end of the connection sub-segment 152A is connected to the anode pad P1 of the second device pad group 141B, and the other end of the connection sub-segment 152A is connected to the cathode pad N1 of the first device pad group 141A.

Since the plurality of connection sub-segments 152A included in a second connection line 152 may be located in different wiring environments, during forming different connection sub-segments 152A by electroplating, the thickness uniformity of different connection sub-segments 152A also needs to be considered.

Based on this, as shown in FIG. 9, in some embodiments, at least part of the dummy conductive pattern 13 is located within a region surrounded by the same second connection line 152.

In this way, in a process of forming the plurality of connection sub-segments 152A by electroplating, the dummy conductive pattern 13 located in the region surrounded by the second connection line 152 may also be formed simultaneously. The positions of the dummy conductive patterns 13 to be plated and the number of the dummy conductive patterns 13 to be plated are reasonably set as needed. As a result, during electroplating, the electric fields at the positions where different connection sub-segments 152A to be plated are located are uniformly distributed, so that the thicknesses of different connection sub-segments 152A are uniform, thereby improving the yield of the wiring substrate 1 and ensuring the reliability of the wiring substrate 1.

The connection sub-segment 152A to be plated refers to an intermediate state presented by the connection sub-segment 152A during forming the connection sub-segment 152A with a specific thickness in a specific region by electroplating.

In order to meet the arrangement requirements of multiple device pad groups 141 in the same pad unit 14, the plurality of connection sub-segments 152A generally have two directions. The first type of connection sub-segments 152A extend in the first direction X, and the second type of connection sub-segments 152A extend in the second direction Y.

In some embodiments, as shown in FIG. 9, the plurality of connection sub-segments 152A include a plurality of first connection sub-segments B01 and a second connection sub-segment B02 located between two adjacent first connection sub-segments B01. The first connection sub-segment B01 extends in the second direction Y, and the second connection sub-segment B02 extends in the first direction X.

The first connection sub-segment B01 is used to connect two device pad groups 141 spaced apart in the second direction Y in the same pad unit 14; and the second connection sub-segment B02 is used to connect two device pad groups 141 spaced apart in the first direction X in the same pad unit 14.

In this way, space of the display region 1a in the first direction X may be saved through the tortuous direction of the second connection line 152 while two adjacent device pad groups 141 are connected, so that more dense device pad groups 141 may be provided in the limited space above the substrate 11 to connect more light-emitting devices 2.

It can be understood that according to the difference in number of the device pad groups 141 in a pad unit 14, the numbers and arrangements of the first connection sub-segments B01 and the second connection sub-segments B02 included in the second connection line 152 are also different.

For example, as shown in FIG. 8, in a case where four device pad groups 141 in a pad unit 14 are arranged in a 2×2 array, the second connection line 152 includes two first connection sub-segments B01 and a second connection sub-segment B02, and the second connection line 152 has a “U”-shaped structure.

As another example, as shown in FIG. 9, in a case where six device pad groups 141 in a pad unit 14 are arranged in a 2×3 array, the second connection line 152 includes three first connection sub-segments B01 and two second connection sub-segments B02, and the second connection line 152 has an “S”-shaped structure.

As another example, as shown in FIG. 10, in a case where nine device pad groups 141 in a pad unit 14 are arranged in a 3×3 array, the second connection line 152 includes three first connection sub-segments B01 and two second connection sub-segments B02, and the second connection line 152 has an “S”-shaped structure. In this case, each first connection sub-segment B01 includes a first section B1-1 and a second section B1-2 arranged from top to bottom, and a device pad group 141 located between the first section B1-1 and the second section B1-2, and the device pad group 141 is connected to the first section B1-1 and the second section B1-2.

In addition, it will be explained that the first connection sub-segment B01 extending in the second direction Y does not mean that the first connection sub-segment B01 is a straight line segment extending only in the second direction Y in a strict sense, and the first connection sub-segment B01 may also be a broken line segment extending in the second direction Y as a whole. Similarly, the second connection sub-segment B02 extending in the first direction X does not mean that the second connection sub-segment B02 is a straight line segment extending only in the first direction X in a strict sense, and the second connection sub-segment B02 may also be a broken line segment extending in the first direction X as a whole. Such a design is mainly to facilitate connection between two adjacent device pad groups 141 together by the first connection sub-segment B01 and the second connection sub-segment B02.

The specific forms of the first connection sub-segment B01 and the second connection sub-segment B02 will be described below for a case where a pad unit 14 includes four, six or nine device pad groups 141.

For ease of description, a positive direction of the first direction X is defined as a right direction, a negative direction of the first direction X is defined as a left direction, a positive direction of the second direction Y is defined as an upper direction, and a negative direction of the second direction Y is defined as a lower direction.

For a case where a pad unit 14 includes four device pad groups 141, for example, as shown in FIG. 8, in a pad unit 14, the first connection sub-segments B01 at left and right sides are each used to connect two device pad groups 141 spaced apart in the second direction Y, and each include a first straight section B11, a first inclined section B12 and a second straight section B13 that are sequentially connected from top to bottom. The first straight section B11 extends in the second direction Y, and the second straight section B13 extends in the second direction Y. For the first connection sub-segment B01 at the left, the first straight section B11 is located on a left side of the second straight section B13, an upper end of the first straight section B11 is connected to a device pad group 141, and a lower end of the second straight section B13 is connected to another device pad group 141. For the first connection sub-segment B01 at the right, the first straight section B11 is located on a right side of the second straight section B13.

The second connection sub-segment B02 is used to connect two device pad groups 141 spaced apart in the first direction X. The second connection sub-segment B02 is a line segment extending in the first direction X.

For a case where a pad unit 14 includes six device pad groups 141, as shown in FIG. 9, since pad units 14 and the driver chip IC have different relative positional relationships therebetween, morphologies of the plurality of first connection sub-segments B01 and the plurality of second connection sub-segments B02 in each of the pad units 14 are not consistent.

For a pad unit 14 located on an upper side of the driver chip IC, the first connection sub-segment B01 is used to connect two device pad groups 141 spaced apart in the second direction Y. There are three first connection sub-segments B01 arranged at intervals in the first direction X. For the first connection sub-segment B01 at the middle, the first connection sub-segment B01 is a line segment extending in the second direction Y; while for the first connection sub-segments B01 at both sides, the first connection sub-segments B01 each include a third straight section B14, a fourth straight section B15, a second inclined section B16, a fifth straight section B17 and a sixth straight section B18 that are sequentially connected from top to bottom. The third straight section B14 extends in the first direction, the fourth straight section B15 extends in the second direction, the fifth straight section B17 extends in the second direction, the sixth straight section B18 extends in the first direction, and the fourth straight section B15 is located on a right side of the fifth straight section B17. A left end of the third straight section B14 is connected to a device pad group 141, and a right end of the sixth straight section B18 is connected to another device pad group 141. The second connection sub-segment B02 is used to connect two device pad groups 141 spaced apart in the first direction X. The upper and lower second connection sub-segments B02 each include a seventh straight section B19, a third inclined section B20 and an eighth straight section B21 that are connected sequentially from left to right. The seventh straight section B19 is located on an upper side of the eighth straight section B21. A left end of the seventh straight section B19 is connected to a device pad group 141, and a right end of the eighth straight section B21 is connected to another device pad group 141.

For a pad unit 14 located on a lower side of the driver chip IC, as shown in FIG. 9, the first connection sub-segment B01 is used to connect two device pad groups 141 spaced apart in the second direction Y. There are three first connection sub-segments B01 arranged at intervals in the first direction X. For the first connection sub-segment B01 at the middle, the first connection sub-segment B01 includes a ninth straight section B22, a tenth straight section B23, a fourth inclined section B24, an eleventh straight section B25 and a twelfth straight section B26 that are sequentially connected from top to bottom. The ninth straight section B22 extends in the first direction, the tenth straight section B23 extends in the second direction, the eleventh straight section B25 extends in the second direction, the twelfth straight section B26 extends in the first direction, and the tenth straight section B23 is located on a right side of the eleventh straight section B25. A left end of the ninth straight section B22 is connected to a device pad group 141, and a right end of the twelfth straight section B26 is connected to another device pad group 141. For the first connection sub-segments B01 at both sides, the first connection sub-segments B01 are each a line segment extending in the second direction Y.

The second connection sub-segment B02 is used to connect two device pad groups 141 spaced apart in the first direction X. The upper and lower second connection sub-segments B02 each include a thirteenth straight section B27, a fifth inclined section B28 and a fourteenth straight section B29 that are connected sequentially from left to right. The thirteenth straight section B27 is located on an upper side of the fourteenth straight section B29. A left end of the thirteenth straight section B27 is connected to a device pad group 141, and a right end of the fourteenth straight section B29 is connected to another device pad group 141.

For a case where a pad unit 14 includes nine device pad groups 141, since pad units 14 and the driver chip IC have different relative positional relationships therebetween, morphologies of the plurality of first connection sub-segments B01 and the second connection sub-segments B02 in each of the pad units 14 are not consistent.

For a pad unit 14 located on an upper side of the driver chip IC, the first connection sub-segment B01 is used to connect device pad groups 141 spaced apart in the second direction Y. There are three first connection sub-segments B01 arranged at intervals in the first direction X. For the first section B1-1 and the second section B1-2 of the first connection sub-segment B01 at the middle, the first section B1-1 and the second section B1-2 each include a first connecting section B30, a second connecting section B31, a third connecting section B32, a fourth connecting section B33 and a fifth connecting section B34 that are sequentially connected from top to bottom. The first connecting section B30, the third connecting section B32 and the fifth connecting section B34 extend in the first direction X, the second connecting section B31 and the fourth connecting section B33 extend in the second direction Y, and the second connecting section B31 is located on a left side of the fourth connecting section B33. A right end of the first connecting section B30 is connected to a device pad group 141, and a left end of the fifth connecting section B34 is connected to another device pad group 141.

For the first sections B1-1 and the second sections B1-2 of the first connection sub-segments B01 at both sides, the first sections B1-1 and the second sections B1-2 are each a line segment extending in the second direction Y.

The second connection sub-segment B02 is used to connect two device pad groups 141 spaced apart in the first direction X. The upper and lower second connection sub-segments B02 each include a sixth connecting section B35, a sixth inclined section B36 and a seventh connecting section B37 that are sequentially connected from left to right. The sixth connecting section B35 and the seventh connecting section B37 both extend in the first direction, and the sixth connecting section B35 is located on a lower side of the seventh connecting section B37. A left end of the sixth connecting section B35 is connected to a device pad group 141, and a right end of the seventh connecting section B37 is connected to another device pad group 141.

For a pad unit 14 located on a lower side of the driver chip IC, the first connection sub-segment B01 is used to connect device pad groups 141 spaced apart in the second direction Y. There are three first connection sub-segments B01 arranged at intervals in the first direction X. For the first section B1-1 and the second section B1-2 of the first connection sub-segment B01 at the middle, the first section B1-1 and the second section B1-2 are each a line segment extending in the second direction Y. For the first sections B1-1 and the second sections B1-2 of the first connection sub-segments B01 at both sides, the first sections B1-1 and the second sections B1-2 each include an eighth connecting section B38, a ninth connecting section B39, a tenth connecting section B40, an eleventh connecting section B41 and a twelfth connecting section B42 that are sequentially connected. The eighth connecting section B38, the tenth connecting section B40 and the twelfth connecting section B42 extend in the first direction X, and the ninth connecting section B39 and the eleventh connecting section B41 extend in the second direction Y. A right end of the eighth connecting section B38 is connected to a device pad group 141, and a left end of the twelfth connecting section B42 is connected to another device pad group 141. The ninth connecting section B39 is located on a left side of the eleventh connecting section B41.

The second connection sub-segment B02 is used to connect two device pad groups 141 spaced apart in the first direction X. The upper and lower second connection sub-segments B02 each include a thirteenth connecting section B43, a seventh inclined section B44 and a fourteenth connecting section B45 that are sequentially connected from left to right. The thirteenth connecting section B43 and the fourteenth connecting section B45 extend in the first direction, and the thirteenth connecting section B43 is located on a lower side of the fourteenth connecting section B45. A left end of the thirteenth connecting section B43 is connected to a device pad group 141, and a right end of the fourteenth connecting section B45 is connected to another device pad group 141.

On a basis that the plurality of connection sub-segments 152A include the first connection sub-segment B01 and the second connection sub-segment B02, there are a variety of positions at which the dummy conductive patterns 13 are located. The specific positions of the dummy conductive patterns 13 will be introduced below.

In a possible implementation, as shown in FIG. 10, in the first direction X, the dummy conductive pattern 13 is located between two adjacent first connection sub-segments B01 in the same second connection line 152.

In this way, in a process of forming two adjacent first connection sub-segments B01 in the same second connection line 152 by electroplating, the dummy conductive pattern 13 is formed simultaneously. The dummy conductive patterns 13 to be plated are provided at appropriate positions as needed, and an appropriate number of dummy conductive patterns 13 to be plated are set. As a result, during electroplating, the electric fields at the positions where different first connection sub-segments B01 to be plated are located are uniformly distributed, so that the thicknesses of different first connection sub-segments B01 are uniform, thereby improving the yield of the wiring substrate 1 and ensuring the reliability of the wiring substrate 1.

The first connection sub-segment B01 to be plated refers to an intermediate state presented by the first connection sub-segment B01 during forming the first connection sub-segment B01 with a specific thickness in a specific region by electroplating.

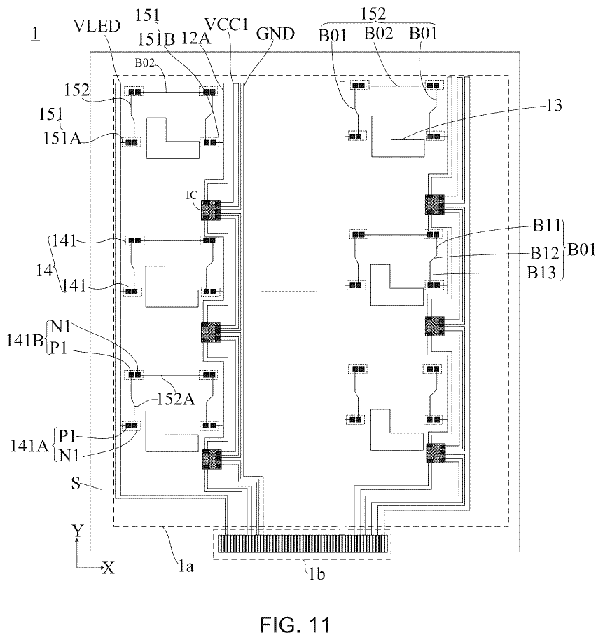

In another possible implementation, as shown in FIG. 11, in the second direction Y, the dummy conductive pattern 13 is located between the second connection sub-segment B02 and the first connection line 151 that are adjacent.

As a result, in a process of forming the second connection sub-segment B02 and the first connection line 151 that are adjacent by electroplating, the dummy conductive pattern 13 is formed simultaneously. The dummy conductive patterns 13 to be plated are provided at appropriate positions as needed, and an appropriate number of dummy conductive patterns 13 to be plated are set as needed. As a result, during electroplating, the electric fields at the positions where the second connection sub-segment B02 to be plated and the first connection line 151 to be plated are located are uniformly distributed, so that the thicknesses of the second connection sub-segment B02 and the first connection line 151 are uniform, thereby improving the yield of the wiring substrate 1 and ensuring the reliability of the wiring substrate 1.

It can be understood that in the second direction Y, the second connection sub-segment B02 and the first connection line 151 that are adjacent may be located in the same connection line 15. Alternatively, the second connection sub-segment B02 and the first connection line 151 that are adjacent may be located in two adjacent connection lines 15.

The second connection sub-segment B02 to be plated refers to an intermediate state presented by the second connection sub-segment B02 during forming the second connection sub-segment B02 with a specific thickness in a specific region by electroplating. The first connection line 151 to be plated refers to an intermediate state presented by the first connection line 151 during forming the first connection line 151 with a specific thickness in a specific region by electroplating.

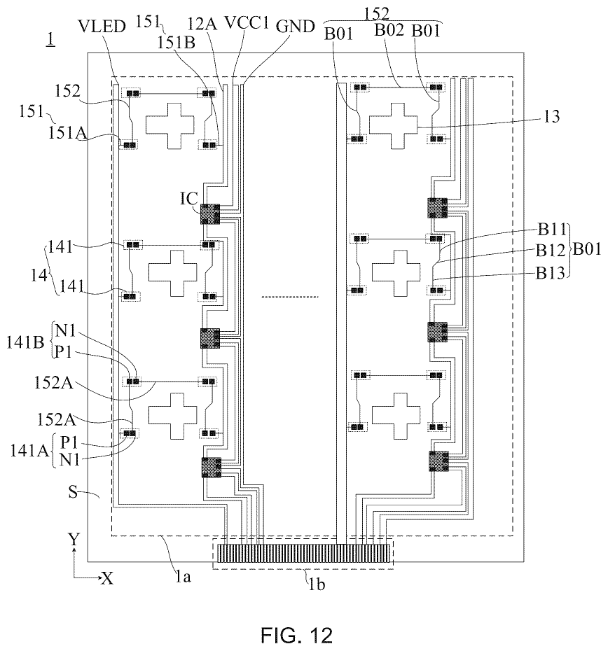

In another possible implementation, as shown in FIG. 12, in the first direction X, the dummy conductive pattern 13 is located between two adjacent first connection sub-segments B01 in the same second connection line 152; and in the second direction Y, the dummy conductive pattern 13 is located between the second connection sub-segment B02 and the first connection line 151 that are adjacent.

It will be explained that in the first direction X, the dummy conductive pattern 13 is located between two adjacent first connection sub-segments B01 in the same second connection line 152, which means that the dummy conductive pattern 13 is located between extension lines of two adjacent first connection sub-segments B01 in the same second connection line 152. Similarly, in the second direction Y, the dummy conductive pattern 13 is located between the second connection sub-segment B02 and the first connection line 151 that are adjacent, which means that the dummy conductive pattern 13 is located between extension lines of the second connection sub-segment B02 and the first connection line 151 that are adjacent.

In some examples, as shown in FIG. 12, in the first direction X, the dummy conductive pattern 13 is located between two adjacent first connection sub-segments B01 in the same second connection line 152; and in the second direction, the dummy conductive pattern 13 is located between the second connection sub-segment B02 and the first connection line 151 that are adjacent, and the second connection sub-segment B02 and the first connection line 151 that are adjacent belong to the same connection line 15.

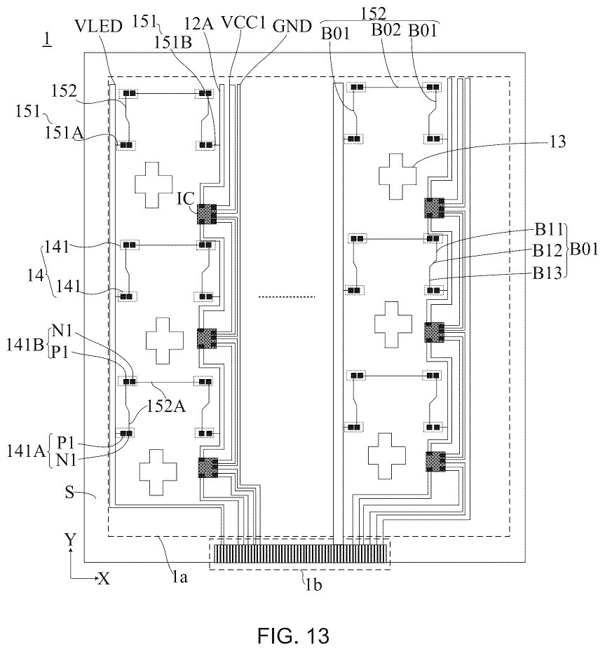

In some other examples, as shown in FIG. 13, in the first direction, the dummy conductive pattern 13 is located between two adjacent first connection sub-segments B01 in the same second connection line 152; and in the second direction, the dummy conductive pattern 13 is located between the second connection sub-segment B02 and the first connection line 151 that are adjacent, and the second connection sub-segment B02 and the first connection line 151 that are adjacent are respectively located in the adjacent connection lines 15.

In this way, in a process of forming two adjacent first connection sub-segments B01, and the second connection sub-segment B02 and the first connection line 151 that are adjacent by electroplating, the dummy conductive pattern 13 is formed simultaneously. The positions of the dummy conductive patterns 13 to be plated and the number of the dummy conductive patterns 13 to be plated are reasonably set as needs. As a result, during electroplating, the electric fields at the positions where the second connection sub-segment B02 to be plated and the first connection line 151 to be plated are located are uniformly distributed, so that the thicknesses of the second connection sub-segment B02 and the first connection line 151 are uniform, thereby improving the yield of the wiring substrate 1 and ensuring the reliability of the wiring substrate 1.

Depending on different requirements, the dummy conductive patterns 13 may have different shapes. For example, the dummy conductive pattern 13 may include at least one dummy conductive portion 131.

On this basis, in some embodiments, the plurality of signal lines 12, the plurality of connection lines 15 and the dummy conductive portion(s) 131 are provided in the same layer. That is, the plurality of signal lines 12, the plurality of connection lines 15 and the at least one dummy conductive portion 131 may be formed simultaneously through a single electroplating process.

In this way, the dummy conductive portions 131 may make current densities on two adjacent signal lines 12 to be plated and current densities on two adjacent connection lines 15 to be plated close, so as to improve the thickness uniformity of the two adjacent signal lines 12 and the two adjacent connection lines 15.

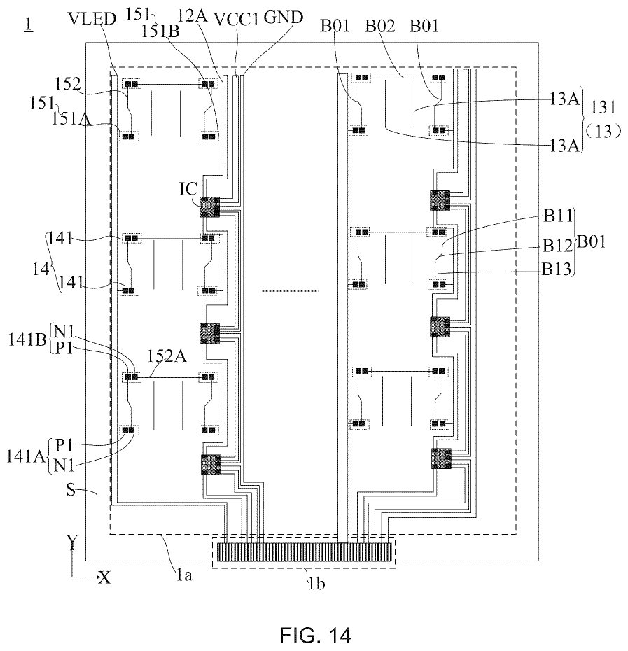

In this case, as shown in FIG. 14, in some embodiments, in a case where multiple dummy conductive portions 131 are provided between two adjacent first connection sub-segments B01, at least two dummy conductive portions 131 are insulated from each other.

The dummy conductive portions 131 may be disposed in various ways. The arrangement of the dummy conductive portions 131 will be described in detail below for a case where the dummy conductive pattern 13 is located between two adjacent first connection sub-segments B01 in the same second connection line 152.

In some embodiments, as shown in FIG. 14, in the first direction X, a dummy conductive pattern 13 located between two adjacent first connection sub-segments B01 in the same second connection line 152 includes at least one first dummy conductive portion 13A; and the first dummy conductive portion(s) 13A extend in the second direction Y. In the first direction X, the two adjacent first connection sub-segments B01 and the first dummy conductive portion(s) 13A are arranged at equal intervals.

In this way, during electroplating, the first dummy conductive portion(s) 13A to be plated may make the current densities on two adjacent first connection sub-segments B01 to be plated close, and make the electroplating efficiencies close, so as to make the thicknesses of the two adjacent first connection sub-segments B01 close, thereby improving the thickness uniformity of the two adjacent first connection sub-segments B01. In addition, the two adjacent first connection sub-segments B01 and the first dummy conductive portion(s) 13A are arranged at equal intervals. Therefore, when a mask is manufactured, shielding patterns of the mask corresponding to the two adjacent first connection sub-segments B01 and shielding patterns of the mask corresponding to the first dummy conductive portion(s) 13A are also arranged at equal intervals. Such a regular arrangement of a plurality of shielding patterns facilitates manufacture of the mask.

It can be understood that the first dummy conductive portion 13A to be plated refers to an intermediate state presented by the first dummy conductive portion 13A during forming the first dummy conductive portion 13A with a specific thickness in a specific region by electroplating.

It will be explained that the first dummy conductive portion 13A and the dummy conductive portion 131 have the same function and are only distinguished by name.

The number of the first dummy conductive portion(s) 13A may be one, two, three, four, five, or the like.

It will be explained that the dummy conductive pattern 13 being located between two adjacent first connection sub-segments B01 in the same second connection line 152 includes the following two cases.

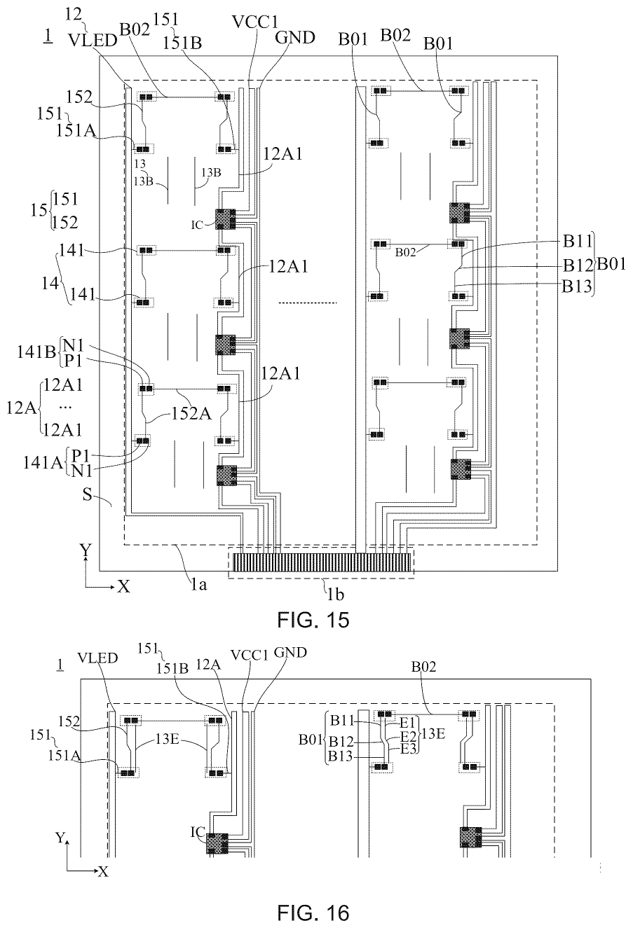

In the first case, as shown in FIG. 15, in the first direction X, the two adjacent first connection sub-segments B01 and the first dummy conductive portion(s) 13A do not overlap.

In the second case, as shown in FIG. 14, in the first direction X, projections of the two adjacent first connection sub-segments B01 and the first dummy conductive portion(s) 13A along the second direction Y at least partially overlap. It will be noted that here, “the projections of the two adjacent first connection sub-segments B01 and the first dummy conductive portion(s) 13A along the second direction Y at least partially overlapping” includes two situations: the projection of the first connection sub-segment B01 along the second direction Y partially overlaps with the projection of the first dummy conductive portion 13A along the second direction Y, and the projection of the first connection sub-segment B01 along the second direction Y completely overlaps with the projection of the first dummy conductive portion 13A along the second direction Y.

In this case, the first connection sub-segment B01 and the first dummy conductive portion 13A have a small distance. In this way, during electroplating, the first dummy conductive portion 13A to be plated can well divert the current on one, with a higher current density, of the two adjacent first connection sub-segments B01 to be plated, thereby making the electroplating efficiencies of the adjacent first connection sub-segments B01 close, making the thicknesses of the adjacent first connection sub-segments B01 close after the electroplating is completed, and making the thickness uniformity of the adjacent first connection sub-segments B01 great.

In some other embodiments, as shown in FIG. 16, in the first direction X, the dummy conductive pattern 13 located between two adjacent first connection sub-segments B01 in the same second connection line 152 includes at least one fifth dummy conductive portion 13E, and the fifth dummy conductive portion 13E extends in the second direction. In the first direction, the adjacent first connection sub-segments B01 and the fifth dummy conductive portion(s) 13E are arranged at intervals and are arranged at unequal intervals.

In this way, the fifth dummy conductive portion 13E to be plated may also be used to reduce the current on one, with a higher current density, of the two adjacent first connection sub-segments B01 to be plated, so that the current densities on the two adjacent first connection sub-segments B01 to be plated are close, and the electroplating efficiencies are close, thereby improving the thickness uniformity of the two adjacent first connection sub-segments B01.

The fifth dummy conductive portion 13E to be plated refers to an intermediate state presented by the fifth dummy conductive portion 13E during forming the fifth dummy conductive portion 13E with a specific thickness in a specific region by electroplating.

In some examples, there may be one, two or more fifth dummy conductive portions 13E between two adjacent first connection sub-segments B01.

For example, for a column of connection lines 15 at the left, there are two fifth dummy conductive portions 13E between two adjacent first connection sub-segments B01. As shown in FIG. 16, in the first direction X, a distance between the fifth dummy conductive portion 13E at the left and the first connection sub-segment B01 at the left is less than a distance between the two adjacent fifth dummy conductive portions 13E, and a distance between the fifth dummy conductive portion 13E at the right and the first connection sub-segment B01 at the right is less than the distance between the two adjacent fifth dummy conductive portions 13E.

In the first direction X, the distance between the fifth dummy conductive portion 13E at the left and the first connection sub-segment B01 at the left may be equal to the distance between the fifth dummy conductive portion 13E at the right and the first connection sub-segment B01 at the right.

Of course, the distance between the fifth dummy conductive portion 13E at the left and the first connection sub-segment B01 at the left may be unequal to the distance between the fifth dummy conductive portion 13E at the right and the first connection sub-segment B01 at the right.

For example, the distance between the fifth dummy conductive portion 13E at the left and the first connection sub-segment B01 at the left is in a range of 0.2 mm to 0.5 mm, inclusive. For example, the distance is 0.2 mm, 0.25 mm, 0.3 mm, 0.4 mm or 0.5 mm.

For example, the distance between the fifth dummy conductive portion 13E at the right and the first connection sub-segment B01 at the right is in a range of 0.2 mm to 0.5 mm, inclusive. For example, the distance is 0.2 mm, 0.25 mm, 0.3 mm, 0.4 mm or 0.5 mm.

Within this range, it may avoid a distance between the fifth dummy conductive portion 13E and the first connection sub-segment B01 being too small, thereby reducing a risk of electrostatic discharge (ESD) between the two and ensuring the normal work of the first connection sub-segment B01; moreover, it may also avoid the distance between the fifth dummy conductive portion 13E and the first connection sub-segment B01 being too large, thereby ensuring the accompanying plating effect of the fifth dummy conductive portion 13E.

In addition, the fifth dummy conductive portion 13E may be a line segment extending in the second direction. Alternatively, according to the shape of the first connection sub-segment B01, the fifth dummy conductive portion 13E has the same shape as the first connection sub-segment B01, that is, the two are of the same shapes. The specific arrangement of the fifth dummy conductive portion 13E will be described below for a case where a pad unit 14 includes four device pad groups 141, six device pad groups 141, and nine device pad groups 141.

For example, in a case where a pad unit 14 includes four device pad groups 141, in a left column of connection lines 15 shown in FIG. 16, a first arrangement of the fifth dummy conductive portions 13E is that the fifth dummy conductive portions 13E are line segments extending in the second direction.

Alternatively, in a right column of connection lines 15 shown in FIG. 16, a second arrangement of the fifth dummy conductive portions 13E is that the fifth dummy conductive portion 13E at the left and the first connection sub-segment B01 at the left are consistent in direction, and the fifth dummy conductive portion 13E at the right and the first connection sub-segment B01 at the right are consistent in direction. That is, in the second direction, the fifth dummy conductive portion 13E at the left includes a first straight dummy sub-portion E1, a first inclined dummy sub-portion E2 and a second straight dummy sub-portion E3 that are sequentially connected from top to bottom. The first straight dummy sub-portion E1 at the left is parallel to the first straight section B11 at the left, the first inclined dummy sub-portion E2 at the left is parallel to the first inclined section B12 at the left, and the second straight dummy sub-portion E3 at the left is parallel to the second straight section B13 at the left.

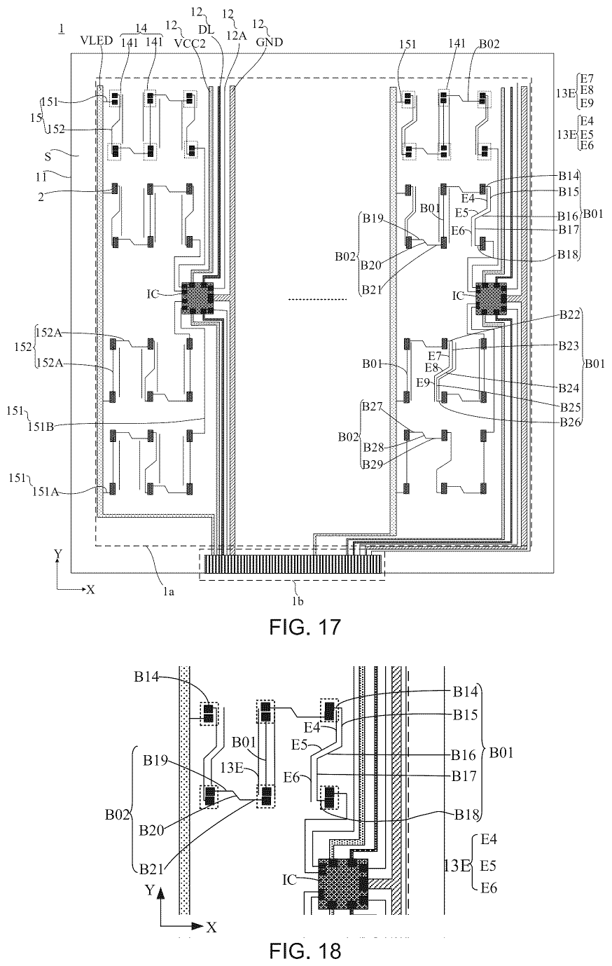

For example, as shown in FIG. 17, in a case where a pad unit 14 includes six device pad groups 141, an arrangement of the fifth dummy conductive portions 13E is that the fifth dummy conductive portions 13E are line segments extending in the second direction.

Alternatively, as shown in FIG. 18, another arrangement of the fifth dummy conductive portions 13E is that the fifth dummy conductive portions 13E and the first connection sub-segments B01 are consistent in direction. The description that the fifth dummy conductive portions 13E and the first connection sub-segments B01 are consistent in direction will be made exemplarily.

For example, in a pad unit 14 located on an upper side of the driver chip IC in the second direction, for a first connection sub-segment B01 at the middle, two fifth dummy conductive portions 13E located at both sides of the first connection sub-segment B01 in the first direction are line segments extending in the second direction.

As shown in FIG. 17, for first connection sub-segments B01 at the left and right, the fifth dummy conductive portions 13E each include a third straight dummy sub-portion E4, a second inclined dummy sub-portion E5 and a fourth straight dummy sub-portion E6 that are sequentially connected from top to bottom. The third straight dummy sub-portion E4 is parallel to the fourth straight section B15, the second inclined dummy sub-portion E5 is parallel to the second inclined section B16, and the fourth straight dummy sub-portion E6 is parallel to the fifth straight section B17.

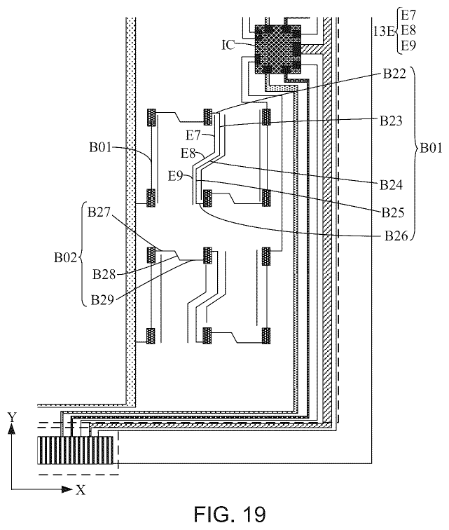

As another example, in the second direction, as shown in FIGS. 17 and 19, in a pad unit 14 located on a lower side of the driver chip IC, for a first connection sub-segment B01 at the middle, as shown in FIG. 19, two fifth dummy conductive portions 13E located at both sides of the first connection sub-segment B01 in the first direction each include a fifth straight dummy sub-portion E7, a third inclined dummy sub-portion E8 and a sixth straight dummy sub-portion E9 that are sequentially connected from top to bottom. The fifth straight dummy sub-portion E7 is parallel to the tenth straight section B23, the third inclined dummy sub-portion E8 is parallel to the fourth inclined section B24, and the sixth straight dummy sub-portion E9 is parallel to the eleventh straight section B25.

For first connection sub-segments B01 at the left and right, the fifth dummy conductive portions 13E are both line segments extending in the second direction.

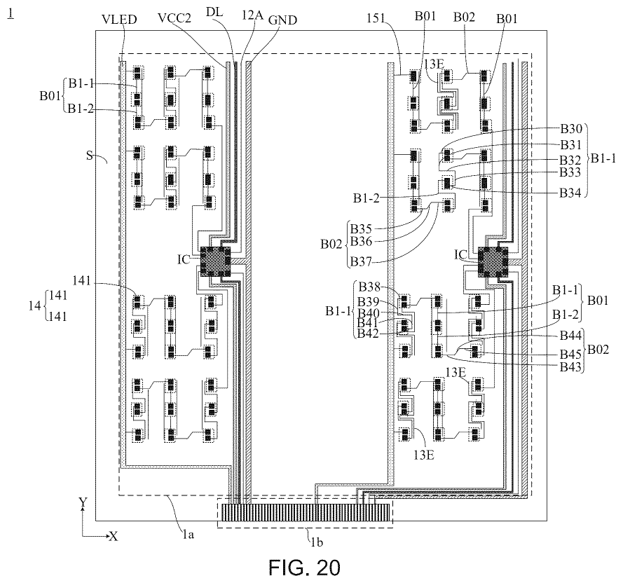

For example, in a case where a pad unit 14 includes nine device pad groups 141, in left column of connection lines 15 shown in FIG. 20, an arrangement of the fifth dummy conductive portions 13E is that the fifth dummy conductive portions 13E are line segments extending in the second direction.

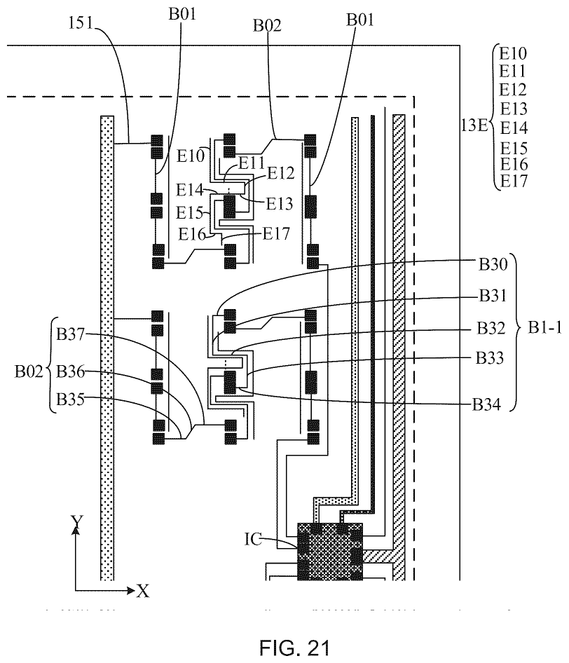

Alternatively, as shown in FIG. 21, another arrangement of the fifth dummy conductive portions 13E is that the fifth dummy conductive portions 13E and the first connection sub-segments B01 are consistent in direction in the second direction. The description that the fifth dummy conductive portions 13E and the first connection sub-segments B01 are consistent in direction will be made exemplarily.

For example, as shown in FIGS. 20 and 21, in the second direction, a pad unit 14 is located on an upper side of the driver chip IC.

For the first section B1-1 (on the upper side) and the second section B1-2 of the first connection sub-segment B01 at the middle, in the first direction, two fifth dummy conductive portions 13E located at both sides of the first connection sub-segment B01 each include a first connecting dummy sub-portion E10, a second connecting dummy sub-portion E11, a third connecting dummy sub-portion E12, a fourth connecting dummy sub-portion E13, a fifth connecting dummy sub-portion E14, a sixth connecting dummy sub-portion E15, a seventh connecting dummy sub-portion E16 and an eighth connecting dummy sub-portion E17 that are sequentially connected from top to bottom. For the first section B1-1 of the first connection sub-segment B01, the first connecting dummy sub-portion E10 is parallel to the second connecting section B31, the second connecting dummy sub-portion E11 is parallel to the third connecting section B32, the third connecting dummy sub-portion E12 is parallel to the fourth connecting section B33, and the fourth connecting dummy sub-portion E13 is parallel to the fifth connecting section B34. For the second section B1-2 of the first connection sub-segment B01, the fifth connecting dummy sub-portion E14 is parallel to the first connecting section B30, the sixth connecting dummy sub-portion E15 is parallel to the second connecting section B31, the seventh connecting dummy sub-portion E16 is parallel to the third connecting section B32, and the eighth connecting dummy sub-portion E17 is parallel to the fourth connecting section B33.

On this basis, as shown in FIG. 21, for example, ends of the fourth connecting dummy sub-portion E13 and the fifth connecting dummy sub-portion E14 that are close to each other are connected together.

For first connection sub-segments B01 at the left and right, the fifth dummy conductive portions 13E are both line segments extending in the second direction.

As another example, in the second direction, a pad unit 14 is located on a lower side of the driver chip IC.

For the first connection sub-segment B01 at the middle, as shown in FIG. 22, two fifth dummy conductive portions 13E located at both sides of the first connection sub-segment B01 in the first direction are line segments extending in the second direction.

For first sections B1-1 (on the upper side) and second sections B1-2 (on the lower side) of the first connection sub-segments B01 at the left and right, the fifth dummy conductive portions 13E for accompanying plating of the two each include a ninth connecting dummy sub-portion E18, a tenth connecting dummy sub-portion E19, an eleventh connecting dummy sub-portion E20, a twelfth connecting dummy sub-portion E21, a thirteenth connecting dummy sub-portion E22, a fourteenth connecting dummy sub-portion E23, a fifteenth connecting dummy sub-portion E24 and a sixteenth connecting dummy sub-portion E25 that are sequentially connected from top to bottom. The ninth connecting dummy sub-portion E18 is parallel to the ninth connecting section B39, the tenth connecting dummy sub-portion E19 is parallel to the tenth connecting section B40, the eleventh connecting dummy sub-portion E20 is parallel to the eleventh connecting section B41, and the twelfth connecting dummy sub-portion E21 is parallel to the twelfth connecting section B42. The thirteenth connecting dummy sub-portion E22 is parallel to the eighth connecting section B38, the fourteenth connecting dummy sub-portion E23 is parallel to the ninth connecting section B39, the fifteenth connecting dummy sub-portion E24 is parallel to the tenth connecting section B40, and the sixteenth connecting dummy sub-portion E25 is parallel to the eleventh connecting section B41.

On this basis, as shown in FIG. 22, for example, ends of the twelfth connecting dummy sub-portion E21 and the thirteenth connecting dummy sub-portion E22 that are close to each other may be connected together.

Then, the arrangement of the dummy conductive pattern 13 will be described in detail for a case where the dummy conductive pattern 13 is located between the second connection sub-segment B02 and the first connection line 151 that are adjacent, and the second connection sub-segment B02 and the first connection line 151 that are adjacent belong to two adjacent connection lines 15.

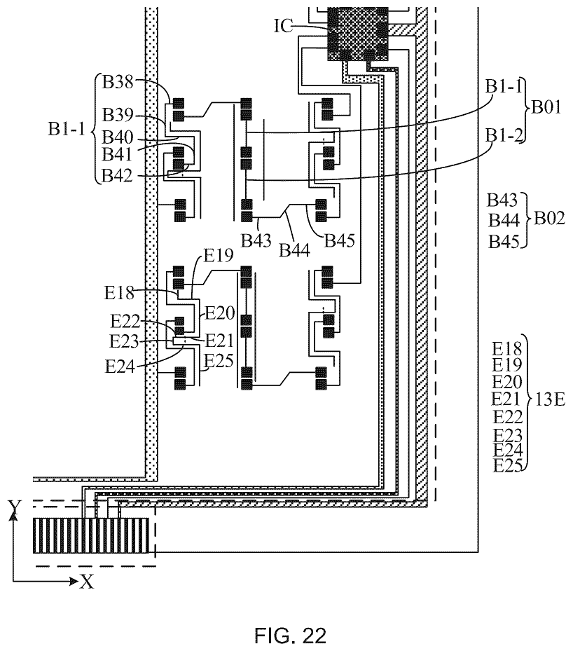

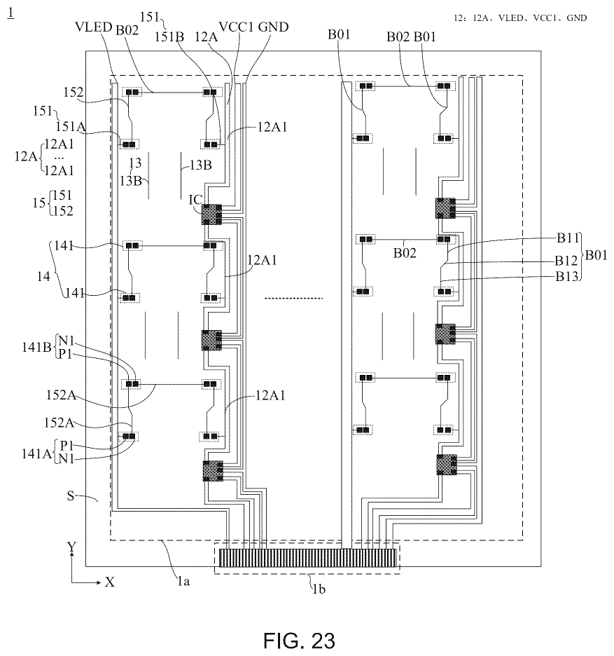

In some embodiments, as shown in FIG. 23, in the second direction Y, in a case where the dummy conductive pattern 13 is located between the second connection sub-segment B02 and the first connection line 151 that are adjacent, and the second connection sub-segment B02 and the first connection line 151 that are adjacent belong to two adjacent connection lines 15, the dummy conductive pattern 13 includes at least one second dummy conductive portion 13B, and the second dummy conductive portion(s) 13B extend in the second direction Y. In the first direction X, the two adjacent signal lines 12 and the second dummy conductive portion(s) 13B are arranged at equal intervals.

In this way, during electroplating, the second dummy conductive portion(s) 13B to be plated are provided, and the two adjacent signal lines 12 and the second dummy conductive portion(s) 13B are arranged at equal intervals. As a result, the current densities on the two adjacent signal lines 12 to be plated may be made close, and the electroplating efficiencies may be made close, so as to make the thicknesses of the two adjacent signal lines 12 close, thereby improving the thickness uniformity of the two adjacent signal lines 12. In addition, the two adjacent signal lines 12 and the second dummy conductive portion(s) 13B are arranged at equal intervals. Therefore, when the mask is manufactured, shielding patterns of the mask corresponding to the two adjacent signal lines 12 and shielding patterns of the mask corresponding to the second dummy conductive portion (a) 13B are also arranged at equal intervals. Such a regular arrangement of a plurality of shielding patterns may facilitate manufacture of the mask.

The second dummy conductive portion 13B to be plated refers to an intermediate state presented by the second dummy conductive portion 13B during forming the second dummy conductive portion 13B with a specific thickness in a specific region by electroplating.

In addition, there may be one, two or more second dummy conductive portions 13B.

It can be understood that in a case where a driver chip IC drives a pad unit 14, for example, a pad unit 14 includes four device pad groups 141, as mentioned above, the two adjacent signal lines 12 and the second dummy conductive portion(s) 13B are arranged at equal intervals in the first direction X, where the two adjacent signal lines 12 refer to a first signal line VLED and an addressing signal line 12A. Since the addressing signal line 12A includes a plurality of addressing signal sub-segments 12A1 arranged in the second direction, the two adjacent signal lines 12 may be understood as the first signal line VLED and the addressing signal sub-segment 12A1.

On this basis, as shown in FIG. 23, for layout requirements, the addressing signal sub-segment 12A1 needs to be bent when connected to the driver chip IC. In this case, a distance between two adjacent signal lines 12 refers to the minimum spacing between the first signal line VLED and the addressing signal line 12A.

In a case where a driver chip IC drives four pad units 14, for example, a pad unit 14 includes six device pad groups 141, as mentioned above, the two adjacent signal lines 12 and the second dummy conductive portion(s) 13B are arranged at equal intervals in the first direction X, where the two adjacent signal lines 12 refer to a first signal line VLED and a first voltage line VCC1. As another example, a pad unit 14 includes nine device pad groups 141, and the two adjacent signal lines 12 refer to the first signal line VLED and a second voltage line VCC2.

In some examples, as shown in FIG. 23, projections of the second dummy conductive portion 13B and the first connection sub-segment B01 along the second direction Y are at least partially staggered.

It will be noted that here, “the projections of the second dummy conductive portion 13B and the first connection sub-segment B01 along the second direction Y being at least partially staggered” includes two situations: the projections of the second dummy conductive portion 13B and the first connection sub-segment B01 along the second direction Y are staggered, and the projections of the second dummy conductive portion 13B and the first connection sub-segment B01 along the second direction Y are partially overlapped and partially staggered.

In this way, in a case where the second dummy conductive portion 13B and the first connection sub-segment B01 are located in the same conductive layer, in a process of forming the second dummy conductive portion 13B and the first connection sub-segment B01 by electroplating, mutual interference between the first connection sub-segment B01 to be plated and the second dummy conductive portion 13B to be plated may be avoided to ensure that the first connection sub-segment B01 and the second dummy conductive portion 13B formed are insulated from each other.

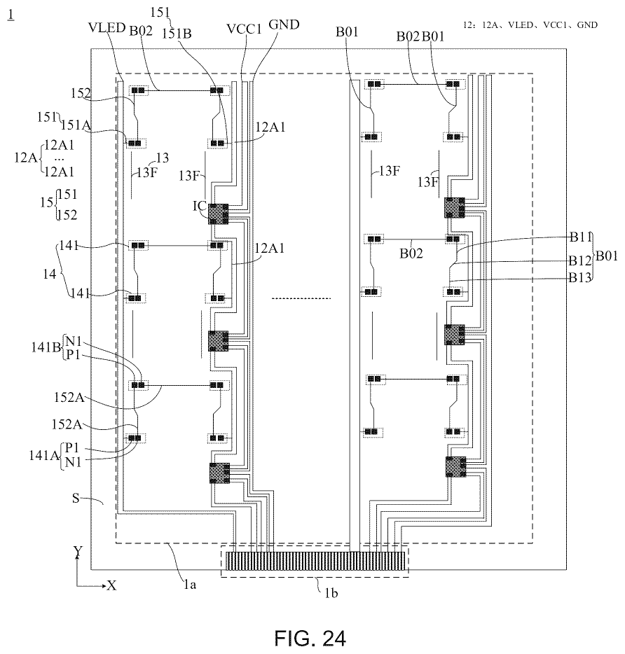

In some other embodiments, as shown in FIG. 24, in the second direction Y, in a case where the dummy conductive pattern 13 is located between the second connection sub-segment B02 and the first connection line 151 that are adjacent, and the second connection sub-segment B02 and the first connection line 151 that are adjacent belong to two adjacent connection lines 15, the dummy conductive pattern 13 includes at least one sixth dummy conductive portion 13F, and the sixth dummy conductive portion(s) 13F extend in the second direction Y. In the first direction X, the adjacent signal lines 12 and the sixth dummy conductive portion(s) 13F are arranged at intervals and are arranged at unequal intervals.

In this way, the sixth dummy conductive portion 13F to be plated may also be used to divert the current on one, with a higher current density, of two adjacent signal lines to be plated, so as to make the current densities on the two adjacent signal lines to be plated close and make the electroplating efficiencies close, thereby improving the thickness uniformity of the two adjacent signal lines 12.

The sixth dummy conductive portion 13F to be plated refers to an intermediate state presented by the sixth dummy conductive portion 13F during forming the sixth dummy conductive portion 13F with a specific thickness in a specific region by electroplating.

In some examples, there may be one, two or more sixth dummy conductive portions 13F between the second connection sub-segment B02 and the first connection line 151 that are adjacent.

For example, in a case where a pad unit 14 includes four device pad groups 141, there are two sixth dummy conductive portions 13F between the second connection sub-segment B02 and the first connection line 151 that are adjacent. As shown in FIG. 24, in the first direction, a distance between a sixth dummy conductive portion 13F at the left and a signal line 12 (the first signal line VLED) at the left is less than a distance between the two adjacent sixth dummy conductive portions 13F, and a distance between a sixth dummy conductive portion 13F at the right and the addressing signal line 12A at the right is less than the distance between the two adjacent sixth dummy conductive portions 13F.

In the first direction, the distance between the sixth dummy conductive portion 13F at the left and the signal line 12 (the first signal line VLED) at the left may be equal to the distance between the sixth dummy conductive portion 13F at the right and the addressing signal line 12A at the right.

Of course, the distance between the sixth dummy conductive portion 13F at the left and the signal line 12 (the first signal line VLED) at the left may be unequal to the distance between the sixth dummy conductive portion 13F at the right and the addressing signal line 12A at the right.

For example, the distance between the sixth dummy conductive portion 13F at the left and the signal line 12 (the first signal line VLED) at the left is in a range of 0.2 mm to 0.5 mm, inclusive. For example, the distance is 0.2 mm, 0.23 mm, 0.3 mm, 0.4 mm or 0.5 mm.

For example, the distance between the sixth dummy conductive portion 13F at the right and the addressing signal line 12A at the right is in a range of 0.2 mm to 0.5 mm, inclusive. For example, the distance is 0.2 mm, 0.23 mm, 0.3 mm, 0.4 mm or 0.5 mm.

Within this range, it may avoid a distance between the sixth dummy conductive portion 13F and the signal line 12 being too small, thereby reducing a risk of electrostatic discharge (ESD) between the two and ensuring the normal work of the signal line 12; moreover, it may also avoid the distance between the sixth dummy conductive portion 13F and the signal line 12 being too large, thereby ensuring the accompanying plating effect of the sixth dummy conductive portion 13F.

The arrangement of the dummy conductive pattern 13 will be described in detail for a case where the dummy conductive pattern 13 is located between the second connection sub-segment B02 and the first connection line 151 that are adjacent, and the second connection sub-segment B02 and the first connection line 151 that are adjacent belong to two adjacent connection lines 15.

In some embodiments, as shown in FIG. 25, in the second direction Y, in a case where the dummy conductive pattern 13 is located between the second connection sub-segment B02 and the first connection line 151 that are adjacent, and the second connection sub-segment B02 and the first connection line 151 that are adjacent belong to two adjacent connection lines 15, the dummy conductive pattern 13 further includes at least one third dummy conductive portion 13C; and the third dummy conductive portion(s) 13C extend in the first direction X. In the second direction Y, the second connection sub-segment B02 and the first connection line 151 that are adjacent, and the third dummy conductive portion(s) 13C are arranged at equal intervals.

In this way, during electroplating, the third dummy conductive portion(s) 13C to be plated may make the current densities on the second connection sub-segment B02 and the first connection line 151 that are adjacent close, and make the electroplating efficiencies close, so as to make the thicknesses of the second connection sub-segment B02 and the first connection line 151 that are adjacent close, thereby improving the thickness uniformity of the second connection sub-segment B02 and the first connection line 151 that are adjacent. In addition, the second connection sub-segment B02 and the first connection line 151 that are adjacent, and the third dummy conductive portion(s) 13C are arranged at equal intervals. Therefore, when a mask is manufactured, shielding patterns of the mask corresponding to the second connection sub-segment B02 and the first connection line 151 that are adjacent and shielding patterns of the mask corresponding to the third dummy conductive portion(s) 13C are also arranged at equal intervals. Such a regular arrangement of a plurality of shielding patterns may facilitate manufacture of the mask.

It can be understood that the third dummy conductive portion 13C to be plated refers to an intermediate state presented by the third dummy conductive portion 13C during forming the third dummy conductive portion 13C with a specific thickness in a specific region by electroplating.

It will be explained that a case where the dummy conductive pattern 13 is located between the second connection sub-segment B02 and the first connection line 151 that are adjacent, and the second connection sub-segment B02 and the first connection line 151 that are adjacent belong to two adjacent connection lines 15 includes two situations. In the first situation, projections of the dummy conductive pattern 13, the second connection sub-segment B02 and the first connection line 151 in the first direction X at least partially overlap. In the second situation, projections of the dummy conductive pattern 13, the second connection sub-segment B02 and the first connection line 151 in the first direction X do not overlap.

There may be one, two or more third dummy conductive portions 13C.

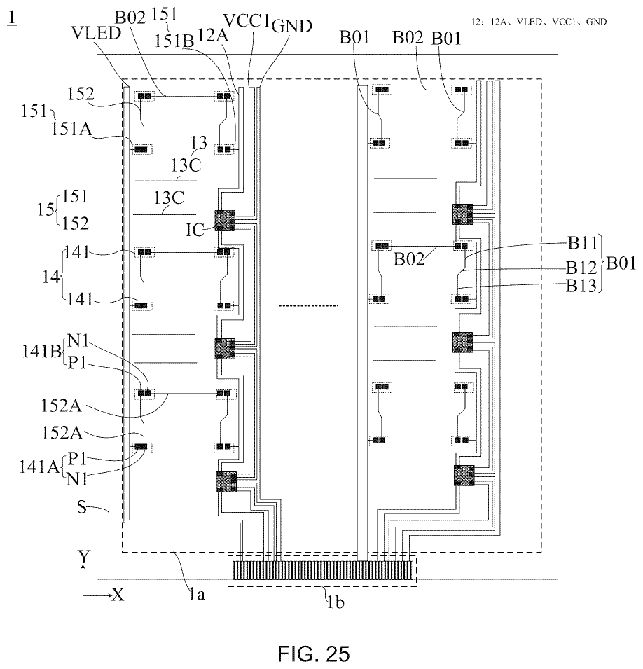

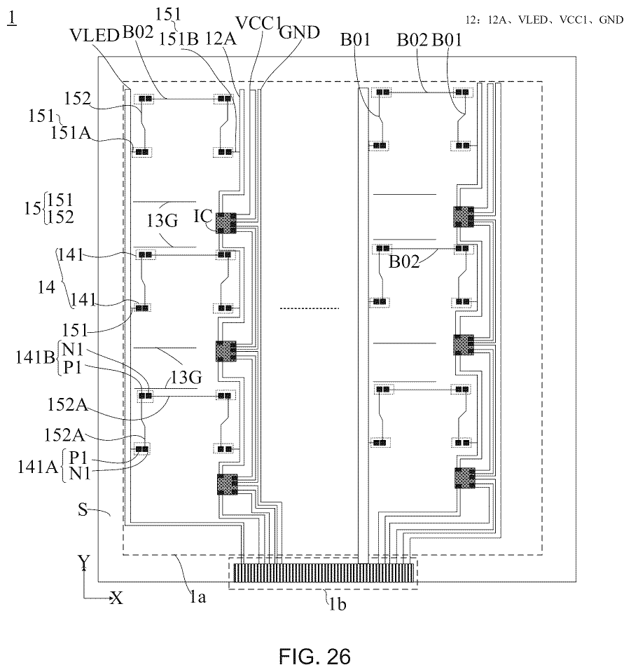

In some other embodiments, as shown in FIG. 26, in the second direction Y, in a case where the dummy conductive pattern 13 is located between the second connection sub-segment B02 and the first connection line 151 that are adjacent, and the second connection sub-segment B02 and the first connection line 151 that are adjacent belong to two adjacent connection lines 15, the dummy conductive pattern 13 further includes at least one seventh dummy conductive portion 13G; and the seventh dummy conductive portion(s) 13G extend in the first direction X. In the second direction Y, the second connection sub-segment B02 and the first connection line 151 that are adjacent, and the seventh dummy conductive portion(s) 13G are arranged at unequal intervals.

In this way, the seventh dummy conductive portion 13G to be plated may also be used to divert the current on one, with a higher current density, of the second connection sub-segment B02 to be plated and the first connection line 151 to be plated that are adjacent, so as to make the current densities on the second connection sub-segment B02 to be plated and the first connection line 151 to be plated that are adjacent close, and make the electroplating efficiencies close, thereby improving the thickness uniformity of the second connection sub-segment B02 and the first connection line 151 that are adjacent.

The seventh dummy conductive portion 13G to be plated refers to an intermediate state presented by the seventh dummy conductive portion 13G during forming the seventh dummy conductive portion 13G with a specific thickness in a specific region by electroplating.

In addition, there may be one, two or more seventh dummy conductive portions 13G.

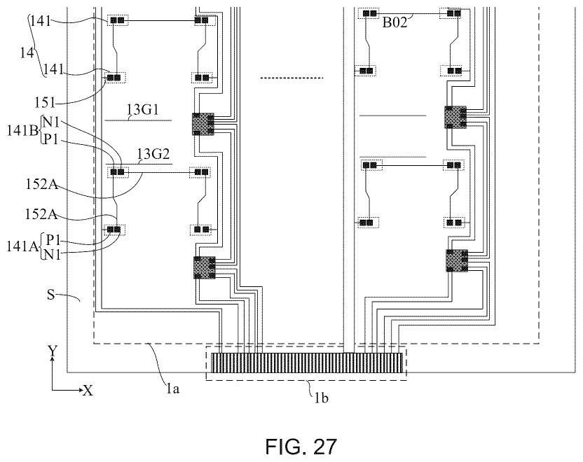

For example, as shown in FIG. 27, in a case where a pad unit 14 includes four device pad groups 141, two seventh dummy conductive portions 13G1 and 13G2 are provided. The seventh dummy conductive portion 13G1 is located on an upper side of the seventh dummy conductive portion 13G2. The second connection sub-segment B02 and the first connection line 151 that are adjacent, and the seventh dummy conductive portion 13G1 are arranged at equal intervals. The seventh dummy conductive portion 13G2 is provided proximate to the second connection sub-segment B02, and a distance between the seventh dummy conductive portion 13G2 and the second connection sub-segment B02 is in a range of 0.2 mm to 0.5 mm, inclusive. For example, the distance is 0.2 mm, 0.23 mm, 0.35 mm, 0.4 mm or 0.5 mm.

The arrangement of the dummy conductive pattern 13 will be described in detail for a case where the dummy conductive pattern 13 is located between the second connection sub-segment B02 and the first connection line 151 that are adjacent, and the second connection sub-segment B02 and the first connection line 151 belong to the same connection lines 15.

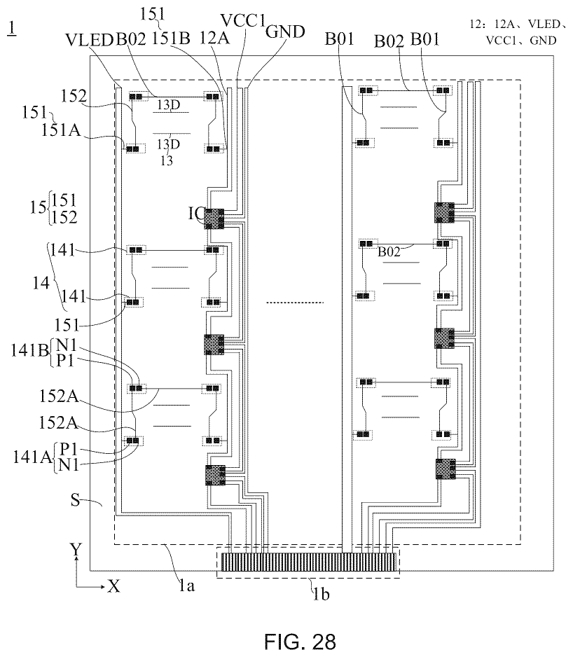

In some embodiments, as shown in FIG. 28, in the second direction Y, in a case where the dummy conductive pattern 13 is located between the second connection sub-segment B02 and the first connection line 151 that are adjacent, and the second connection sub-segment B02 and the first connection line 151 belong to the same connection line 15, the dummy conductive pattern 13 further includes at least one fourth dummy conductive portion 13D; and the fourth dummy conductive portion(s) 13D extend in the first direction X. In the second direction Y, the second connection sub-segment B02, the first connection line 151 and the fourth dummy conductive portion(s) 13D are arranged at equal intervals.

In this way, during electroplating, the fourth dummy conductive portion(s) 13D to be plated may make the current densities on the second connection sub-segment B02 and the first connection line 151 that are adjacent close, and make the electroplating efficiencies close, so as to make the thicknesses of the second connection sub-segment B02 and the first connection line 151 that are adjacent close, thereby improving the thickness uniformity of the second connection sub-segment B02 and the first connection line 151 that are adjacent. In addition, the second connection sub-segment B02 and the first connection line 151 that are adjacent, and the fourth dummy conductive portion(s) 13D are arranged at equal intervals. Therefore, when a mask is manufactured, shielding patterns of the mask corresponding to the second connection sub-segment B02 and the first connection line 151 that are adjacent and shielding patterns of the mask corresponding to the fourth dummy conductive portion(s) 13D are also arranged at equal intervals. Such a regular arrangement of a plurality of shielding patterns may facilitate manufacture of the mask.

It can be understood that the fourth dummy conductive portion 13D to be plated refers to an intermediate state presented by the fourth dummy conductive portion 13D during forming the fourth dummy conductive portion 13D with a specific thickness in a specific region by electroplating.

It will be explained that the description of “the dummy conductive pattern 13 being located between the second connection sub-segment B02 and the first connection line 151 that are adjacent” means that the dummy conductive pattern 13 is located between an extension line of the second connection sub-segment B02 and an extension line of the first connection line 151 that are adjacent, which specifically include two situations. In the first situation, in the second direction, the dummy conductive pattern 13, the second connection sub-segment B02 and the first connection line 151 at least partially overlap. In the second situation, in the second direction, the dummy conductive pattern 13, the second connection sub-segment B02 and the first connection line 151 do not overlap.

There may be one, two or more fourth dummy conductive portions 13D. FIG. 28 shows two fourth dummy conductive portions 13D provided between the second connection sub-segment B02 and the first connection line 151 that are adjacent.

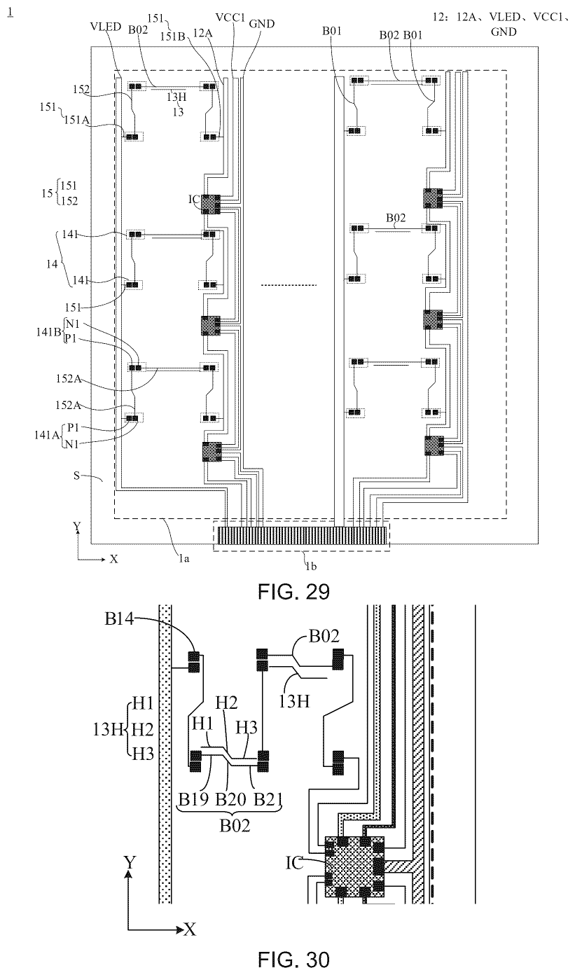

In some other embodiments, as shown in FIG. 29, in the second direction Y, in a case where the dummy conductive pattern 13 is located between the second connection sub-segment B02 and the first connection line 151 that are adjacent, and the second connection sub-segment B02 and the first connection line 151 belong to the same connection line 15, the dummy conductive pattern 13 further includes at least one eighth dummy conductive portion 13H; and the eighth dummy conductive portion(s) 13H extend in the first direction X. In the second direction Y, the second connection sub-segment B02, the first connection line 151 and the eighth dummy conductive portion(s) 13H are arranged at unequal intervals.

In this way, the eighth dummy conductive portion(s) 13H to be plated may make the current densities on the second connection sub-segment B02 and the first connection line 151 that are adjacent close, and make the electroplating efficiencies close, so as to make the thicknesses of the second connection sub-segment B02 and the first connection line 151 that are adjacent close, thereby improving the thickness uniformity of the second connection sub-segment B02 and the first connection line 151 that are adjacent.

The eighth dummy conductive portion 13H to be plated refers to an intermediate state presented by the eighth dummy conductive portion 13H during forming the eighth dummy conductive portion 13H with a specific thickness in a specific region by electroplating.

In some examples, there may be one, two or more eighth dummy conductive portions 13H between the second connection sub-segment B02 and the first connection line 151 that are adjacent.

For example, as shown in FIG. 29, in a case where a pad unit 14 includes four device pad groups 141, there is one eighth dummy conductive portion 13H between the second connection sub-segment B02 and the first connection line 151 that are adjacent. In the same pad unit 14, in the second direction, a distance between the eighth dummy conductive portion 13H and the second connection sub-segment B02 is less than a distance between the eighth dummy conductive portion 13H and the first connection line 151.

For example, the distance between the eighth dummy conductive portion 13H and the second connection sub-segment B02 is in a range of 0.2 mm to 0.5 mm, inclusive. For example, the distance is 0.2 mm, 0.23 mm, 0.35 mm, 0.45 mm or 0.5 mm.

For example, in a case where a pad unit 14 includes six device pad groups 141, as shown in FIG. 30, there is one eighth dummy conductive portion 13H between a second connection sub-segment B02 at the left and a first connection line 151 that are adjacent. In the same pad unit 14, in the second direction, a distance between the eighth dummy conductive portion 13H and the second connection sub-segment B02 at the left is less than a distance between the eighth dummy conductive portion 13H and the first connection line 151.

For example, the distance between the eighth dummy conductive portion 13H and the second connection sub-segment B02 is in a range of 0.2 mm to 0.5 mm, inclusive. For example, the distance is 0.2 mm, 0.23 mm, 0.35 mm, 0.45 mm or 0.5 mm.

It will be explained that in this case, the eighth dummy conductive portion 13H may have two different forms.

In the first form, the eighth dummy conductive portion 13H is a line segment extending in the first direction.

In the second form, for a pad unit 14 on the upper or lower side of the driver chip IC, as shown in FIG. 30, the eighth dummy conductive portion 13H includes a seventh straight dummy sub-portion H1, a fourth inclined dummy sub-portion H2 and an eighth straight dummy sub-portion H3 that are sequentially connected from left to right. The seventh straight dummy sub-portion H1 is parallel to the seventh straight section B19, the fourth inclined dummy sub-portion H2 is parallel to the third inclined section B20, the eighth straight dummy sub-portion H3 is parallel to the eighth straight section B21, and the seventh straight dummy sub-portion H1 is located on the upper side of the eighth straight dummy sub-portion H3.

For example, a pad unit 14 includes nine device pad groups 141.

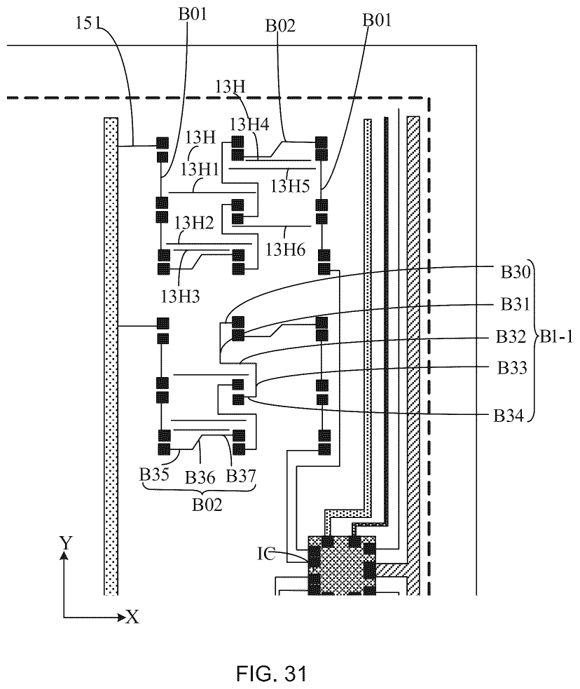

For example, for a pad unit 14 on the upper side of the driver chip IC, as shown in FIG. 31, three eighth dummy conductive portions 13H1, 13H2 and 13H3 are provided between the second connection sub-segment B02 at the left and the first connection line 151 that are adjacent. The three eighth dummy conductive portions 13H1, 13H2 and 13H3 are arranged sequentially at intervals from top to bottom.

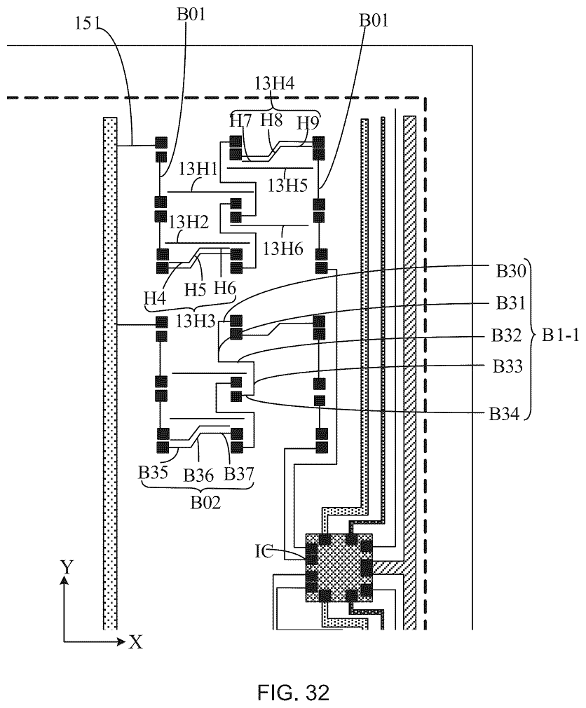

The eighth dummy conductive portion 13H1 is a line segment extending in the first direction, and the eighth dummy conductive portion 13H1 is located between a third connecting section B32 and a fifth connecting section B34 of the first section B1-1. The eighth dummy conductive portion 13H2 is a line segment extending in the first direction, and is located between a third connecting section B32 and a fifth connecting section B34 of the second section B1-2. In the second direction, the eighth dummy conductive portion 13H3 is located between the eighth dummy conductive portion 13H2 and the second connection sub-segment B02. In addition, the eighth dummy conductive portion 13H3 may be a line segment extending in the first direction. Alternatively, as shown in FIG. 32, the eighth dummy conductive portion 13H3 may include a ninth straight dummy sub-portion H4, a fifth inclined dummy sub-portion H5 and a tenth straight dummy sub-portion H6 that are sequentially connected from left to right. The ninth straight dummy sub-portion H4 is parallel to the sixth connecting section B35, the fifth inclined dummy sub-portion H5 is parallel to the sixth inclined section B36, and the tenth straight dummy sub-portion H6 is parallel to the seventh connecting section B37.

In the second direction, the third connecting section B32 and the fifth connecting section B34 of the first section B1-1 and the eighth dummy conductive portion 13H1 are arranged at equal intervals. And/or, the third connecting section B32 and the fifth connecting section B34 of the second section B1-2 and the eighth dummy conductive portion 13H2 are arranged at equal intervals.

In addition, in the second direction, a distance between the eighth dummy conductive portion 13H3 and the second connection sub-segment B02 is in a range of 0.2 mm to 0.5 mm, inclusive. For example, the distance is 0.2 mm, 0.22 mm, 0.35 mm, 0.45 mm or 0.5 mm.

For a pad unit 14 on the upper side of the driver chip IC, as shown in FIG. 32, three eighth dummy conductive portions 13H4, 13H5 and 13H6 are provided between the second connection sub-segment B02 at the right and the first connection line 151 that are adjacent. The eighth dummy conductive portion 13H4 may be a line segment extending in the first direction. Alternatively, as shown in FIG. 32, the eighth dummy conductive portion 13H4 may include an eleventh straight dummy sub-portion H7, a sixth inclined dummy sub-portion H8 and a twelfth straight dummy sub-portion H9 that are sequentially connected from left to right. The eleventh straight dummy sub-portion H7 is parallel to the sixth connecting section B35, the sixth inclined dummy sub-portion H8 is parallel to the sixth inclined section B36, and the twelfth straight dummy sub-portion H9 is parallel to the seventh connecting section B37. The eleventh straight dummy sub-portion H7 is located on the lower side of the twelfth straight dummy sub-portion H9. The eighth dummy conductive portion 13H5 is located between a first connecting section B30 and a third connecting section B32 of the first section B1-1. The eighth dummy conductive portion 13H6 is located between a first connecting section B30 and a third connecting section B32 of the second section B1-2.

In the second direction, the first connecting section B30 and the third connecting section B32 of the first section B1-1 and the eighth dummy conductive portion 13H5 are arranged at equal intervals. And/or, the first connecting section B30 and the third connecting section B32 of the second section B1-2 and the eighth dummy conductive portion 13H6 are arranged at equal intervals.

In addition, in the second direction, a distance between the eighth dummy conductive portion 13H4 and the second connection sub-segment B02 is in a range of 0.2 mm to 0.5 mm, inclusive. For example, the distance is 0.2 mm, 0.22 mm, 0.36 mm, 0.45 mm or 0.5 mm.

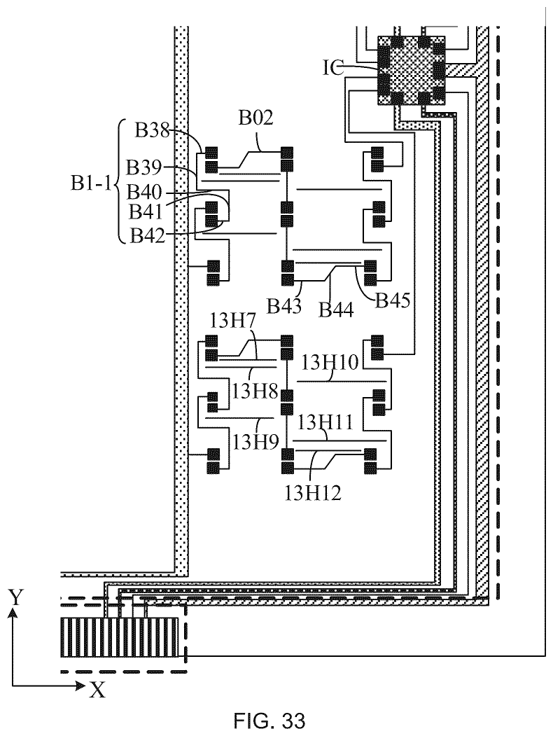

As another example, for a pad unit 14 on the lower side of the driver chip IC, as shown in FIG. 33, three eighth dummy conductive portions 13H7, 13H8 and 13H9 are provided between the second connection sub-segment B02 at the left and the first connection line 151 that are adjacent. The three eighth dummy conductive portions 13H7, 13H8 and 13H9 are arranged sequentially at intervals from top to bottom.

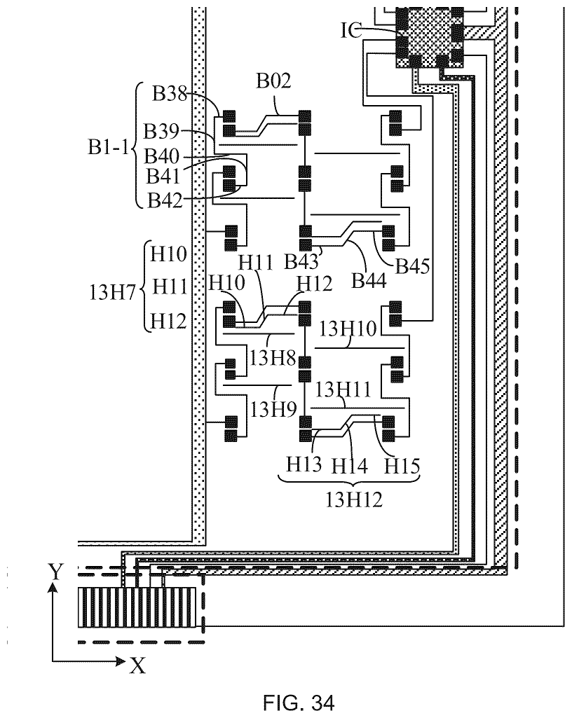

As shown in FIG. 33, the eighth dummy conductive portion 13H7 may be a line segment extending in the first direction X. Alternatively, as shown in FIG. 34, the eighth dummy conductive portion 13H7 may include a thirteenth straight dummy sub-portion H10, a seventh inclined dummy sub-portion H11 and a fourteenth straight dummy sub-portion H12 that are sequentially connected from left to right. The thirteenth straight dummy sub-portion H10 is parallel to the sixth connecting section B35, the seventh inclined dummy sub-portion H11 is parallel to the sixth inclined section B36, and the fourteenth straight dummy sub-portion H12 is parallel to the seventh connecting section B37. The thirteenth straight dummy sub-portion H10 is located on the lower side of the fourteenth straight dummy sub-portion H12. The eighth dummy conductive portion 13H8 is located between an eighth connecting section B38 and a tenth connecting section B40 of the first section B1-1. The eighth dummy conductive portion 13H9 is located between an eighth connecting section B38 and a tenth connecting section B40 of the second section B1-2. The eighth dummy conductive portion 13H8 and the eighth dummy conductive portion 13H9 may be line segments extending in the first direction X.

In the second direction, the eighth connecting section B38 and the tenth connecting section B40 of the first section B1-1 and the eighth dummy conductive portion 13H8 are arranged at equal intervals. And/or, the eighth connecting section B38 and the tenth connecting section B40 of the second section B1-2 and the eighth dummy conductive portion 13H9 are arranged at equal intervals.

In addition, in the second direction, the minimum distance between the eighth dummy conductive portion 13H7 and the second connection sub-segment B02 is in a range of 0.2 mm to 0.5 mm, inclusive. For example, the distance is 0.2 mm, 0.22 mm, 0.36 mm, 0.45 mm or 0.5 mm.

For a pad unit 14 on the lower side of the driver chip IC, as shown in FIG. 34, three eighth dummy conductive portions 13H10, 13H11 and 13H12 are provided between the second connection sub-segment B02 at the right and the first connection line 151 that are adjacent. The three eighth dummy conductive portions 13H10, 13H11 and 13H12 are arranged sequentially at intervals from top to bottom.

The eighth dummy conductive portion 13H10 is a line segment extending in the first direction and is located between a tenth connecting section B40 and a twelfth connecting section B42 of the first section B1-1. The eighth dummy conductive portion 13H11 is located between a tenth connecting section B40 and a twelfth connecting section B42 of the second section B1-2. The eighth dummy conductive portion 13H12 is located between the eighth dummy conductive portion 13H11 and the second connection sub-segment B02. The eighth dummy conductive portion 13H12 may be a line segment extending in the first direction. Alternatively, as shown in FIG. 34, the eighth dummy conductive portion 13H12 may include a fifteenth straight dummy sub-portion H13, an eighth inclined dummy sub-portion H14 and a sixteenth straight dummy sub-portion H15 that are sequentially connected from left to right. The fifteenth straight dummy sub-portion H13 is parallel to the thirteenth connecting section B43, the eighth inclined dummy sub-portion H14 is parallel to the seventh inclined section B44, and the sixteenth straight dummy sub-portion H15 is parallel to the fourteenth connecting section B45.

In the second direction, the tenth connecting section B40 and the twelfth connecting section B42 of the first section B1-1 and the eighth dummy conductive portion 13H10 are arranged at equal intervals. And/or, the tenth connecting section B40 and the twelfth connecting section B42 of the second section B1-2 and the eighth dummy conductive portion 13H11 are arranged at equal intervals.

In addition, in the second direction, a distance between the eighth dummy conductive portion 13H12 and the second connection sub-segment B02 is in a range of 0.2 mm to 0.5 mm, inclusive. For example, the distance is 0.2 mm, 0.22 mm, 0.35 mm, 0.45 mm or 0.5 mm.

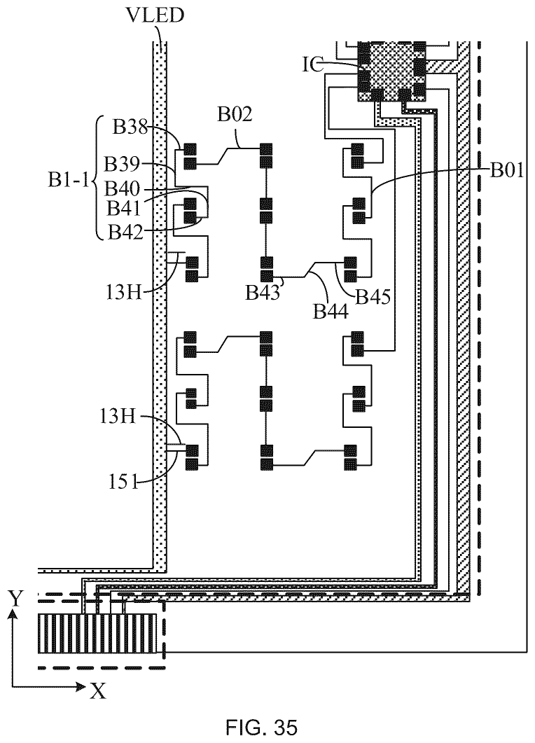

In some examples, as shown in FIG. 35, the signal line 12 and the connection line 15 are disposed in the same conductive layer. In the first direction, the eighth dummy conductive portion 13H is located between the first signal line VLED and the first connection sub-segment B01 that are adjacent. In the second direction, a distance between the eighth dummy conductive portion 13H and the first connection line 151 is greater than a distance between the eighth dummy conductive portion 13H and the first connection sub-segment B01.

In the second direction, the distance between the eighth dummy conductive portion 13H and the first connection line 151 is in a range of 0.2 mm to 0.5 mm, inclusive. For example, the distance is 0.2 mm, 0.22 mm, 0.35 mm, 0.45 mm or 0.5 mm.

The dummy conductive pattern 13 may also be disposed at other positions besides the positions mentioned in the above embodiments. The arrangement of other dummy conductive patterns 13 will be described below for a case where a pad unit 14 includes six device pad groups 141 or nine device pad groups 141.

In a case, a pad unit 14 includes six device pad groups 141.

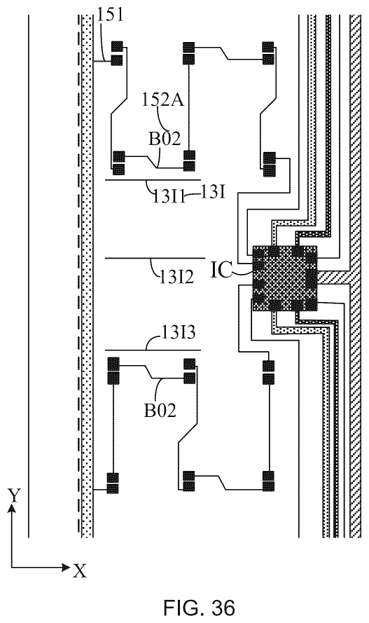

In some embodiments, in the second direction, an accompanying plating design is performed on a region between the upper and lower connection lines 15 adjacent to the driver chip IC. As shown in FIG. 36, the dummy conductive pattern 13 is disposed between two adjacent second connection sub-segments B02, and the two adjacent second connection sub-segments B02 belong to two adjacent second connection lines 152. The dummy conductive pattern 13 further includes at least one ninth dummy conductive portion 131; and the ninth dummy conductive portion(s) 131 extend in the first direction X. In the second direction Y, the two adjacent second connection sub-segments B02 and the ninth dummy conductive portion(s) 131 are arranged at unequal intervals.

In this way, the ninth dummy conductive portion(s) 131 to be plated may make the current densities on two adjacent second connection sub-segments B02 close, and make the electroplating efficiencies close, so as to make the thicknesses of the two adjacent second connection sub-segments B02 close, thereby improving the thickness uniformity of the two adjacent second connection sub-segments B02.

The ninth dummy conductive portion 131 to be plated refers to an intermediate state presented by the ninth dummy conductive portion 131 during forming the ninth dummy conductive portion 131 with a specific thickness in a specific region by electroplating.

In some examples, there may be one, two or more ninth dummy conductive portions 131 between two adjacent second connection sub-segments B02.

For example, as shown in FIG. 36, three ninth dummy conductive portions 1311, 1312 and 1313 are disposed between two adjacent second connection sub-segments B02. The three ninth dummy conductive portions 1311, 1312 and 1313 are arranged sequentially at intervals from top to bottom.

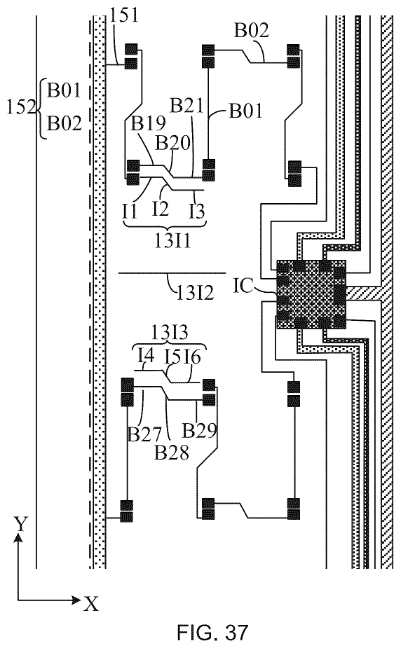

The ninth dummy conductive portion 1311 may be a line segment extending in the first direction. Alternatively, as shown in FIG. 37, the ninth dummy conductive portion 1311 may include a seventeenth straight dummy sub-portion 11, a ninth inclined dummy sub-portion 12 and an eighteenth straight dummy sub-portion 13 that are sequentially connected from left to right. The seventeenth straight dummy sub-portion 11 is parallel to the seventh straight section B19 at the upper side, the ninth inclined dummy sub-portion 12 is parallel to the third inclined section B20 at the upper side, and the eighteenth straight dummy sub-portion 13 is parallel to the eighth straight section B21 at the upper side. The seventeenth straight dummy sub-portion 11 is located on the upper side of the eighteenth straight dummy sub-portion 13.

The ninth dummy conductive portion 1312 is a line segment extending in the first direction. The ninth dummy conductive portion 1313 may be a line segment extending in the first direction. Alternatively, as shown in FIG. 37, the ninth dummy conductive portion 1313 may include a nineteenth straight dummy sub-portion 14, a tenth inclined dummy sub-portion 15 and a twentieth straight dummy sub-portion 16 that are sequentially connected from left to right. The nineteenth straight dummy sub-portion 14 is parallel to the thirteenth straight section B27 at the lower side, the tenth inclined dummy sub-portion 15 is parallel to the fifth inclined section B28 at the lower side, and the twentieth straight dummy sub-portion 16 is parallel to the fourteenth straight section B29 at the lower side.

For example, in the second direction, a distance between the ninth dummy conductive portion 1312 and the ninth dummy conductive portion 1311 is equal to a distance between the ninth dummy conductive portion 1312 and the ninth dummy conductive portion 1313.

In addition, in the second direction, a distance between the ninth dummy conductive portion 1311 and the second connection sub-segment B02 at the upper side is in a range of 0.2 mm to 0.5 mm, inclusive. For example, the distance is 0.2 mm, 0.22 mm, 0.35 mm, 0.44 mm or 0.5 mm.

In the second direction, a distance between the ninth dummy conductive portion 1313 and the second connection sub-segment B02 at the lower side is in a range of 0.2 mm to 0.5 mm, inclusive. For example, the distance is 0.2 mm, 0.22 mm, 0.35 mm, 0.43 mm or 0.5 mm.

In a case, a pad unit 14 includes nine device pad groups 141.

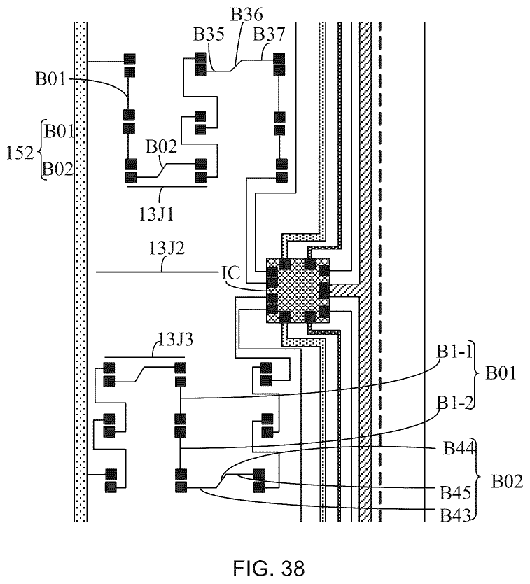

In some embodiments, in the second direction, an accompanying plating design is performed on a region between the upper and lower connection lines 15 adjacent to the driver chip IC. As shown in FIG. 38, the dummy conductive pattern 13 is disposed between two adjacent second connection sub-segments B02, and the two adjacent second connection sub-segments B02 belong to two adjacent second connection lines 152. The dummy conductive pattern 13 further includes at least one tenth dummy conductive portion 13J; and the tenth dummy conductive portion(s) 13J extend in the first direction X. In the second direction Y, the two adjacent second connection sub-segments B02 and the tenth dummy conductive portion(s) 13J are arranged at unequal intervals.

In this way, the tenth dummy conductive portion(s) 13J to be plated may make the current densities on two adjacent second connection sub-segments B02 close, and make the electroplating efficiencies close, so as to make the thicknesses of the two adjacent second connection sub-segments B02 close, thereby improving the thickness uniformity of the two adjacent second connection sub-segments B02.

The tenth dummy conductive portion 13J to be plated refers to an intermediate state presented by the tenth dummy conductive portion 13J during forming the tenth dummy conductive portion 13J with a specific thickness in a specific region by electroplating.

In some examples, there may be one, two or more tenth dummy conductive portions 13J between two adjacent second connection sub-segments B02.

For example, as shown in FIG. 38, in a case where the two adjacent second connection sub-segments B02 belong to two adjacent second connection lines 152, three tenth dummy conductive portions 13J1, 13J2 and 13J3 are provided between the two adjacent second connection sub-segments B02. The three tenth dummy conductive portions 13J1, 13J2 and 13J3 are arranged sequentially at intervals from top to bottom.

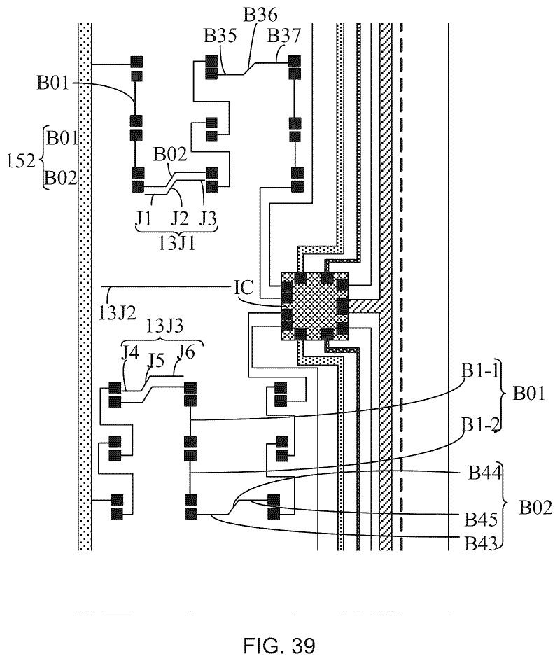

The tenth dummy conductive portion 13J1 may be a line segment extending in the first direction. Alternatively, as shown in FIG. 39, the tenth dummy conductive portion 13J1 may include a twenty-first straight dummy sub-portion J1, an eleventh inclined dummy sub-portion J2 and a twenty-second straight dummy sub-portion J3 that are sequentially connected from left to right. The twenty-first straight dummy sub-portion J1 is parallel to the sixth connecting section B35 at the upper side, the eleventh inclined dummy sub-portion J2 is parallel to the sixth inclined section B36 at the upper side, and the twenty-second straight dummy sub-portion J3 is parallel to the seventh connecting section B37 at the upper side. The twenty-first straight dummy sub-portion J1 is located on the lower side of the twenty-second straight dummy sub-portion J3.

The tenth dummy conductive portion 13J2 is a line segment extending in the first direction. The tenth dummy conductive portion 13J3 may be a line segment extending in the first direction. Alternatively, as shown in FIG. 39, the tenth dummy conductive portion 13J3 may include a twenty-third straight dummy sub-portion J4, a twelfth inclined dummy sub-portion J5 and a twenty-fourth straight dummy sub-portion J6 that are sequentially connected from left to right at intervals. The twenty-third straight dummy sub-portion J4 is parallel to the thirteenth connecting section B43 at the lower side, the twelfth inclined dummy sub-portion J5 is parallel to the seventh inclined section B44 at the lower side, and the twenty-fourth straight dummy sub-portion J6 is parallel to the fourteenth connecting section B45 at the lower side.

For example, in the second direction Y, a distance between the tenth dummy conductive portion 13J2 and the tenth dummy conductive portion 13J1 is equal to a distance between the tenth dummy conductive portion 13J2 and the tenth dummy conductive portion 13J3.

In addition, in the second direction, the minimum distance between the tenth dummy conductive portion 13J1 and the second connection sub-segment B02 at the upper side is in a range of 0.2 mm to 0.5 mm, inclusive. For example, the distance is 0.2 mm, 0.22 mm, 0.35 mm, 0.44 mm or 0.5 mm.

In the second direction, a distance between the tenth dummy conductive portion 13J3 and the second connection sub-segment B02 at the lower side is in a range of 0.2 mm to 0.5 mm, inclusive. For example, the distance is 0.2 mm, 0.22 mm, 0.35 mm, 0.43 mm or 0.5 mm.

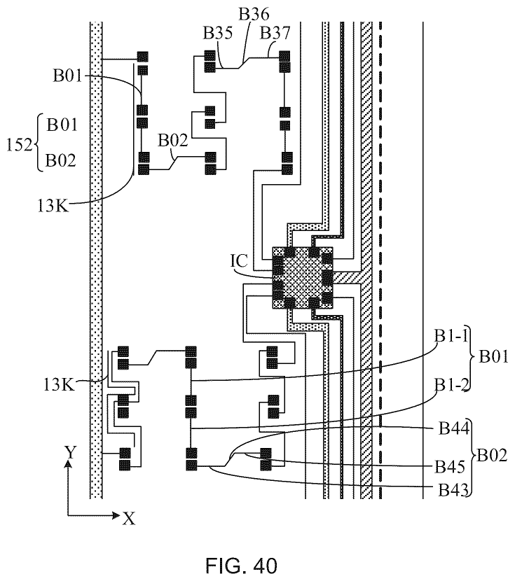

In some embodiments, as shown in FIG. 40, the signal line 12 and the connection line 15 are located in the same conductive layer. In the second direction, an accompanying plating design is performed on the upper and lower connection lines 15 adjacent to the driver chip IC.

In the first direction, the dummy conductive pattern 13 is located between an adjacent signal line 12 (i.e., the first signal line VLED) and the first connection sub-segment B01. The dummy conductive pattern 13 includes an eleventh dummy conductive portion 13K. The eleventh dummy conductive portion 13K extends in the second direction. In the first direction, a distance between the eleventh dummy conductive portion 13K and the signal line 12 is greater than a distance between the eleventh dummy conductive portion 13K and the first connection sub-segment B01.

The eleventh dummy conductive portion 13K to be plated refers to an intermediate state presented by the eleventh dummy conductive portion 13K during forming the eleventh dummy conductive portion 13K with a specific thickness in a specific region by electroplating.

In addition, a distance between the eleventh dummy conductive portion 13K and the first connection sub-segment B01 is in a range of 0.2 mm to 0.5 mm, inclusive. For example, the distance is 0.2 mm, 0.22 mm, 0.35 mm, 0.44 mm or 0.5 mm.

In some examples, as shown in FIG. 40, for a pad unit 14 at a side of the driver chip IC (e.g., the pad unit 14 at the upper side), the eleventh dummy conductive portion 13K may be a line segment extending in the second direction.

In some other examples, as shown in FIG. 40, for a pad unit 14 at a side of the driver chip IC (e.g., the pad unit 14 at the lower side), the eleventh dummy conductive portion 13K has an extending direction consistent with the adjacent first connection sub-segment B01.

The first dummy conductive portion 13A, the second dummy conductive portion 13B, the third dummy conductive portion 13C, the fourth dummy conductive portion 13D, the fifth dummy conductive portion 13E, the sixth dummy conductive portion 13F, the seventh dummy conductive portion 13G, the eighth dummy conductive portion 13H, the ninth dummy conductive portion 131, the tenth dummy conductive portion 13J and the eleventh dummy conductive portion 13K as mentioned above may not only be provided separately, but also be provided in combination. The specific accompanying plating situation of a pad unit 14 including four device pad groups 141, six device pad groups 141 or nine device pad groups 141 will be introduced below for a case where at least two of the first dummy conductive portion 13A, the second dummy conductive portion 13B, the third dummy conductive portion 13C, the fourth dummy conductive portion 13D, the fifth dummy conductive portion 13E, the sixth dummy conductive portion 13F, the seventh dummy conductive portion 13G, the eighth dummy conductive portion 13H, the ninth dummy conductive portion 131, the tenth dummy conductive portion 13J and the eleventh dummy conductive portion 13K are provided, and the connection lines 15 and the signal lines 12 are disposed in the same conductive layer.

In a case, a pad unit 14 includes four device pad groups 141.

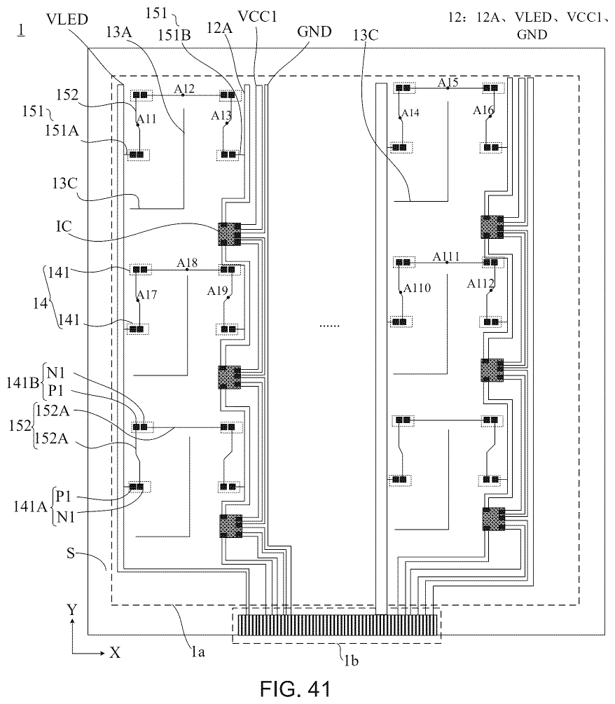

In the first embodiment, as shown in FIG. 41, in the second direction, the first dummy conductive portion 13A and the third dummy conductive portion 13C are both provided between two adjacent connection lines 15, and there is one first dummy conductive portion 13A and one third dummy conductive portion 13C. A lower end of the first dummy conductive portion 13A is connected to a right end of the third dummy conductive portion 13C, and the first dummy conductive portion 13A and the third dummy conductive portion 13C are in an “L” shape.

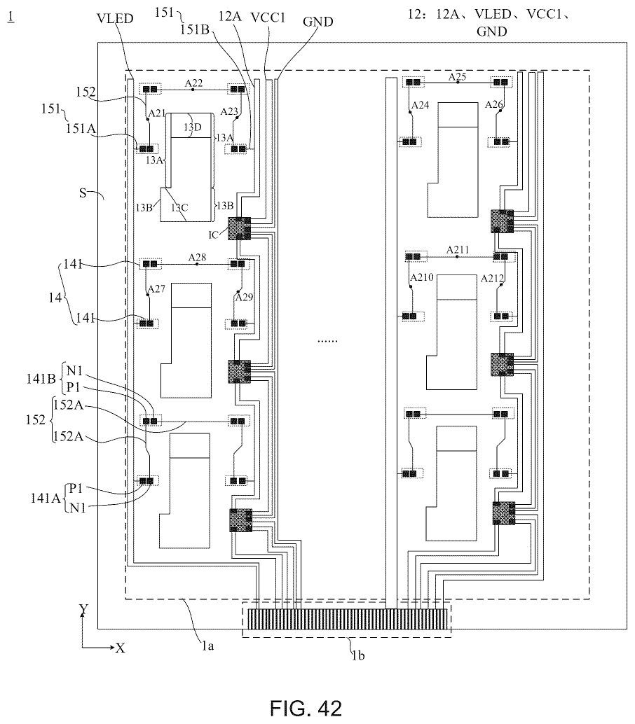

In a second embodiment, as shown in FIG. 42, in the second direction, the first dummy conductive portion 13A, the second dummy conductive portion 13B, the third dummy conductive portion 13C and the fourth dummy conductive portion 13D are all provided between two adjacent connection lines 15, and there are two first dummy conductive portions 13A, two second dummy conductive portions 13B, two third dummy conductive portions 13C and two fourth dummy conductive portions 13D. The fourth dummy conductive portions 13D are located between the two first dummy conductive portions 13A. The second dummy conductive portions 13B are located between two adjacent third dummy conductive portions 13C.

An upper end of the first dummy conductive portion 13A at the left is connected to a left end of the fourth dummy conductive portion 13D at the upper side, a lower end of the first dummy conductive portion 13A at the left is connected to a right end of the third dummy conductive portion 13C at the upper side, an upper end of the first dummy conductive portion 13A at the right is connected to a right end of the fourth dummy conductive portion 13D at the upper side, and a lower end of the first dummy conductive portion 13A at the right is connected to an upper end of the second dummy conductive portion 13B at the right, A left end of the fourth dummy conductive portion 13D at the lower side is connected to the fourth dummy conductive portion 13D at the left, and a right end of the fourth dummy conductive portion 13D at the lower side is connected to the first dummy conductive portion 13A at the right. A left end of the third dummy conductive portion 13C at the upper side is connected to an upper end of the second dummy conductive portion 13B at the left, a left end of the third dummy conductive portion 13C at the lower side is connected to a lower end of the second dummy conductive portion 13B at the left, and a lower end of the second dummy conductive portion 13B at the right is connected to a right end of the third dummy conductive portion 13C at the lower side.

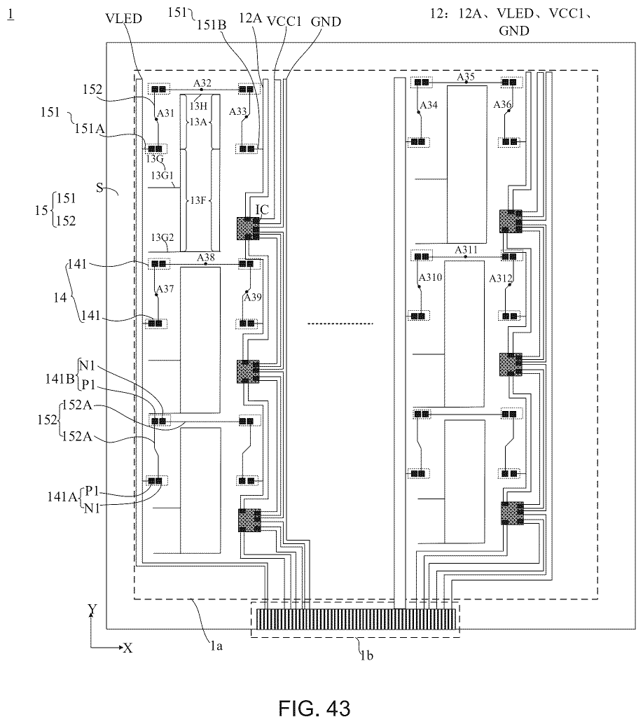

In the third embodiment, as shown in FIG. 43, in the second direction, the first dummy conductive portion 13A, the sixth dummy conductive portion 13F, the seventh dummy conductive portion 13G and the eighth dummy conductive portion 13H are all provided between two adjacent connection lines 15. There are two first dummy conductive portions 13A, two sixth dummy conductive portions 13F and two seventh dummy conductive portions 13G, and there is one eighth dummy conductive portion 13H.

The eighth dummy conductive portion 13H is located between the two first dummy conductive portions 13A. The two sixth dummy conductive portions 13F are located at the lower side of the two first dummy conductive portions 13A, an extension direction of the sixth dummy conductive portion 13F at the left is consistent with an extension direction of the first dummy conductive portion 13A at the left, and an extension direction of the sixth dummy conductive portion 13F at the right is consistent with an extension direction of the first dummy conductive portion 13A at the right. The seventh dummy conductive portion 13G1 is located at the left side of the sixth dummy conductive portion 13F at the left, and the seventh dummy conductive portion 13G2 is located at the lower side of the sixth dummy conductive portions 13F. A left end of the eighth dummy conductive portion 13H is connected to an upper end of the first dummy conductive portion 13A at the left, and a right end of the eighth dummy conductive portion 13H is connected to an upper end of the first dummy conductive portion 13A at the right. An upper end of the sixth dummy conductive portion 13F at the left is connected to a lower end of the first dummy conductive portion 13A at the left, and a lower end of the sixth dummy conductive portion 13F at the left is connected to the seventh dummy conductive portion 13G2. An upper end of the sixth dummy conductive portion 13F at the right is connected to a lower end of the first dummy conductive portion 13A at the right, and a lower end of the sixth dummy conductive portion 13F at the right is connected to the seventh dummy conductive portion 13G2. A right end of the seventh dummy conductive portion 13G1 is connected to the sixth dummy conductive portion 13F at the left, and a lower end of the sixth dummy conductive portion 13F at the left is connected to the seventh dummy conductive portion 13G2.

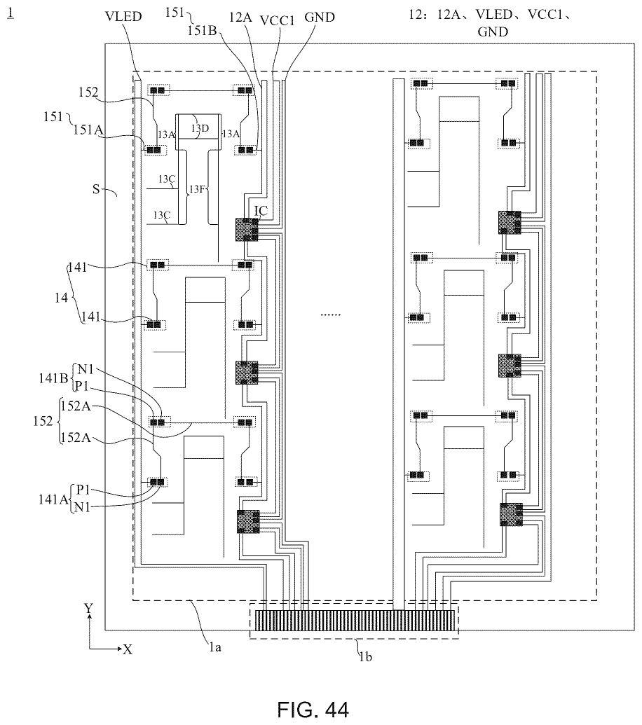

In the fourth embodiment, as shown in FIG. 44, in the second direction, the first dummy conductive portion 13A, the third dummy conductive portion 13C, the fourth dummy conductive portion 13D and the sixth dummy conductive portion 13F are all provided between two adjacent connection lines 15, and there are two first dummy conductive portions 13A, two third dummy conductive portions 13C, two fourth dummy conductive portions 13D and two sixth dummy conductive portions 13F. The two fourth dummy conductive portions 13D are provided between the two adjacent first dummy conductive portions 13A. The sixth dummy conductive portions 13F are provided on the lower side of the first dummy conductive portions 13A, an extension direction of the sixth dummy conductive portion 13F at the left is consistent with an extension direction of the first dummy conductive portion 13A at the left, and an extension direction of the sixth dummy conductive portion 13F at the right is consistent with an extension direction of the first dummy conductive portion 13A at the right. The two third dummy conductive portions 13C are provided on the left side of the sixth dummy conductive portion 13F at the left.

A left end of the fourth dummy conductive portion 13D at the upper side is connected to an upper end of the first dummy conductive portion 13A at the left, and a right end of the fourth dummy conductive portion 13D at the upper side is connected to an upper end of the first dummy conductive portion 13A at the right. A left end of the fourth dummy conductive portion 13D at the lower side is connected to the first dummy conductive portion 13A at the left, and a right end of the fourth dummy conductive portion 13D at the lower side is connected to the first dummy conductive portion 13A at the right. A lower end of the first dummy conductive portion 13A at the left is connected to an upper end of the sixth dummy conductive portion 13F at the left, and a lower end of the first dummy conductive portion 13A at the right is connected to an upper end of the sixth dummy conductive portion 13F at the right. A right end of the third dummy conductive portion 13C at the upper side is connected to the sixth dummy conductive portion 13F at the left, and a right end of the third dummy conductive portion 13C at the lower side is connected to a lower end of the sixth dummy conductive portion 13F at the left.

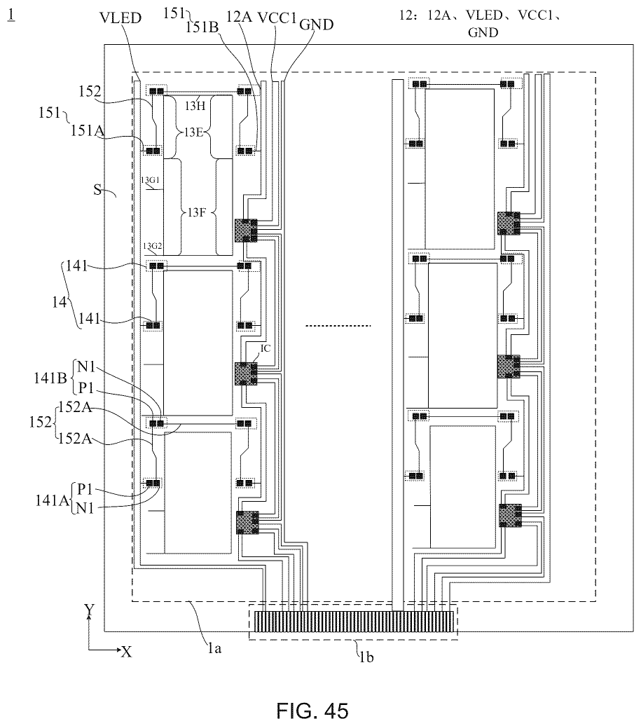

In the fifth embodiment, as shown in FIG. 45, in the second direction, the fifth dummy conductive portion 13E, the sixth dummy conductive portion 13F, the seventh dummy conductive portion 13G and the eighth dummy conductive portion 13H are all provided between two adjacent connection lines 15. There are two fifth dummy conductive portions 13E, two sixth dummy conductive portions 13F and two seventh dummy conductive portions 13G, and there is one eighth dummy conductive portion 13H. The two sixth dummy conductive portions 13F are a sixth dummy conductive portion 13F1 and a sixth dummy conductive portion 13F2; and the two seventh dummy conductive portions 13G are a seventh dummy conductive portion 13G1 and a seventh dummy conductive portion 13G2.

The eighth dummy conductive portion 13H is provided between the two fifth dummy conductive portions 13E. The two sixth dummy conductive portions 13F are provided on the lower side of the fifth dummy conductive portions 13E, an extension direction of the sixth dummy conductive portion 13F at the left is consistent with an extension direction of the fifth dummy conductive portion 13E at the left, and an extension direction of the sixth dummy conductive portion 13F at the right is consistent with an extension direction of the fifth dummy conductive portion 13E at the right. The seventh dummy conductive portion 13G1 is provided on the left side of the sixth dummy conductive portion 13F at the left, and the seventh dummy conductive portion 13G2 is provided on the lower side of the sixth dummy conductive portion 13F. A left end of the eighth dummy conductive portion 13H is connected to an upper end of the fifth dummy conductive portion 13E at the left, and a right end of the eighth dummy conductive portion 13H is connected to an upper end of the fifth dummy conductive portion 13E at the right. An upper end of the sixth dummy conductive portion 13F at the left is connected to a lower end of the fifth dummy conductive portion 13E at the left, and an upper end of the sixth dummy conductive portion 13F at the right is connected to a lower end of the fifth dummy conductive portion 13E at the right. A right end of the seventh dummy conductive portion 13G2 is connected to a lower end of the sixth dummy conductive portion 13F at the right, and a lower end of the sixth dummy conductive portion 13F at the left is connected to the seventh dummy conductive portion 13G2.

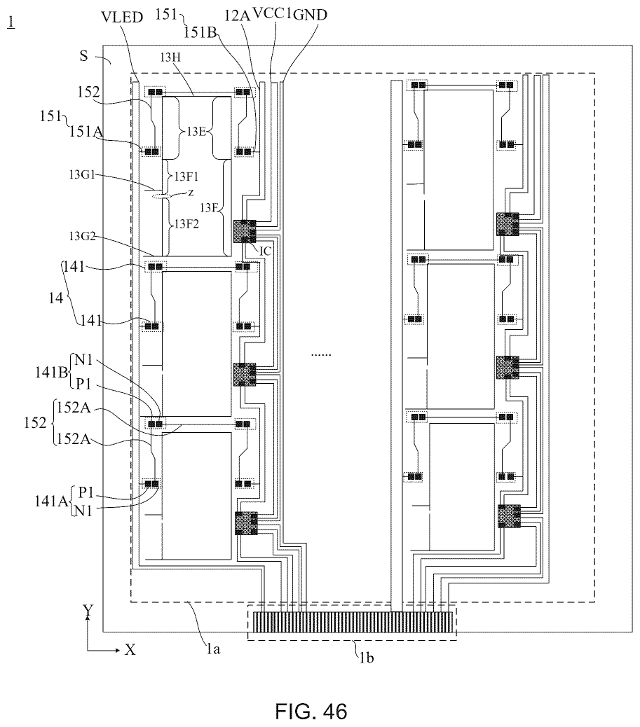

In this case, as shown in FIG. 46, in the second direction Y, a distance between a lower end of the sixth dummy conductive portion 13F1 and an upper end of the sixth dummy conductive portion 13F2 may be greater than or equal to 0.2 mm (at the position of the dotted box in FIG. 46), so that the two fifth dummy conductive portions 13E, the two sixth dummy conductive portions 13F and the eighth dummy conductive portion 13H may be prevented from forming a closed loop, and charges may be prevented from being residual on the two fifth dummy conductive portions 13E, the two sixth dummy conductive portions 13F and the eighth dummy conductive portion 13H after the electroplating is completed, and electrostatic discharge (ESD) may be avoided, so as to ensure normal work of the first connection sub-segment B01, the second connection sub-segment B02, the first connection line 151 and the signal line 12 at the periphery of the two fifth dummy conductive portions 13E, the two sixth dummy conductive portions 13F and the eighth dummy conductive portion 13H.

In a case, a pad unit 14 includes six device pad groups 141. The accompanying plating situation of two adjacent connection lines 15 on the upper and lower sides of the driver chip IC are introduced.

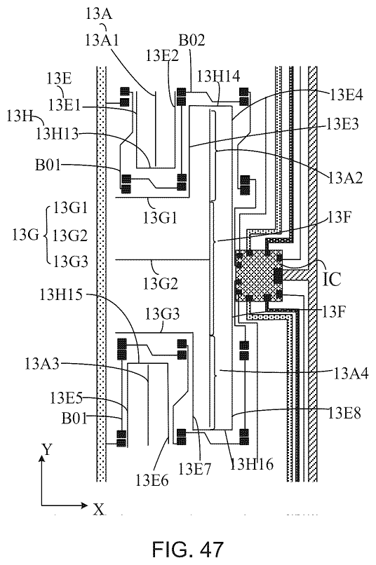

In the sixth embodiment, as shown in FIG. 47, the first dummy conductive portion 13A, the fifth dummy conductive portion 13E, the sixth dummy conductive portion 13F, the seventh dummy conductive portion 13G, the eighth dummy conductive portion 13H and the ninth dummy conductive portion 131 are provided in the wiring substrate.

The wiring substrate 1 is provided therein with four first dummy conductive portions 13A1, 13A2, 13A3 and 13A4; the wiring substrate 1 is provided therein with eight fifth dummy conductive portions 13E1, 13E2, 13E3, 13E4, 13E5, 13E6, 13E7 and 13E8; the wiring substrate 1 is provided therein with two sixth dummy conductive portions 13F; the wiring substrate 1 is provided therein with three seventh dummy conductive portions 13G1, 13G2 and 13G3; the wiring substrate 1 is provided therein with four eighth dummy conductive portions 13H13, 13H14, 13H15 and 13H16; and the wiring substrate 1 is provided therein with three ninth dummy conductive portions 1311, 1312 and 1313.

As shown in FIG. 47, for the connection line 15 located on the upper side of the driver chip IC, the first dummy conductive portion 13A1, the fifth dummy conductive portion 13E1, the fifth dummy conductive portion 13E2 and the eighth dummy conductive portion 13H13 are disposed between adjacent first connection sub-segments B01 at the left. The fifth dummy conductive portion 13E1 is located on the left side of the fifth dummy conductive portion 13E2, and the eighth dummy conductive portion 13H13 is located between the fifth dummy conductive portion 13E1 and the fifth dummy conductive portion 13E2. A left end of the eighth dummy conductive portion 13H13 is connected to a lower end of the fifth dummy conductive portion 13E1, and a right end of the eighth dummy conductive portion 13H13 is connected to a lower end of the fifth dummy conductive portion 13E2. The first dummy conductive portion 13A1 is located between the fifth dummy conductive portion 13E1 and the fifth dummy conductive portion 13E2, and a lower end of the first dummy conductive portion 13A1 is spaced apart from the eighth dummy conductive portion 13H13.

The first dummy conductive portion 13A2, the fifth dummy conductive portion 13E3, the fifth dummy conductive portion 13E4 and the eighth dummy conductive portion 13H14 are disposed between adjacent first connection sub-segments B01 at the right. The fifth dummy conductive portion 13E3 is located on the left side of the fifth dummy conductive portion 13E4, and the eighth dummy conductive portion 13H14 is located between the fifth dummy conductive portion 13E3 and the fifth dummy conductive portion 13E4. An upper end of the fifth dummy conductive portion 13E3 is connected to a left end of the eighth dummy conductive portion 13H14, and an upper end of the fifth dummy conductive portion 13E4 is connected to a right end of the eighth dummy conductive portion 13H14. The first dummy conductive portion 13A2 is located between the fifth dummy conductive portion 13E3 and the fifth dummy conductive portion 13E4, and an upper end of the first dummy conductive portion 13A2 is spaced apart from the eighth dummy conductive portion 13E14.

For the connection line 15 located on the lower side of the driver chip IC, the first dummy conductive portion 13A3, the fifth dummy conductive portion 13E5, the fifth dummy conductive portion 13E6 and the eighth dummy conductive portion 13H15 are located between adjacent first connection sub-segments B01 at the left. The fifth dummy conductive portion 13E5 is located on the left side of the fifth dummy conductive portion 13E6, and the eighth dummy conductive portion 13E15 is located between the fifth dummy conductive portion 13E5 and the fifth dummy conductive portion 13E6. A left end of the eighth dummy conductive portion 13H15 is connected to an upper end of the fifth dummy conductive portion 13E5, and a right end of the eighth dummy conductive portion 13H15 is connected to an upper end of the fifth dummy conductive portion 13E6. The first dummy conductive portion 13A3 is located between the fifth dummy conductive portion 13E5 and the fifth dummy conductive portion 13E6, and, an upper end of the first dummy conductive portion 13A3 is spaced apart from the eighth dummy conductive portion 13H15.

The first dummy conductive portion 13A4, the fifth dummy conductive portion 13E7, the fifth dummy conductive portion 13E8, and the eighth dummy conductive portion 13H16 are located between adjacent first connection sub-segments B01 at the right. The fifth dummy conductive portion 13E7 is located on the left side of the fifth dummy conductive portion 13E8, and the eighth dummy conductive portion 13H16 is located between the fifth dummy conductive portion 13E7 and the fifth dummy conductive portion 13E8. A left end of the eighth dummy conductive portion 13H16 is connected to a lower end of the fifth dummy conductive portion 13E7, and a right end of the eighth dummy conductive portion 13H16 is connected to a lower end of the fifth dummy conductive portion 13E8. The first dummy conductive portion 13A4 is located between the fifth dummy conductive portion 13E7 and the fifth dummy conductive portion 13E8, and a lower end of the first dummy conductive portion 13A4 is spaced apart from the eighth dummy conductive portion.

The three seventh dummy conductive portions 13G are located on the left side of the sixth dummy conductive portion 13F at the left. A right end of the seventh dummy conductive portion 13G1 is connected to a lower end of the fifth dummy conductive portion 13E3, a right end of the seventh dummy conductive portion 13G2 is connected to the sixth dummy conductive portion 13F at the left, and a right end of the seventh dummy conductive portion 13G3 is connected to an upper end of the fifth dummy conductive portion 13E7. An extension direction of the sixth dummy conductive portion 13F at the left is consistent with an extension direction of the first dummy conductive portion 13A2, and is connected to an upper end of the first dummy conductive portion 13A4. An upper end of the sixth dummy conductive portion 13F at the left is connected to a lower end of the first dummy conductive portion 13A2, and a lower end of the sixth dummy conductive portion 13F at the left is connected to the upper end of the first dummy conductive portion 13A4. An extending direction of the sixth dummy conductive portion 13F at the right is consistent with an extending direction of the fifth dummy conductive portion 13E4 and is consistent with an extending direction of the fifth dummy conductive portion 13E8. An upper end of the sixth dummy conductive portion 13F at the right is connected to a lower end of the fifth dummy conductive portion 13E4, and a lower end of the sixth dummy conductive portion 13F at the right is connected to an upper end of the fifth dummy conductive portion 13E8.

In a case, a pad unit 14 includes nine device pad groups 141. The accompanying plating situation of two adjacent connection lines 15 on the upper and lower sides of the driver chip IC are introduced.

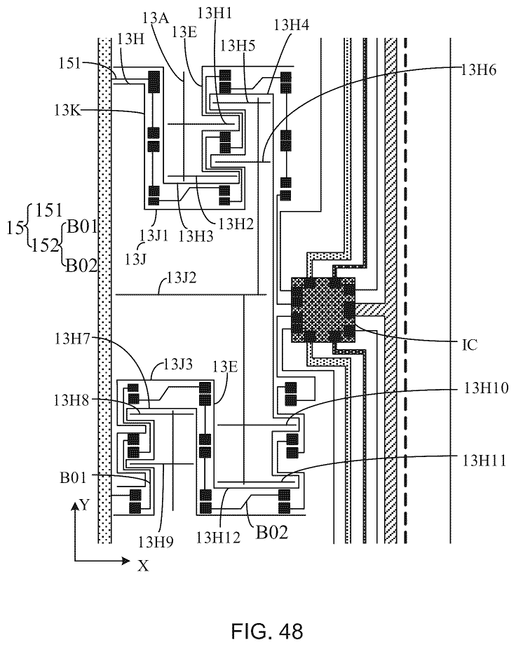

In the seventh embodiment, as shown in FIG. 48, the first dummy conductive portion 13A, the fifth dummy conductive portion 13E, the eighth dummy conductive portion 13H, the tenth dummy conductive portion 13J and the eleventh dummy conductive portion 13K are all provided.

There are four first dummy conductive portions 13A, eight fifth dummy conductive portions 13E, fourteen eighth dummy conductive portions 13H, three tenth dummy conductive portions 13J and two eleventh dummy conductive portions 13K.

A direction of the fifth dummy conductive portion 13E is consistent with a direction of the first connection sub-segment B01. The eighth dummy conductive portions 13H are all line segments extending in the first direction. The tenth dummy conductive portions 13J are all line segments extending in the first direction. The eleventh dummy conductive portions 13K have the same direction as the first connection sub-segment B01.

For a connection line 15 on the upper side of the driver chip IC, a right end of the eighth dummy conductive portion 13H at the left is connected to an upper end of the eleventh dummy conductive portion 13K at the left, and a lower end of the eleventh dummy conductive portion 13K is connected to a left end of the tenth dummy conductive portion 13J1. In the first direction X from left to right, a lower end of the first fifth dummy conductive portion 13E is connected to a left end of the eighth dummy conductive portion 13H3, a lower end of the second fifth dummy conductive portion 13E is connected to a right end of the eighth dummy conductive portion 13H3, an upper end of the third fifth dummy conductive portion 13E is connected to a left end of the eighth dummy conductive portion 13H4, a lower end of the third fifth dummy conductive portion 13E is connected to a right end of the tenth dummy conductive portion 13J1, and an upper end of the fourth fifth dummy conductive portion 13E is connected to a right end of the eighth dummy conductive portion 13H4. A lower end of the first dummy conductive portion 13A at the right extends to intersect with the tenth dummy conductive portion 13J2.

For a connection line 15 on the lower side of the driver chip IC, a right end of the eighth dummy conductive portion 13H at the left is connected to a lower end of the eleventh dummy conductive portion 13K at the left, and an upper end of the eleventh dummy conductive portion 13K at the left is connected to a left end of the tenth dummy conductive portion 13J3. In the first direction X from left to right, an upper end of the first fifth dummy conductive portion 13E is connected to the eighth dummy conductive portion 13H7, a right end of the eighth dummy conductive portion 13H7 is connected to an upper end of the second fifth dummy conductive portion 13E, an upper end of the third fifth dummy conductive portion 13E is connected to a right end of the tenth dummy conductive portion 13J3, a lower end of the third fifth dummy conductive portion 13E is connected to a left end of the eighth dummy conductive portion 13H12, and a lower end of the fourth fifth dummy conductive portion 13E is connected to a right end of the eighth dummy conductive portion 13H12. An upper end of the first dummy conductive portion 13A at the right extends to intersect with the tenth dummy conductive portion 13J2.

The fourth fifth dummy conductive portion 13E on the upper side of the driver chip IC is connected to an upper end of the fourth fifth dummy conductive portion 13E on the lower side of the driver chip IC.

In order to verify the thickness uniformity at different points of different second connection lines 152 after different dummy conductive portions 131 are provided, for a case where the connection lines 15 and the signal lines 12 are disposed in the same conductive layer, the thickness uniformity of points of twelve connection sub-segments 152A is studied below by selecting four second connection lines 152 in a wiring substrate 1 where each second connection line 152 includes three connection sub-segments 152A. For details, reference may be made to the data in Tables 1 to 4 below. The electroplating time may be set so that the connection sub-segment 152A reaches a designed thickness value of 9 μm.

Table 1 below represents experimental data in a case where no dummy conductive portion 131 is provided.

TABLE 1

| Location | A01 | A02 | A03 | A04 | A05 | A06 | A07 | A08 | A09 | A010 | A011 | A012 |
|---|---|---|---|---|---|---|---|---|---|---|---|---|
| Thickness (μm) | 13.15 | 11.36 | 11.08 | 10.63 | 10.47 | 10.52 | 13.22 | 12 | 11.5 | 11.29 | 11.35 | 11.28 |

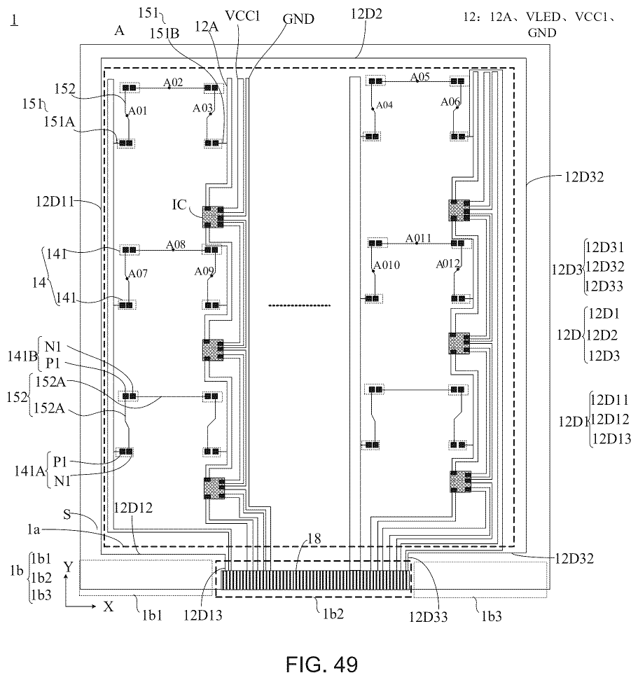

In Table 1, A01 to A012 are shown in FIGS. 49, and A01 to A012 represent midpoint positions of the connection sub-segments 152A where they are located.

It can be calculated according to the data in Table 1 that an average value of the thicknesses at twelve positions of A01 to A012 is 11.5 μm. On this basis, it can be calculated that a uniformity value of the thicknesses at the twelve positions of A01 to A012 is 12.0%.

The following formula (18) shows the calculation formula of uniformity.

$$Unif ( {t}_{loc} ) = \frac{[ Max ( {t}_{loc} ) - Min ( {t}_{loc} ) ]}{2 {t}_{aνg}} . \qquad ( 18 )$$

Where, Unif (t_{loc}) represents the uniformity value, Max (t_{loc}) represents the maximum value of thicknesses, Min (t_{loc}) represents the minimum value of thicknesses, and t_{avg} represents an average value of thicknesses.

Table 2 below represents experimental data in a case where the dummy conductive portions 131 are provided as mentioned in the first embodiment shown in FIG. 41.

TABLE 2

| Location | A11 | A12 | A13 | A14 | A15 | A16 | A17 | A18 | A19 | A110 | A111 | A112 |
|---|---|---|---|---|---|---|---|---|---|---|---|---|
| Thickness (μm) | 11.21 | 10.69 | 10.44 | 10.38 | 11.41 | 11.20 | 11.60 | 11.07 | 10.04 | 10.65 | 10.15 | 10.00 |

It can be calculated according to the data in Table 2 that an average value of the thicknesses at twelve positions of A11 to A112 is 10.7 μm. On this basis, it can be calculated that a uniformity value of the thicknesses at the twelve positions of A11 to A112 is 7.4%. Reference may be made to the above formula 18 for the specific calculation formula.

Table 3 below represents experimental data in a case where the dummy conductive portions 131 are provided as mentioned in the second embodiment shown in FIG. 42.

TABLE 3

| Location | A21 | A22 | A23 | A24 | A25 | A26 | A27 | A28 | A29 | A210 | A211 | A212 |
|---|---|---|---|---|---|---|---|---|---|---|---|---|
| Thickness (μm) | 10.20 | 10.40 | 9.88 | 10.00 | 9.58 | 9.29 | 9.3 | 8.66 | 8.48 | 8.37 | 8.4 | 8.4 |

It can be calculated according to the data in Table 3 that an average value of the thicknesses at twelve positions of A21 to A212 is 9.3 μm. On this basis, it can be calculated that a uniformity value of the thicknesses at the twelve positions of A21 to A212 is 10.8%. Reference may be made to the above formula 18 for the specific calculation formula.

Table 4 below represents experimental data in a case where the dummy conductive portions 131 are provided as mentioned in the third embodiment shown in FIG. 43.

TABLE 4

| Location | A31 | A32 | A33 | A34 | A35 | A36 | A37 | A38 | A39 | A310 | A311 | A312 |
|---|---|---|---|---|---|---|---|---|---|---|---|---|
| Thickness (μm) | 9.58 | 9.07 | 8.90 | 8.70 | 8.41 | 8.49 | 10.07 | 9.44 | 9.11 | 9.27 | 9.50 | 9.47 |

It can be calculated according to the data in Table 4 that an average value of the thicknesses at twelve positions of A31 to A312 is 9.1 μm. On this basis, it can be calculated that a uniformity value of the thicknesses at the twelve positions of A31 to A312 is 8.9%. Reference may be made to the above formula 18 for the specific calculation formula.

It can be obtained in combination with the experimental data in Tables 1 to 4 above that the uniformity value of thicknesses corresponding to Table 2 is less than the uniformity value of thicknesses corresponding to Table 4, the uniformity value of thicknesses corresponding to Table 4 is less than the uniformity value of thicknesses corresponding to Table 3, and the uniformity value of thicknesses corresponding to Table 3 is less than the uniformity value of thicknesses corresponding to Table 1. It can be concluded that the embodiment (i.e. the first embodiment) corresponding to Table 2 has the best effect on improvement of the thickness uniformity. As for the uniformity value of thicknesses and the average value of thicknesses corresponding to Table 4, not only is the uniformity value of thicknesses corresponding to Table 4 relatively small, but also the average value of thicknesses of 9.1 μm corresponding to Table 4 is close to the theoretical thickness value 9 μm. Therefore, the embodiment corresponding to Table 4 has the best accompanying plating effect.

In addition, by adopting the accompanying plating solution in the third embodiment, a proportion of the metal pattern to be plated on the first surface S may be controlled to be less than 30%, so as to save materials and reduce production costs.

It can be understood that after the signal line 12 extends from the display region 1a to the peripheral region 1b, the signal line 12 need to be bonded to the bonding pin 18 in the peripheral region 1b, so as to achieve normal signal transmission.

In some embodiments, as shown in FIG. 49, the wiring substrate 1 further includes a plurality of bonding pins 18. The bonding pins 18 are provided on the first surface S and located in the peripheral region 1b. An end of a signal line 12 extending to the peripheral region 1b is connected to a bonding pin 18 to ensure smooth transmission of a signal of the signal line 12.

In some examples, as shown in FIG. 49, the peripheral region 1b includes a first blank region 1b1, a bonding region 1b2 and a second blank region 1b3 that are arranged sequentially in the first direction X. The first blank region 1b1 and the second blank region 1b3 have similar dimensions in the first direction, and the bonding pins 18 are located in the bonding region 1b2. In this way, in the first direction, the signal lines 12 at both sides of the bonding region 1b2 have close distances to the bonding region 1b2, and the symmetry of connection of the signal lines 12 at both sides of the bonding region 1b2 may be ensured to facilitate the signal transmission.

In some embodiments, as shown in FIG. 49, the wiring substrate 1 further includes an annular electrostatic release line 12D, and the annular electrostatic release line 12D is disposed on the first surface S. The annular electrostatic release line 12D includes a first electrostatic release sub-segment 12D1, a second electrostatic release sub-segment 12D2 and a third electrostatic release sub-segment 12D3 that are electrically connected in sequence. The first electrostatic release sub-segment 12D1 and the third electrostatic release sub-segment 12D3 are located on opposite sides of the display region 1a in the first direction X, and the second electrostatic release sub-segment 12D2 is located on a side of the display region 1a away from the peripheral region 1b. An end of the first electrostatic release sub-segment 12D1 away from the second electrostatic release sub-segment 12D2 extends into the peripheral region 1b and is electrically connected to the bonding pin 18. An end of the third electrostatic release sub-segment 12D3 away from the second electrostatic release sub-segment 12D2 extends into the peripheral region 1b and is electrically connected to the bonding pin 18.

By providing the annular electrostatic release line 12D, the annular electrostatic release line 12D may conduct static electricity in the display region 1a to the pin in the peripheral region 1b, thereby avoiding accumulation of the static electricity in the display region 1a, and avoiding damage to the light-emitting device 2 or the driver chip IC after the static electricity accumulates to a certain level. Thus, the normal work of the light-emitting device 2 may be ensured and the yield of manufacturing the wiring substrate 1 may be improved.

For example, as shown in FIG. 49, the first electrostatic release sub-segment 12D1 includes a first vertical sub-segment 12D11, a first horizontal sub-segment 12D12 and a second vertical sub-segment 12D13 that are sequentially connected. The first vertical sub-segment 12D11 and the second vertical sub-segment 12D13 extend in the second direction, and the first horizontal sub-segment 12D12 extends in the first direction. An upper end of the first vertical sub-segment 12D11 is connected to a left end of the second electrostatic release sub-segment 12D2, and an end of the second vertical sub-segment 12D13 away from the first horizontal sub-segment 12D12 extends into the peripheral region 1b and is connected to the bonding pin 18.

For example, as shown in FIG. 49, the third electrostatic release sub-segment 12D3 includes a third vertical sub-segment 12D31, a second horizontal sub-segment 12D32 and a fourth vertical sub-segment 12D33 that are sequentially connected. The third vertical sub-segment 12D31 and the fourth vertical sub-segment 12D33 extend in the second direction, and the second horizontal sub-segment 12D32 extends in the first direction. An upper end of the third vertical sub-segment 12D31 is connected to a right end of the second electrostatic release sub-segment 12D2, and a lower end of the fourth vertical sub-segment 12D33 extends into the peripheral region 1b and is connected to the bonding pin 18.

During actual manufacture, the bonding pins 18 may also be formed together with the signal lines 12 by electroplating. The bonding pins 18 are mainly concentrated in the bonding region 1b2, and there are a first blank region 1b1 and a second blank region 1b3 at both sides of the bonding region 1b2. Therefore, during electroplating, the current density on the bonding pins 18 to be plated is relatively large, and the electroplating thickness is relatively large per unit time. In this way, the thickness uniformity of the plurality of bonding pins 18, as well as the thickness uniformity between the plurality of bonding pins 18 and both the connection lines 15 and signal lines 12 in the display region 1a, may be affected.

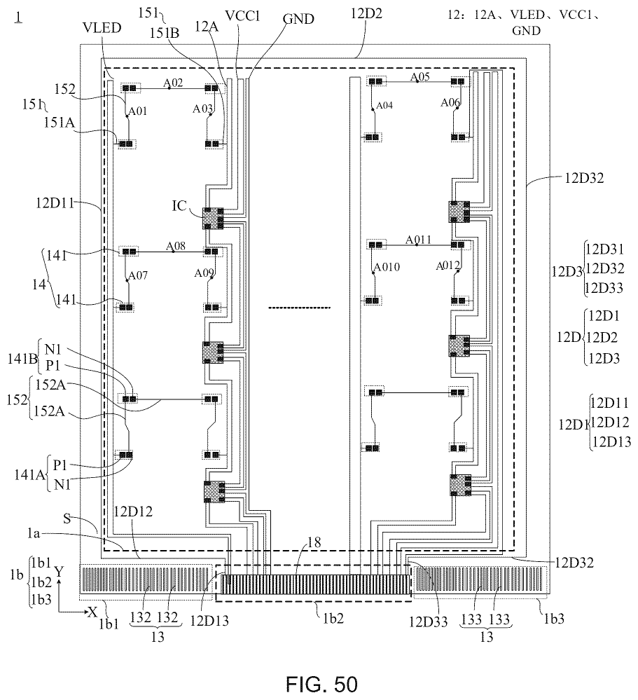

Based on this, in some embodiments, as shown in FIG. 50, the first blank region 1b1 and the second blank region 1b3 are both provided with dummy conductive patterns 13 therein. In this way, in a process of forming the bonding pins 18 by electroplating, the dummy conductive patterns 13 are also formed, and thus a proportion of the metal pattern to be plated per unit area in the peripheral region 1b increases. As a result, the current densities on the plurality of bonding pins 18 to be plated are close, the electroplating efficiencies are close, and the thicknesses of all the bonding pins 18 are close, thereby improving the thickness uniformity of the bonding pins 18.

In addition, for the first blank region 1b1, the provision of the dummy conductive patterns 13 may increase the proportion of the metal pattern to be plated per unit area, and reduce an edge effect caused by existence of the first blank region 1b1, so as to reduce an electroplating rate of the first horizontal sub-segment 12D12 during electroplating, increase a thickness difference between the first horizontal sub-segment 12D12 and other signal lines 12, connection lines 15 and bonding pins 18 therearound, thereby improving the uniformity.

For the second blank region 1b3, the provision of the dummy conductive patterns 13 may increase the proportion of the metal pattern to be plated per unit area, and reduce an edge effect caused by existence of the second blank region 1b3, so as to reduce an electroplating rate of the second horizontal sub-segment 12D32 during electroplating, increase a thickness difference between the second horizontal sub-segment 12D32 and other signal lines 12, connection lines 15 and bonding pins 18 therearound, thereby improving the uniformity.

In some examples, the dummy conductive patterns 13 located in the first blank region 1b1 include a plurality of first dummy pins 132. The first dummy pins 132 extend in the second direction Y, and the plurality of first dummy pins 132 are arranged at intervals in the first direction X.

For example, a width (i.e., a dimension in the first direction X) of the bonding pin 18 is in a range of 5 mm to 7 mm, inclusive. For example, the width of the bonding pin 18 is 5.0 mm, 5.3 mm, 5.6 mm, 6.0 mm, 6.2 mm or 7 mm.

For example, in the second direction Y, a distance between an upper end of the first dummy pin 132 and the first horizontal sub-segment 12D12 is in a range of 0.2 mm to 0.3 mm, inclusive. For example, the distance between the upper end of the first dummy pin 132 and the first horizontal sub-segment 12D12 is 0.2 mm, 0.22 mm, 0.24 mm, 0.26 mm or 0.30 mm.

In some examples, the dummy conductive patterns 13 located in the second blank region 1b3 include a plurality of second dummy pins 133. The second dummy pins 133 extend in the second direction Y, and the plurality of second dummy pins 133 are arranged at intervals in the first direction X.

For example, in the second direction Y, a distance between an upper end of the second dummy pin 133 and the second horizontal sub-segment 12D32 is in a range of 0.2 mm to 0.3 mm, inclusive. For example, the distance between the upper end of the second dummy pin 133 and the second horizontal sub-segment 12D32 is 0.2 mm, 0.23 mm, 0.25 mm, 0.28 mm or 0.30 mm.

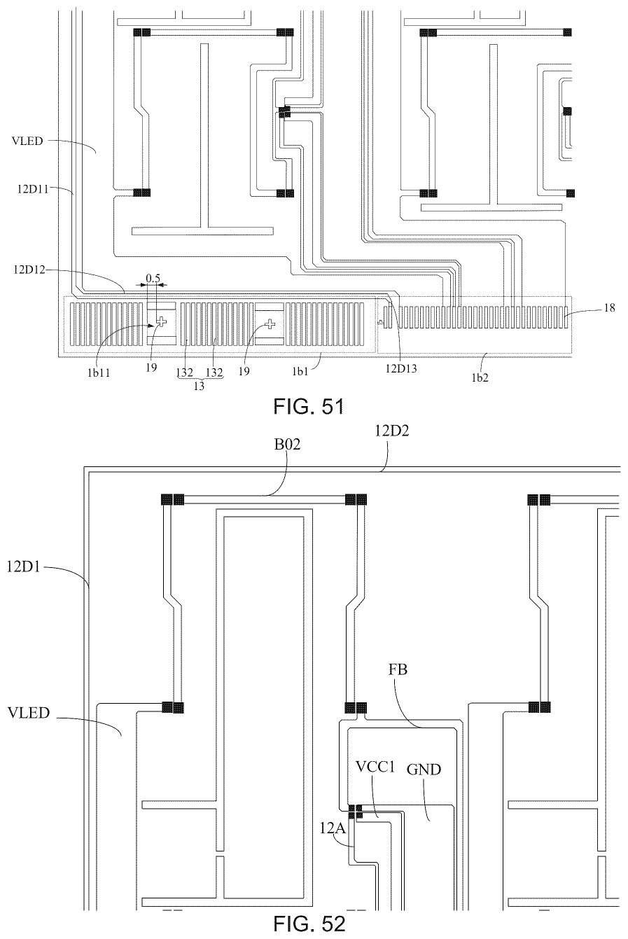

In order to ensure an accuracy of the position at which the bonding pin 18 is provided, as shown in FIG. 51, the peripheral region 1b is required to be provided with bonding alignment patterns 19 therein. For example, the bonding alignment pattern 19 is in an “X” shape, so as to facilitate positioning electroplating of the bonding pins 18. The bonding alignment patterns 19 are generally disposed in the first blank region 1b1 and the second blank region 1b3. In this way, it may avoid interference of the bonding alignment pattern with the bonding pins 18.

However, since the first blank region 1b1 and the second blank region 1b3 are both provided with dummy conductive patterns 13 therein, it is necessary to avoid interference between the positions of the dummy conductive patterns 13 and the positions of the bonding alignment patterns.

For example, as shown in FIG. 51, there are first clearance regions 1b11 within the first blank region 1b1. The bonding alignment pattern 19 is disposed in the first clearance region 1b11, and the dummy conductive patterns 13 are disposed outside the first clearance region 1b11.

For example, the first clearance region 1b11 is rectangular, and the bonding alignment pattern is disposed at the center of the rectangular first clearance region 1b11.

For example, a distance between an outline of the first clearance region 1b11 and a closest edge of the bonding alignment pattern is about 0.5 mm.

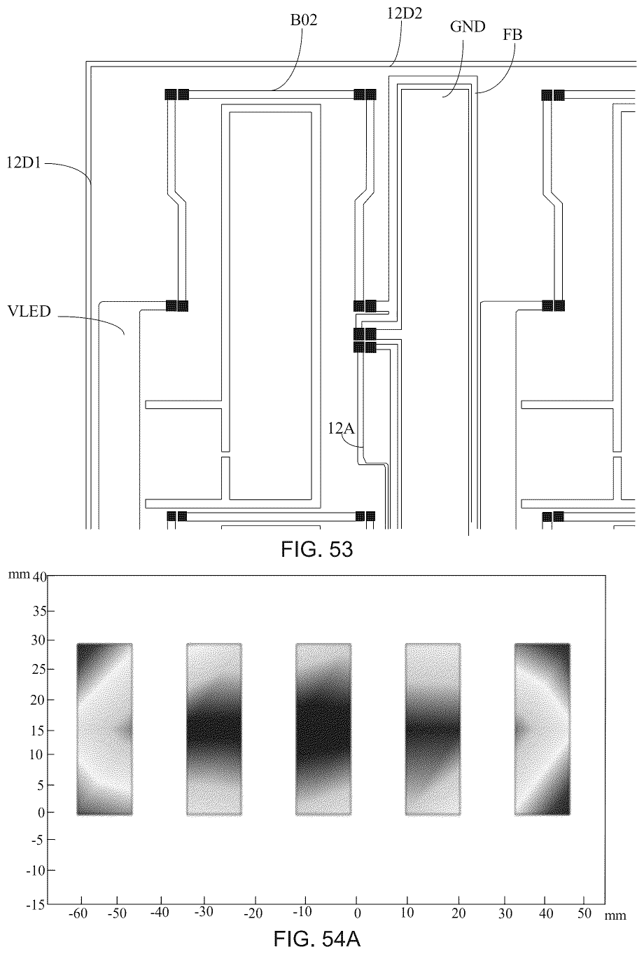

In some embodiments, as shown in FIGS. 52 to 53, in order to well improve the thickness uniformity of the connection lines 15 and the signal lines 12 of the wiring substrate 1, positions of part of the signal lines 12 and connection lines 15 are adjusted.

For example, as shown in FIG. 52, in the related art, in the second direction, a second connection sub-segment B02 furthest away from the peripheral region 1b and the second electrostatic release sub-segment 12D2 have a relatively large distance therebetween. Thus, a blank region with a relatively large area will be caused between the feedback signal line FB and the second electrostatic release sub-segment 12D2, thereby affecting the overall thickness uniformity of the signal lines 12 and the connection lines 15.

Based on the above problems, as shown in FIG. 53, the embodiments of the present disclosure adjust the positions of the feedback signal line FB and the second signal line GND. In the second direction, the second signal line GND and the feedback signal line FB extend upwards, so that an upper end of the second signal line GND is flush with the second connection sub-segment B02, and the feedback signal line FB is partially located between the second signal line GND and the second electrostatic release sub-segment 12D2. Thus, the blank region between the second signal line GND and the second electrostatic release sub-segment 12D2 is filled to increase a proportion of the metal pattern to be plated per unit area in the blank region, thereby improving the overall thickness uniformity of the connection lines 15 and the signal lines 12.

In some embodiments, as shown in FIG. 53, the second electrostatic release sub-segment 12D2 may be moved downward, so that in the second direction Y, the distance between the second electrostatic release sub-segment 12D2 and the uppermost second connection sub-segment B02 is maintained at about 0.2 mm. In this way, the distance between the second electrostatic release sub-segment 12D2 and the second connection sub-segment B02 may be reduced well, thereby improving the thickness uniformity of the connection lines 15 and the signal lines 12.

In order to verify that the provision of the dummy conductive pattern 13 has an improving effect on the uniformity of the thicknesses of the signal lines 12, the thicknesses of the connection lines 15 and the thicknesses of the bonding pins 18. In an initial stage of design, in a case where the signal lines 12 and the connection lines 15 are located in the same conductive layer, the provision of the dummy conductive patterns 13 will be studied below in two aspects.

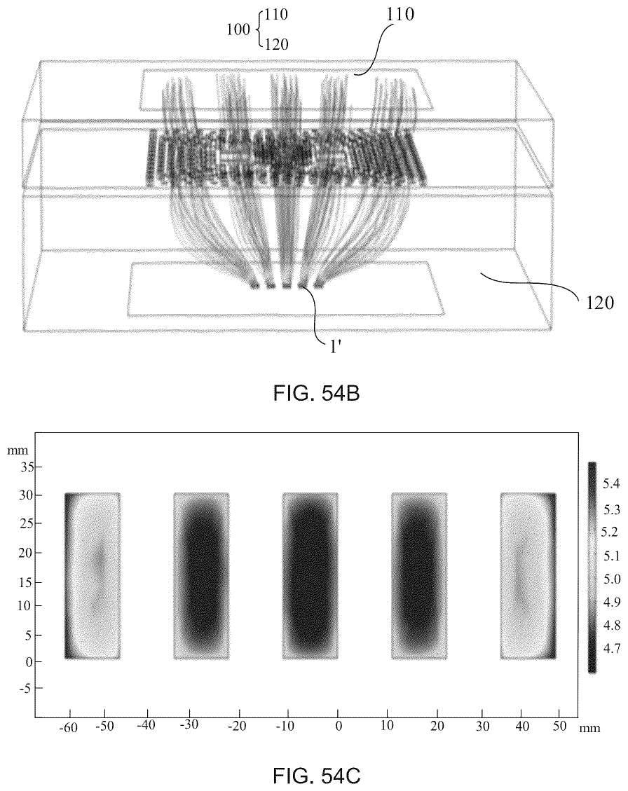

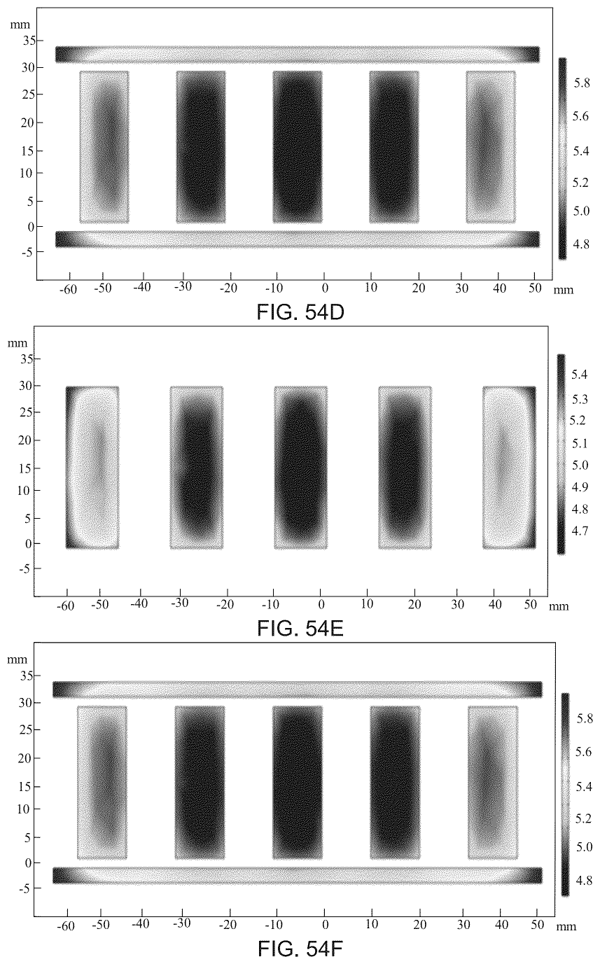

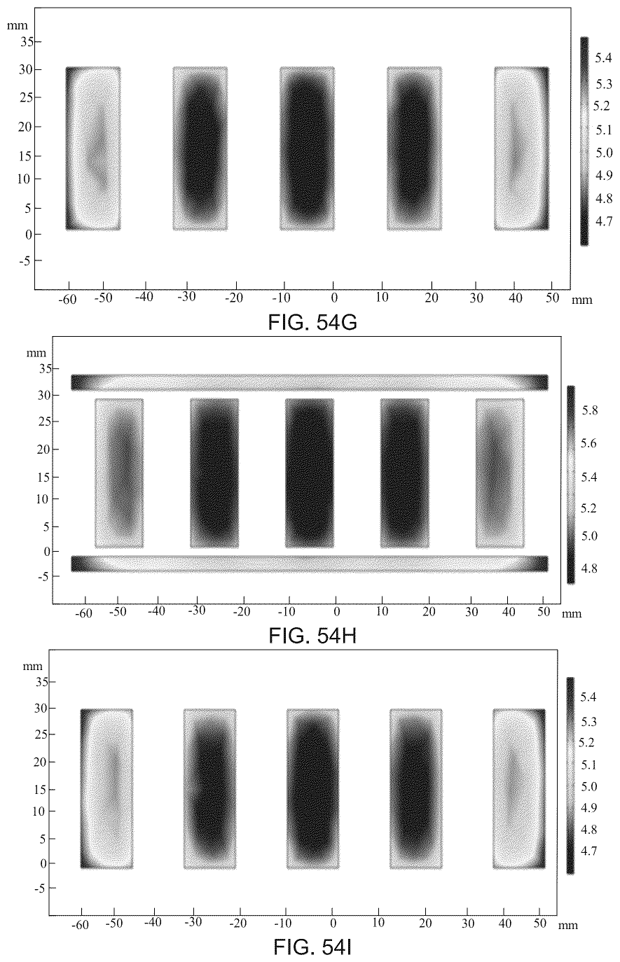

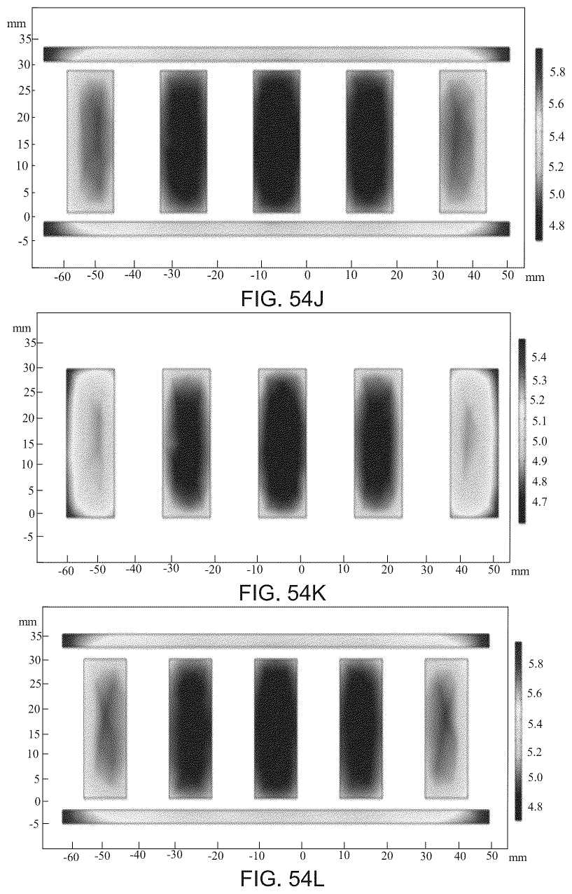

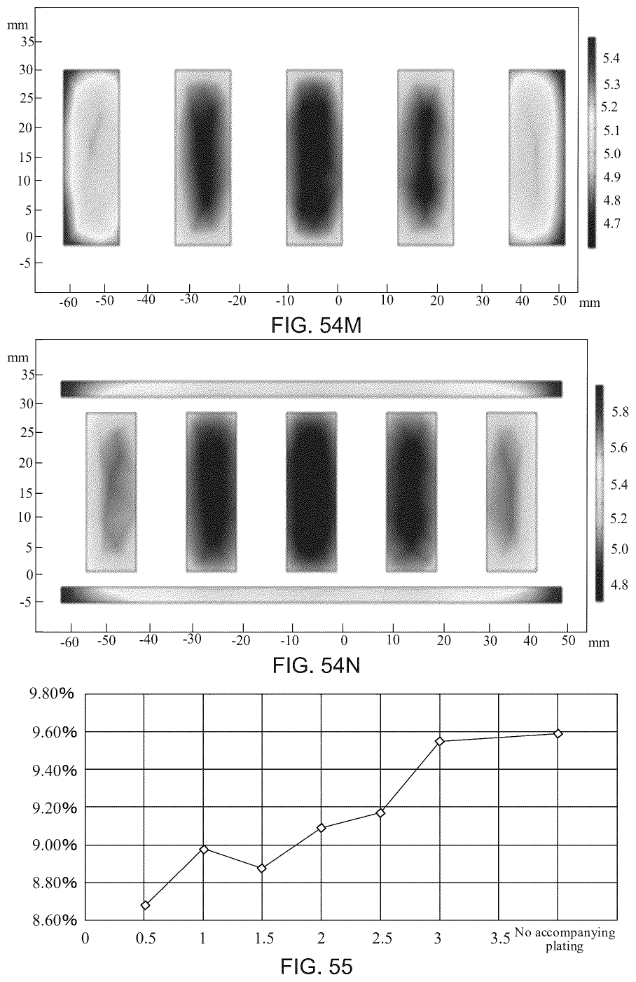

In a first aspect, as shown in FIGS. 54A to 54N, the dummy conductive pattern 13 includes a dummy conductive portion 131, and an influence of a distance between the dummy conductive portion 131 and the signal line 12 or the connection line 15 or the bonding pin 18 on the uniformity of the signal line 12 or the connection line 15 is studied.

A width of the dummy conductive portion 131 is set to 3 μm, and a theoretical thickness of the dummy conductive portion 131 that need to be electroplated and a theoretical thickness of a wire to be plated (at least one of the signal line 12, the connection line 15 and the bonding pin 18) is set to 5 μm. The influence of the distance between the dummy conductive portion 131 and the wire to be plated on the uniformity of different wires to be plated is studied below.

It can be understood that the width of the dummy conductive portion 131 refers to a dimension perpendicular to an extension direction of the dummy conductive portion 131.

As shown in FIGS. 54A, and 54C to 54N, a horizontal axis in each figure represents a dimension of the substrate 11 in the first direction X, and a vertical axis in the figure represents a dimension of the substrate 11 in the second direction Y. Each rectangle in the figure represents a region, and each region is provided with a wire to be plated. Dummy conductive portions 131 are provided in blank regions at both ends of the wire to be plated. Each figure has five thickness distribution regions arranged at intervals in the first direction X. The wire to be plated in each thickness distribution region is measured by a film thickness gauge to obtain a respective thickness and finally obtain the thickness distribution.

In addition, FIG. 54B shows a commonly used electroplating equipment model, and FIG. 54B shows flow and distribution of metal ions (such as copper ions) in the electrolyte solution during electroplating. An electroplating equipment 100 includes an anode 110. A substrate 1′ to be plated is placed in a receiving tank 120 of the electroplating equipment 100 and is disposed opposite to the anode 110. A negative output terminal of the power supply is electrically connected to a seed layer on the substrate 1′ to be plated, and the anode 110 is connected to a positive output terminal of the power supply, thereby generating an electric field between the anode 110 and the substrate 1′ to be plated, where the electric field line distribution is directed from the anode 110 to the substrate 1′ to be plated.

As shown in FIG. 54B, the electric field lines at the middle are distributed relatively sparsely, and the electric field lines at the edge sides are distributed denser than the electric field lines at the middle. Therefore, as electroplating proceeds, the wires to be plated (e.g., at least one of the signal line 12, the connection line 15 and the bonding pin 18) at an edge position where the electric field lines are distributed densely are plated thicker, while the wires to be plated (e.g., at least one of the signal line 12, the connection line 15 and the bonding pin 18) at the middle positions where the electric field lines are distributed sparsely are plated thinner, resulting in poor electroplating uniformity.

FIG. 54A represents the thickness distribution of the wires to be plated in five thickness distribution regions in a case where no dummy conductive portion 131 is provided.

FIGS. 54C and 54D are a set of comparative experiments. FIG. 54C represents the thickness distribution of the wires to be plated in five thickness distribution regions in a case where no dummy conductive portion 131 is provided. FIG. 54D represents the thickness distribution of the wires to be plated in five thickness distribution regions in a case where a distance between the dummy conductive portion 131 and the wire to be plated is 0.5 mm.

FIGS. 54E and 54F are a set of comparative experiments. FIG. 54E represents the thickness distribution of the wires to be plated in five thickness distribution regions in a case where no dummy conductive portion 131 is provided. FIG. 54F represents the thickness distribution of the wires to be plated in five thickness distribution regions in a case where a distance between the dummy conductive portion 131 and the wire to be plated is 1 mm.

FIGS. 54G and 54H are a set of comparative experiments. FIG. 54G represents the thickness distribution of the wires to be plated in five thickness distribution regions in a case where no dummy conductive portion 131 is provided. FIG. 54H represents the thickness distribution of the wires to be plated in five thickness distribution regions in a case where a distance between the dummy conductive portion 131 and the wire to be plated is 1.5 mm.

FIGS. 54I and 54J are a set of comparative experiments. FIG. 54I represents the thickness distribution of the wires to be plated in five thickness distribution regions in a case where no dummy conductive portion 131 is provided. FIG. 54J represents the thickness distribution of the wires to be plated in five thickness distribution regions in a case where a distance between the dummy conductive portion 131 and the wire to be plated is 2 mm.

FIGS. 54K and 54L are a set of comparative experiments. FIG. 54K represents the thickness distribution of the wires to be plated in five thickness distribution regions in a case where no dummy conductive portion 131 is provided. FIG. 54L represents the thickness distribution of the wires to be plated in five thickness distribution regions in a case where a distance between the dummy conductive portion 131 and the wire to be plated is 2.5 mm.

FIGS. 54M and 54N are a set of comparative experiments. FIG. 54M represents the thickness distribution of the wires to be plated in five thickness distribution regions in a case where no dummy conductive portion 131 is provided. FIG. 54N represents the thickness distribution of the wires to be plated in five thickness distribution regions in a case where a distance between the dummy conductive portion 131 and the wire to be plated is 3 mm.

The data in the following Table 5 can be obtained in combination with the thickness distribution of the wires to be plated in the above FIGS. 54A and 54C to 54N and by taking values for calculation.

TABLE 5

| Distance between | Maximum | Minimum | Average | |
|---|---|---|---|---|
| the dummy | thickness of | thickness of | value of | Thickness |
| conductive portion | wires to | wires to | wires to | uniformity |
| 131 and the wire | be plated | be plated | be plated | of wires to |
| to be plated (mm) | (mm) | (mm) | (mm) | be plated |
| No dummy | 5.6596 | 4.7008 | 5 | 9.59% |
| conductive portion | | | | |
| 131 provided | | | | |
| 0.5 | 5.4652 | 4.6144 | 4.8989 | 8.68% |
| 1 | 5.4821 | 4.6033 | 4.8934 | 8.98% |
| 1.5 | 5.4666 | 4.5987 | 4.8862 | 8.88% |
| 2 | 5.4721 | 4.5849 | 4.8813 | 9.09% |
| 2.5 | 5.4609 | 4.5662 | 4.8796 | 9.17% |
| 3 | 5.4554 | 4.5239 | 4.8787 | 9.55% |

A line chart shown in FIG. 55 may be obtained in combination with the data in Table 5 above. It can be seen from the figure that as the distance between the wire to be plated and the dummy conductive portion 131 gradually decreases, the thickness uniformity of the wires to be plated gradually increases. In a case where the distance between the dummy conductive portion 131 and the wire to be plated is 0.5 μm, the wires to be plated have the optimal thickness uniformity.

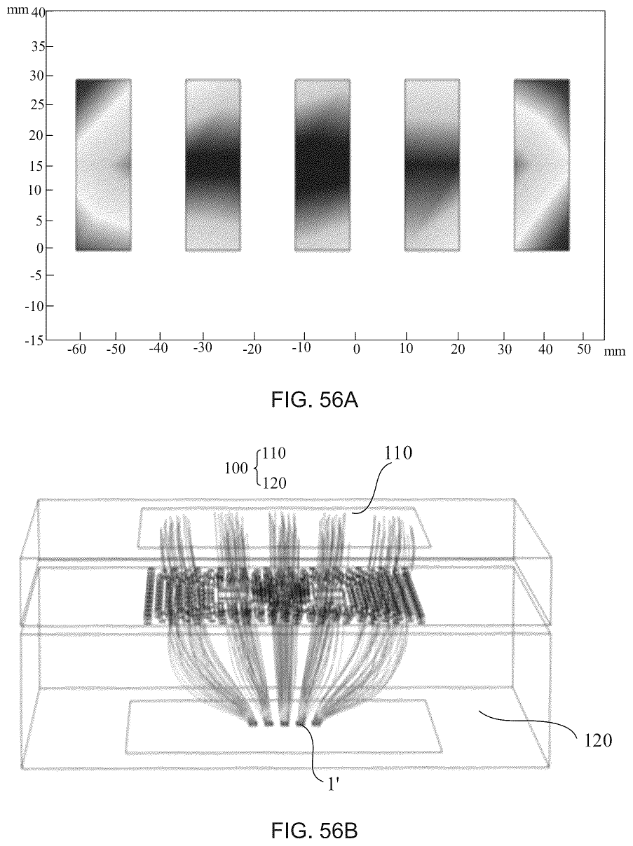

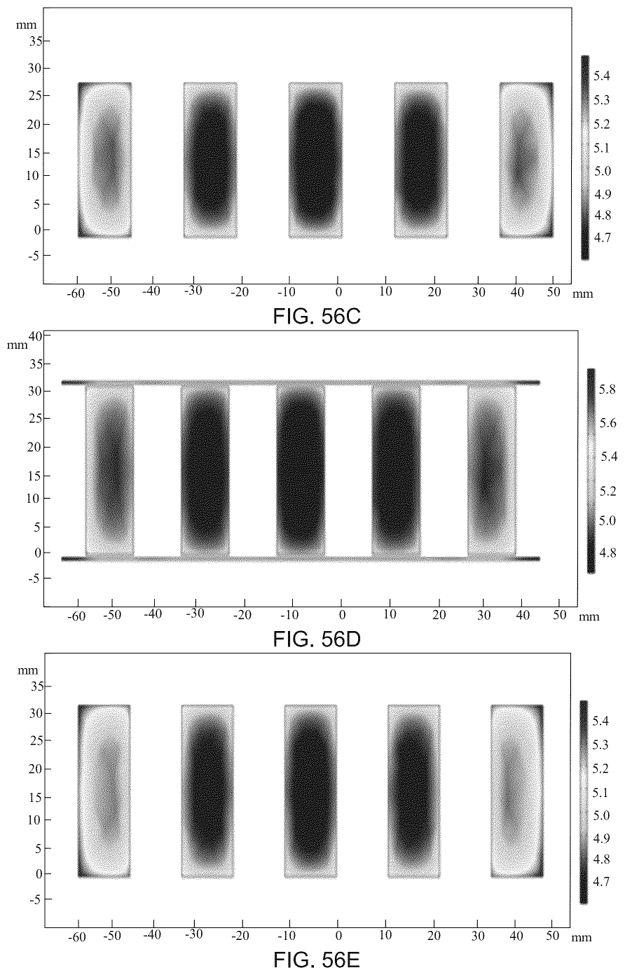

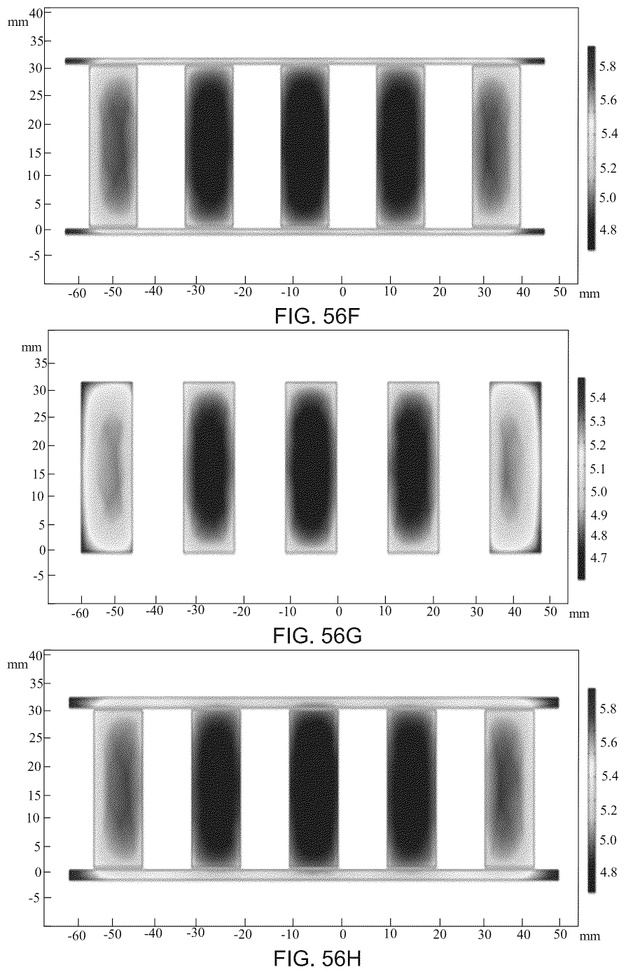

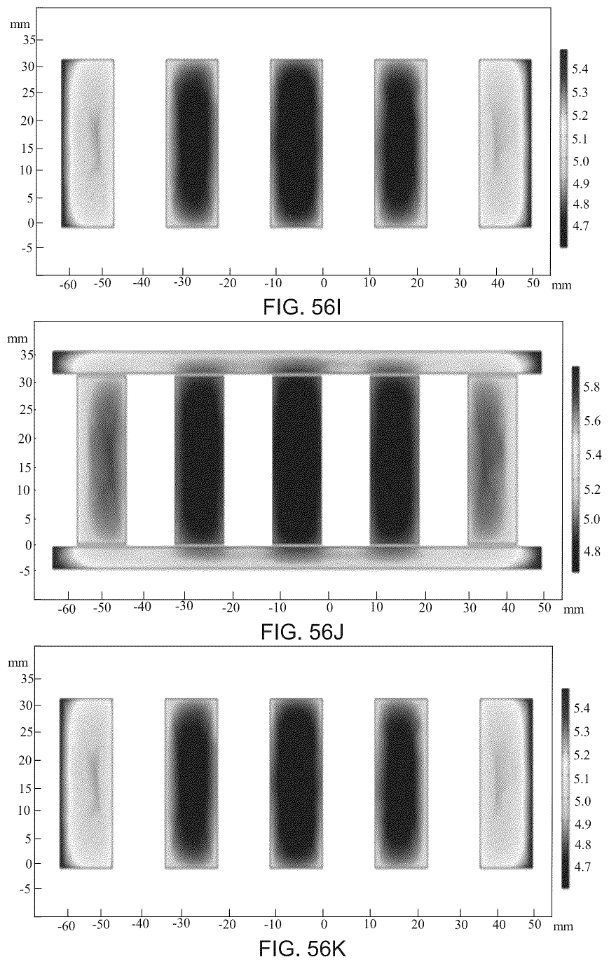

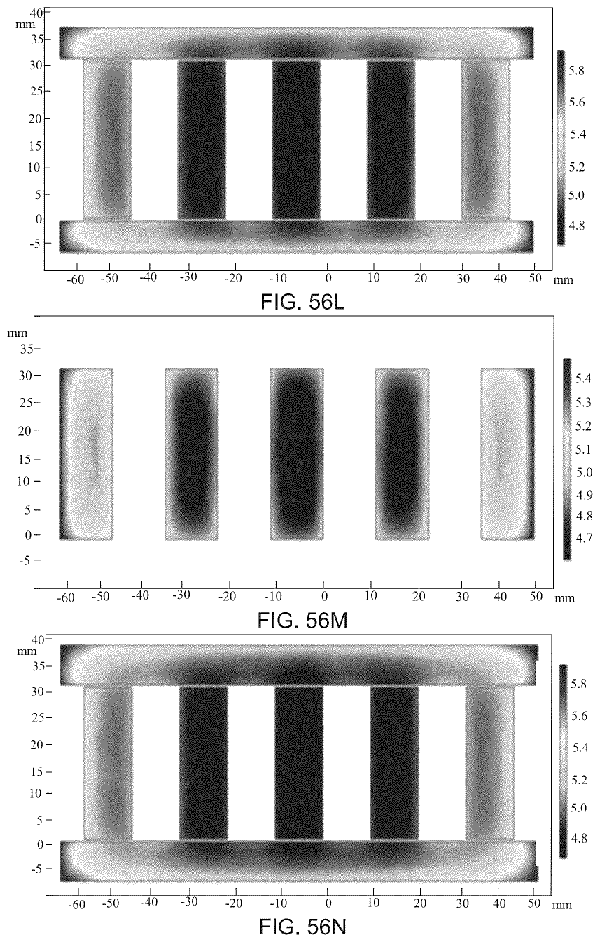

In a second aspect, as shown in FIGS. 56A to 56N, the dummy conductive pattern 13 includes a dummy conductive portion 131, and an influence of width variation of the dummy conductive portion 131 on the uniformity of the signal line 12 or the connection line 15 is studied.

The distance between the wire to be plated and the dummy conductive portion 131 is set to 0.5 mm, and a theoretical thickness of the dummy conductive portion 131 that need to be electroplated and a theoretical thickness of a wire to be plated (at least one of the signal line 12, the connection line 15 and the bonding pin 18) is set to 5 μm. The influence of a varying width of the dummy conductive portion 131 on the uniformity of different wires to be plated is studied below.

As shown in FIGS. 56A, and 56C to 56N, a horizontal axis in each figure represents a dimension of the substrate 11 in the first direction, and a vertical axis in the figure represents a dimension of the substrate 11 in the second direction. Each rectangle in the figure represents a region, and each region is provided with a wire to be plated. Dummy conductive portions 131 are provided in blank regions at both ends of the wire to be plated. Each figure has five thickness distribution regions arranged at intervals in the first direction. The wire to be plated in each thickness distribution region is measured by a film thickness gauge to obtain a respective thickness and finally obtain the thickness distribution.

In addition, FIG. 56B shows a commonly used electroplating equipment model, and FIG. 56B shows flow and distribution of metal ions (such as copper ions) in the electrolyte solution during electroplating. An electroplating equipment 100 includes an anode 110. A substrate 1′ to be plated is placed in a receiving tank 120 of the electroplating equipment 100 and is disposed opposite to the anode 110. A negative output terminal of the power supply is electrically connected to a seed layer on the substrate 1′ to be plated, and the anode 110 is connected to a positive output terminal of the power supply, thereby generating an electric field between the anode 110 and the substrate 1′ to be plated, where the electric field line distribution is directed from the anode 110 to the substrate 1′ to be plated.

FIG. 56A represents the thickness distribution of the wires to be plated in five thickness distribution regions in a case where no dummy conductive portion 131 is provided.

FIGS. 56C and 56D are a set of comparative experiments. FIG. 56C represents the thickness distribution of the wires to be plated in five thickness distribution regions in a case where no dummy conductive portion 131 is provided. FIG. 56D represents the thickness distribution of the wires to be plated in five thickness distribution regions in a case where a width of the dummy conductive portion 131 itself is 0.5 mm.

FIGS. 56E and 56F are a set of comparative experiments. FIG. 56E represents the thickness distribution of the wires to be plated in five thickness distribution regions in a case where no dummy conductive portion 131 is provided. FIG. 56F represents the thickness distribution of the wires to be plated in five thickness distribution regions in a case where a width of the dummy conductive portion 131 itself is 1 mm.

FIGS. 56G and 56H are a set of comparative experiments. FIG. 56G represents the thickness distribution of the wires to be plated in five thickness distribution regions in a case where no dummy conductive portion 131 is provided. FIG. 56H represents the thickness distribution of the wires to be plated in five thickness distribution regions in a case where a width of the dummy conductive portion 131 itself is 2 mm.

FIGS. 56I and 56J are a set of comparative experiments. FIG. 56I represents the thickness distribution of the wires to be plated in five thickness distribution regions in a case where no dummy conductive portion 131 is provided. FIG. 56J represents the thickness distribution of the wires to be plated in five thickness distribution regions in a case where a width of the dummy conductive portion 131 itself is 4 mm.

FIGS. 56K and 56L are a set of comparative experiments. FIG. 56K represents the thickness distribution of the wires to be plated in five thickness distribution regions in a case where no dummy conductive portion 131 is provided. FIG. 56L represents the thickness distribution of the wires to be plated in five thickness distribution regions in a case where a width of the dummy conductive portion 131 itself is 6 mm.

FIGS. 56M and 56N are a set of comparative experiments. FIG. 56M represents the thickness distribution of the wires to be plated in five thickness distribution regions in a case where no dummy conductive portion 131 is provided. FIG. 56N represents the thickness distribution of the wires to be plated in five thickness distribution regions in a case where a width of the dummy conductive portion 131 itself is 8 mm.

The data in the following Table 6 can be obtained in combination with the thickness distribution of the wires to be plated in the above FIGS. 56A and 56C to 56N and by taking values for calculation.

TABLE 6

| Width of | Maximum | Minimum | Average | |
|---|---|---|---|---|
| the dummy | thickness of | thickness of | value of | Thickness |
| conductive | wires to | wires to | wires to | uniformity |
| portion 131 | be plated | be plated | be plated | of wires to |
| (μm) | (mm) | (mm) | (mm) | be plated |
| No dummy | 5.6596 | 4.7008 | 5 | 9.59% |
| conductive portion | | | | |
| 131 provided | | | | |
| 0.5 | 5.5965 | 4.6938 | 4.9712 | 9.08% |
| 1 | 5.5544 | 4.6555 | 4.9492 | 9.08% |
| 2 | 5.4915 | 4.6398 | 4.9182 | 8.66% |
| 4 | 5.4472 | 4.6126 | 4.886 | 8.54% |
| 6 | 5.4351 | 4.5829 | 4.8723 | 8.75% |
| 8 | 5.4522 | 4.5655 | 4.8642 | 9.11% |

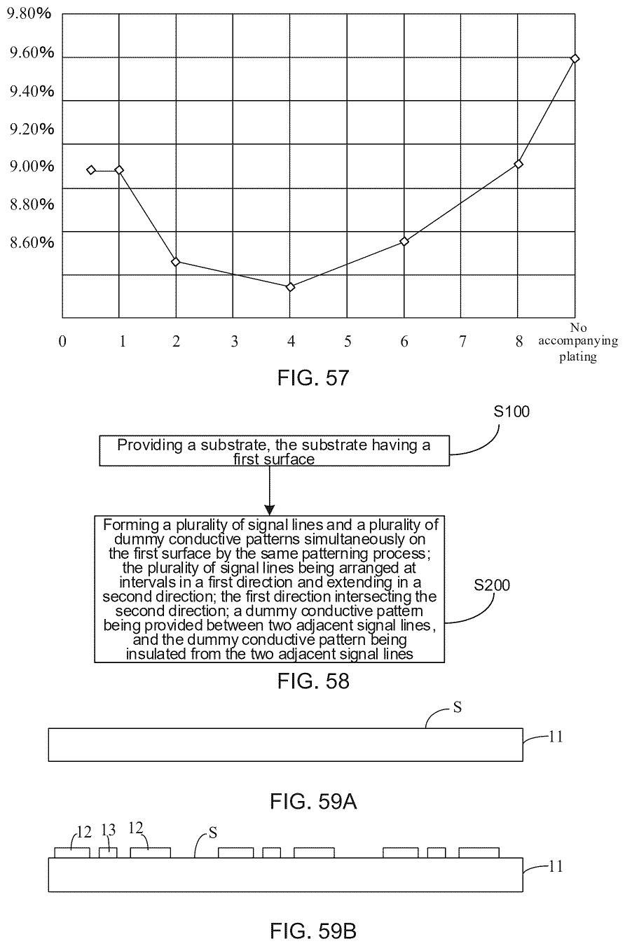

A line chart shown in FIG. 57 may be obtained in combination with the data in Table 6 above. It can be seen from the figure that as the width of the wire to be plated gradually increases, the thickness uniformity of the wires to be plated gradually increases. In a case where the width of the dummy conductive portion 131 is 4 μm, the wires to be plated have the optimal thickness uniformity.

In another aspect, some embodiments of the present disclosure further provide a method for manufacturing a wiring substrate 1. As shown in FIG. 58, the manufacturing method includes steps S100 to S200.

In S100, as shown in FIG. 59A, a substrate 11 is provided, and the substrate 11 has a first surface S.

For example, the material of the substrate 11 is a glass material such as soda-lime glass, quartz glass or sapphire glass, or a metal material such as stainless steel, aluminum or nickel.

In S200, as shown in FIG. 59B, a plurality of signal lines 12 and a plurality of dummy conductive patterns 13 are simultaneously formed on the first surface S by using the same patterning process; the plurality of signal lines 12 are arranged at intervals in the first direction X and extend in the second direction Y; the first direction X and the second direction Y intersect; a dummy conductive pattern 13 is provided between two adjacent signal lines 12, and the dummy conductive pattern 13 is insulated from the two adjacent signal lines 12.

For example, an included angle between the first direction and the second direction is 85°, 90° or 95°.

With the above provision, in a process of forming the signal lines 12 by electroplating, the dummy conductive patterns 13 are formed simultaneously. In a case where areas of bottom surfaces of two adjacent signal lines 12 to be plated are different (i.e., wiring environments of the two signal lines 12 to be plated are different), by reasonably setting the positions of the dummy conductive patterns 13 to be plated and reasonably setting the number of the dummy conductive patterns 13 to be plated, in regions where the two signal lines 12 to be plated are located respectively, proportions of areas of bottom surfaces of metal patterns to be plated (including the signal line 12, the dummy conductive pattern 13 and the connection line 15) are close, so that current densities on the two adjacent signal lines 12 to be plated are close, the electroplating efficiencies are close, and the thicknesses of the two adjacent signal lines 12 are close. Thus, the thickness uniformity of the two adjacent signal lines 12 may be improved, thereby improving yield of the wiring substrate 1 and ensuring reliability of the wiring substrate 1.

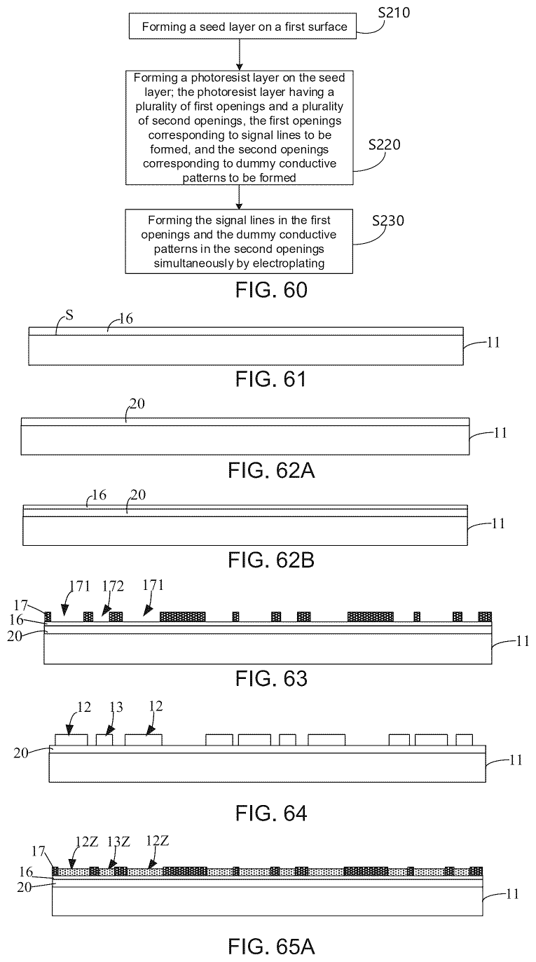

In some embodiments, as shown in FIG. 60, forming a plurality of signal lines 12 and a plurality of dummy conductive patterns 13 simultaneously on the first surface S using the same patterning process in S200 includes steps S210 to S230.

In S210, as shown in FIGS. 60 and 61, a seed layer 16 is formed on the first surface S.

In some examples, the seed layer 16 includes a molybdenum-niobium layer and a seed copper layer, and the molybdenum-niobium layer is located between the seed copper layer and the substrate. The molybdenum-niobium layer and the seed copper layer are sequentially formed on the first surface S.

A thickness of the molybdenum-niobium layer is about 300 angstroms, and a thickness of the seed copper layer is in a range of 0.3 μm to 1.0 μm, inclusive. For example, the thickness of the seed copper layer is 0.3 μm, 0.35 μm, 0.4 μm, 0.5 μm or 1.0 μm.

For example, the molybdenum-niobium layer and the seed copper layer are sequentially formed on the substrate by sputtering.

In some examples, forming the seed layer 16 on the first surface S includes steps S211 to S212.

In S211, as shown in FIG. 62A, a buffer layer 20 is formed on the first surface S.

For example, before the buffer layer 20 is formed on the first surface S, the substrate 11 is cleaned to remove dust and other impurities on the substrate 11, so as to ensure the flatness of the subsequent buffer layer 20.

For example, a thickness of the buffer layer 20 is in a range of 1200 angstroms to 4000 angstroms, inclusive. For example, the thickness of the buffer layer 20 is 1200 angstroms, 1400 angstroms, 2000 angstroms, 2500 angstroms or 4000 angstroms.

In S212, as shown in FIG. 62B, the seed layer 16 is formed on the buffer layer 20.

The buffer layer 20 has a buffering effect. When the substrate 11 is impacted, the buffer layer 20 may absorb the impact force, thereby protecting the seed layer 16 from damage.

In S220, as shown in FIGS. 60 and 63, a photoresist layer 17 is formed on the seed layer 16; the photoresist layer 17 has a plurality of first openings 171 and a plurality of second openings 172, the first openings 171 correspond to the signal lines 12 to be formed, and the second openings 172 correspond to the dummy conductive patterns 13 to be formed.

In some examples, the seed layer 16 may be coated with a photoresist through a coating process to form a photoresist layer 17. In order to help the photoresist to be cured, the photoresist may be baked through a baking process may be used to bake after coating of the photoresist.

A thickness of the photoresist layer 17 may be greater than or equal to 7 μm. For example, the thickness of the photoresist layer 17 is 7 μm, 8 μm or 9 μm, and the specific thickness is determined depending on the thicknesses of the signal line 12 and the dummy conductive pattern 13.

In some examples, after the photoresist layer 17 is formed on the seed layer 16, the photoresist layer 17 is patterned by performing exposure and development processes on the photoresist layer 17 to form a plurality of first openings 171 and a plurality of second openings 172 in the photoresist layer 17.

For example, the photoresist may adopt positive photoresist or negative photoresist. The characteristic of the positive photoresist is that it can dissolve when coming into contact with a developing solution after exposure. The characteristic of the negative photoresist is that it cannot dissolve when coming into contact with the developing solution after exposure.

In S230, as shown in FIGS. 60 and 64, signal lines 12 are formed in the first openings 171 by electroplating, and dummy conductive patterns 13 are simultaneously formed in the second openings 172. In some examples, S230 includes steps S231 to S233.

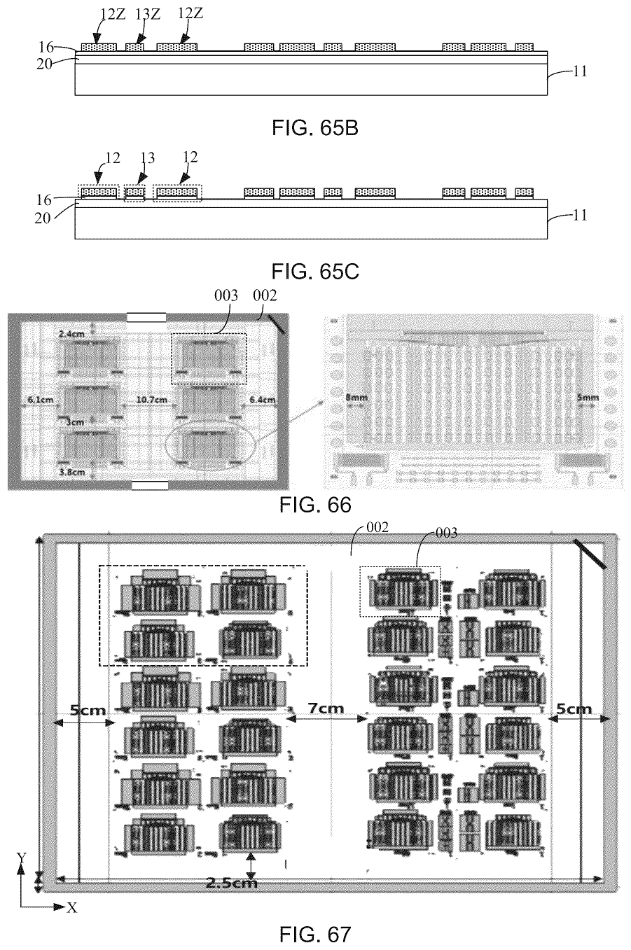

In S231, as shown in FIG. 65A, routing sub-patterns 12Z are formed in the first openings 171 by electroplating, and dummy conductive sub-patterns 13Z are simultaneously formed in the second openings 172.

In S232, as shown in FIG. 65B, the photoresist is stripped off to expose portions of the seed layer 16 corresponding to positions of the stripped photoresist.

In S233, as shown in FIG. 65C, the exposed portions of the seed layer 16 are etched, so that the routing sub-patterns 12Z and portions of the seed layer 16 thereunder form the signal lines 12, and the dummy conductive sub-patterns 13Z and portions of the seed layer 16 thereunder form the dummy conductive patterns 13.

For example, when the exposed portions of the seed layer 16 are etched, the etching time needs to be controlled. Generally, the etching time needs to be appropriately increased, and the actual etching time is 30% to 50% longer than the theoretical etching time. In this way, the seed layer 16 may be overetched to completely remove the portions of the seed layer 16 that needs to be removed, thereby avoiding short circuits between the plurality of signal lines 12.

For example, in a case where the thickness of the molybdenum-niobium layer is 300 angstroms and the thickness of the third copper layer is 0.3 μm, it generally takes about 60 seconds for etching.

Through the above process flow of S210 to S230, in a process of forming the signal lines 12 by electroplating, the dummy conductive patterns 13 are simultaneously formed. In a case where areas of bottom surfaces of two adjacent signal lines 12 to be plated are different (i.e., wiring environments of the two signal lines 12 to be plated are different), by reasonably setting the positions of the dummy conductive patterns 13 to be plated and reasonably setting the number of the dummy conductive patterns 13 to be plated, in regions where the two signal lines 12 to be plated are located respectively, proportions of areas of bottom surfaces of metal patterns to be plated (including the signal line 12, the dummy conductive pattern 13 and the connection line 15) are close, so that current densities on the two adjacent signal lines 12 to be plated are close, the electroplating efficiencies are close, and the thicknesses of the two adjacent signal lines 12 are close. Thus, the thickness uniformity of the two adjacent signal lines 12 may be improved, thereby improving yield of the wiring substrate 1 and ensuring reliability of the wiring substrate 1.

During actual manufacture, a plurality of wiring substrates 1 will be manufactured in the same batch production process. For example, as shown in FIG. 66, a motherboard substrate 002 is divided into a plurality of processing regions 003, and the plurality of processing regions 003 are arranged in an array. Each processing region 003 is provided with a plurality of signal lines 12, a plurality of dummy conductive patterns 13, a plurality of pad units 14 and a plurality of connection lines 15 therein. The motherboard substrate 002 is then cut to separate each processing region 003 from the motherboard substrate 002 to independently constitute a plurality of wiring substrates 1. Thus, the production efficiency may be ensured.

In some examples, as shown in FIG. 66, the motherboard substrate 002 is divided into six processing regions 003, and the six processing regions 003 are arranged in three rows and two columns.

In some other examples, as shown in FIG. 67, the motherboard substrate 002 is divided into twenty-four processing regions 003, and the twenty-four processing regions 003 are arranged in six rows and four columns.

On this basis, with respect to a case where a motherboard substrate 002 has a plurality of processing regions 003, an accompanying plating situation in the intermediate process is introduced.

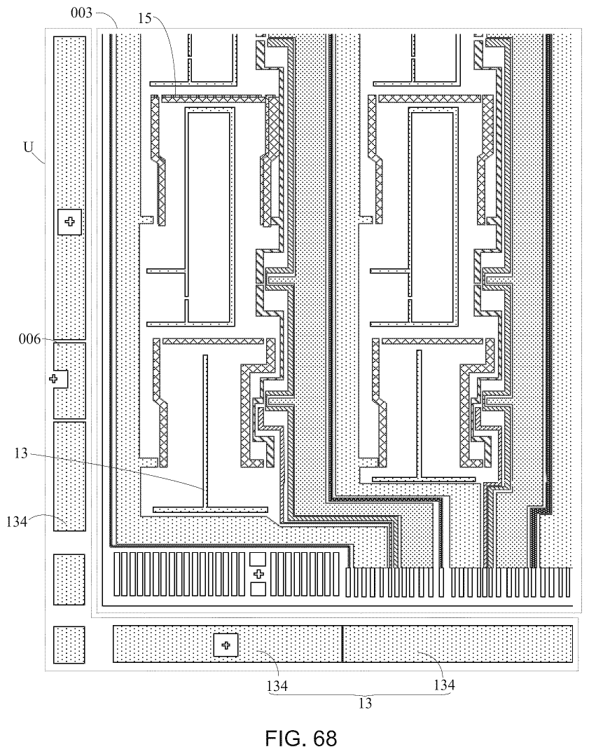

In some embodiments, as shown in FIG. 68, an annular process edge region U is formed around an edge of the processing region 003, and the process edge region U is provided with a dummy conductive pattern 13 therein. Along the circumference of the process edge region U, the dummy conductive pattern 13 includes a plurality of dummy conductive blocks 134 arranged at intervals (with an interval in an order of hundreds of microns, such as not more than 100 μm). By providing the dummy conductive pattern 13 in the process edge region U, the dummy conductive pattern 13 may improve the relatively large thicknesses of the signal lines 12 and the connection lines 15, proximate to the process edge region U, in the processing region 003, thereby improving the thickness uniformity of the connection lines 15, the signal lines 12 and the bonding pattern in the entire processing region 003. In addition, the dummy conductive pattern 13 located in the process edge region U is composed of a plurality of dummy conductive blocks 134. Therefore, during electroplating, the adhesion between the dummy conductive blocks 134 and the motherboard substrate 002 may be ensured to prevent the dummy conductive blocks 134 from falling off.

For example, a width of the dummy conductive block 134 is in a range of 2 mm to 5 mm, inclusive. The width of the dummy conductive block 134 refers to a dimension of the dummy conductive block 134 in a direction parallel to the first surface S and perpendicular to an extension direction of the dummy conductive block 134.

For example, the width of the dummy conductive block 134 is 2 mm, 2.5 mm, 3 mm, 3.5 mm, 4 mm or 5 mm.

For example, each two adjacent dummy conductive blocks 134 have a distance therebetween ranging from 0.1 mm to 0.3 mm, inclusive. For example, the distance between each two adjacent dummy conductive blocks 134 is 0.1 mm, 0.13 mm, 0.15 mm, 0.17 mm, 0.2 mm or 0.3 mm.

For example, a length of the dummy conductive block 134 is in a range of 10 mm to 20 mm, inclusive. For example, the length of the dummy conductive block 134 is 10 mm, 12 mm, 15 mm, 17 mm or 20 mm.

The length of the dummy conductive block 134 refers to a dimension of the dummy conductive block 134 in a circumferential direction of the processing region 003.

In order to ensure smooth completion of the intermediate process, as shown in FIG. 68, a plurality of alignment patterns are provided outside the processing region 003. The alignment pattern is used to assist in completing the production of the wiring substrate 1.

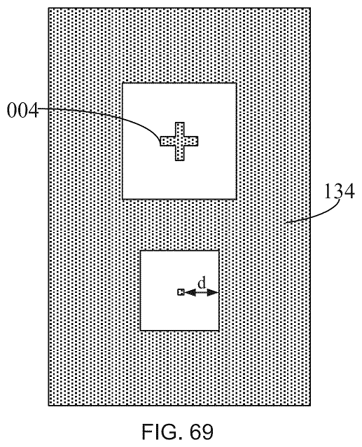

For example, FIG. 69 shows first alignment patterns 004, and the first alignment patterns 004 are disposed in the process edge region U. The dummy conductive block 134 has a plurality of first opening portions, and the first alignment pattern 004 is disposed in the first opening portion.

For example, the first alignment patterns 004 include a first “cross-shaped” pattern and a first square pattern. The first opening portion has a square structure. The first “cross-shaped” pattern is provided in a first opening portion and is located at the center position. The first square pattern is provided in another first opening portion and is located at the center position of the first opening portion.

For example, a distance d between edges, close to each other, of the first square pattern and the first opening portion may be 500 μm.

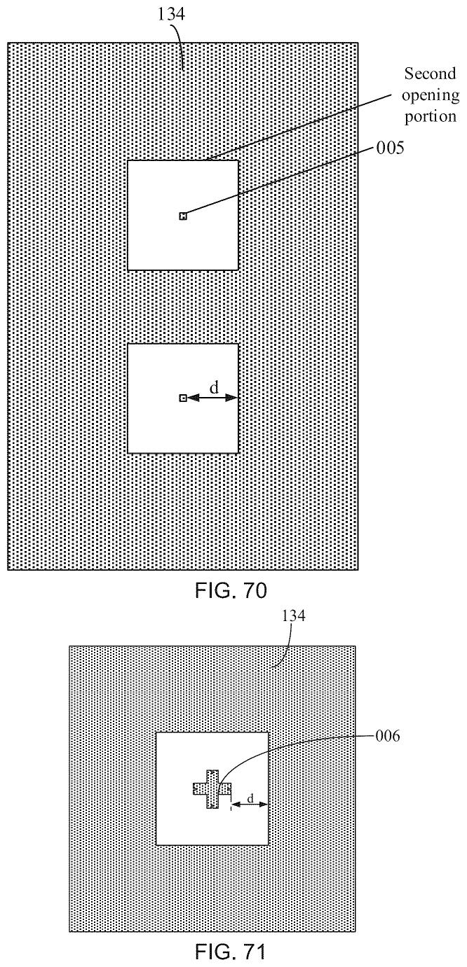

For example, FIG. 70 shows compensation (TP) alignment patterns. The compensation alignment patterns 005 are disposed in the process edge region U. The dummy conductive block 134 is provided with a plurality of second opening portions therein, and the compensation alignment pattern 005 is disposed in the second opening portion.

The compensation alignment patterns 005 include two second square patterns, the second opening portion has a square structure, and the two second square patterns are each disposed in a respective second opening portion.

For example, a distance d between edges, close to each other, of the second square pattern and the second opening portion may be 500 μm.

For example, FIG. 71 shows a cutting alignment pattern. The cutting alignment pattern 006 is disposed in the process edge region U. The dummy conductive block 134 is provided with a plurality of third opening portions therein, and the cutting alignment pattern 006 is disposed in the third opening portion.

The cutting alignment pattern 006 includes a second “cross-shaped” pattern, the third opening portion has a square structure, and the second “cross-shaped” pattern is disposed in the third opening portion.

For example, a distance between edges, close to each other, of the third square pattern and the third opening portion may be 500 μm.

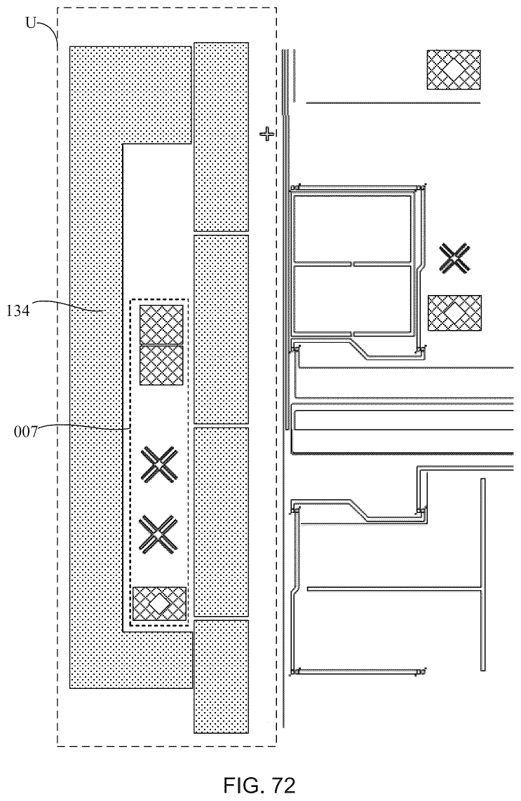

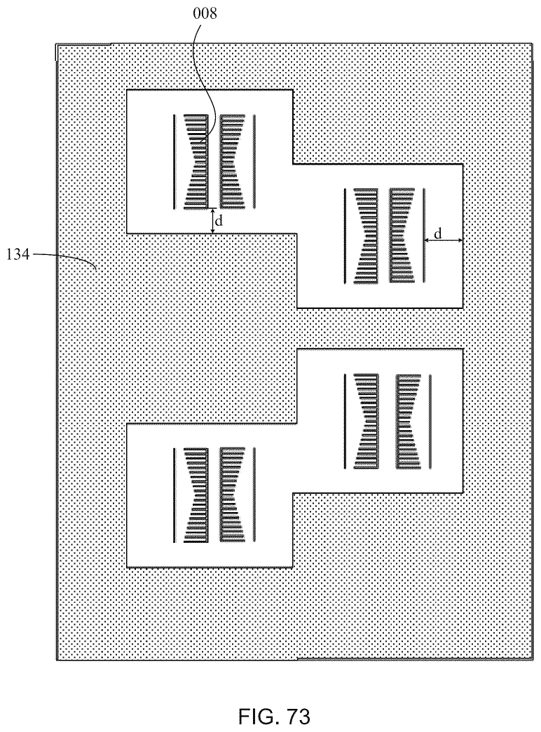

For example, FIG. 72 shows second alignment patterns 007. There are a plurality of second alignment patterns 007, and at least one second alignment pattern 007 is disposed in the process edge region U. The dummy conductive block 134 has fourth opening portions, and the second alignment pattern 007 is disposed in the fourth opening portion.

For example, FIG. 73 shows baffle alignment patterns 008. There are a plurality of baffle alignment patterns 008, and the plurality of baffle alignment patterns 008 are located on a side of the process edge region U away from the processing region 003. During electroplating, in order to ensure the thickness uniformity of the baffle alignment patterns 008, the connection lines 15 and the signal lines 12, a dummy conductive pattern 13 is also provided on the side of the process edge region U away from the processing region 003. The dummy conductive pattern 13 includes a dummy conductive block 134. The dummy conductive block 134 is provided with four fifth opening portions therein, and the fifth opening portion is polygonal. At least one baffle alignment pattern 008 is provided in each fifth opening portion. The dummy conductive block 134 is used to provide accompanying plating for the baffle alignment patterns 008 to ensure the thickness uniformity of the baffle alignment patterns 008, the connection lines 15 and the signal lines 12 during electroplating.

In order to more clearly understand which factors will affect the appearance of the alignment pattern during electroplating, the experimental results are studied using the simulation experiment below.

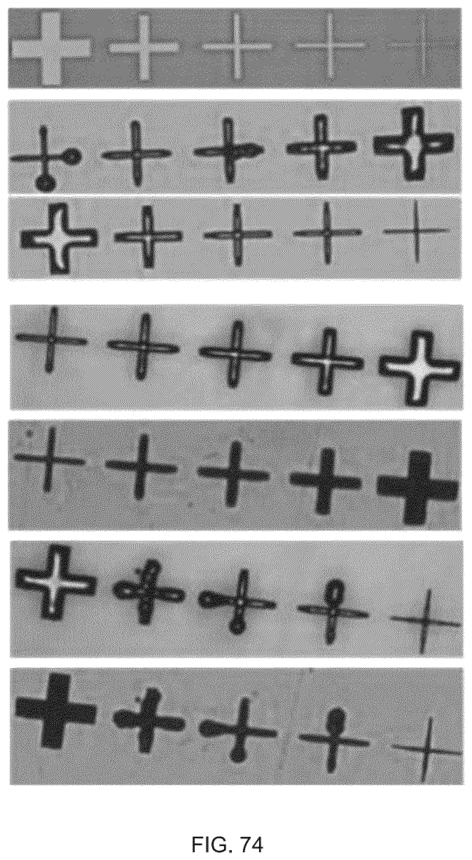

As shown in FIG. 74, the five “cross-shaped” patterns in the first row of the figure are openings corresponding to alignment patterns formed after etching the photoresist layer 17. The five “cross-shaped” patterns in the second row and the five “cross-shaped” patterns in the third row are appearances of the alignment patterns formed after electroplating. The five “cross-shaped” patterns in the fourth row, the five “cross-shaped” patterns in the fifth row, the five “cross-shaped” patterns in the sixth row and the five “cross-shaped” patterns in the seventh row are appearances of the alignment patterns formed after etching the seed layer 16. It can be concluded from the figure that as the width of the alignment pattern increases, the morphology of the alignment pattern becomes clearer, but there is still a problem that the morphology of the alignment pattern is unclear.

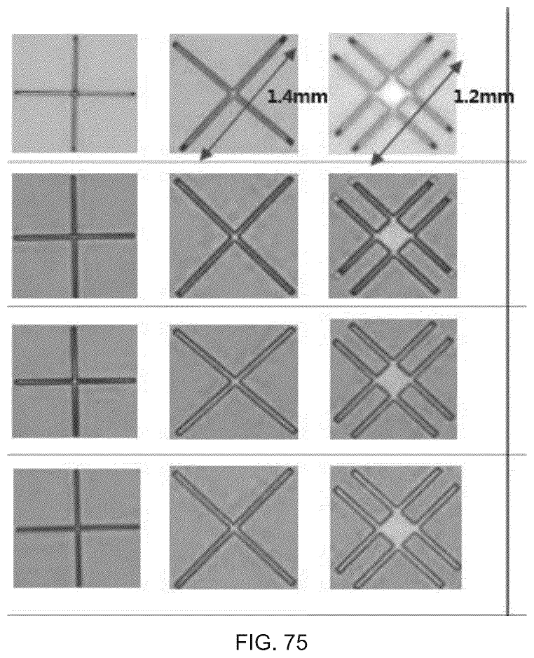

On this basis, a dummy conductive pattern 13 is also provided around the alignment pattern, and the dummy conductive pattern 13 is utilized to reduce the electroplating rate of the alignment pattern and improve the morphology of the alignment pattern. FIG. 75 shows the morphologies of the electroplating patterns after the electroplating is completed. The three alignment patterns in the first row are the morphologies of the alignment patterns in a case of no dummy conductive patterns 13 provided. The three alignment patterns in the second row are the morphologies of the alignment patterns in a case where the dummy conductive pattern 13 is provided and a width of the dummy conductive pattern 13 is 2 mm. The three alignment patterns in the third row are the morphologies of the alignment patterns in a case of the dummy conductive pattern 13 is provided and a width of the dummy conductive pattern 13 is 5 mm. The three alignment patterns in the fourth row are the morphologies of the alignment patterns in a case of the dummy conductive pattern 13 is provided and a width of the dummy conductive pattern 13 is 8 mm.

The width of the dummy conductive pattern 13 refers to a dimension of the dummy conductive block 134 perpendicular to an extension direction thereof in a case where the dummy conductive pattern 13 includes the dummy conductive block 134.

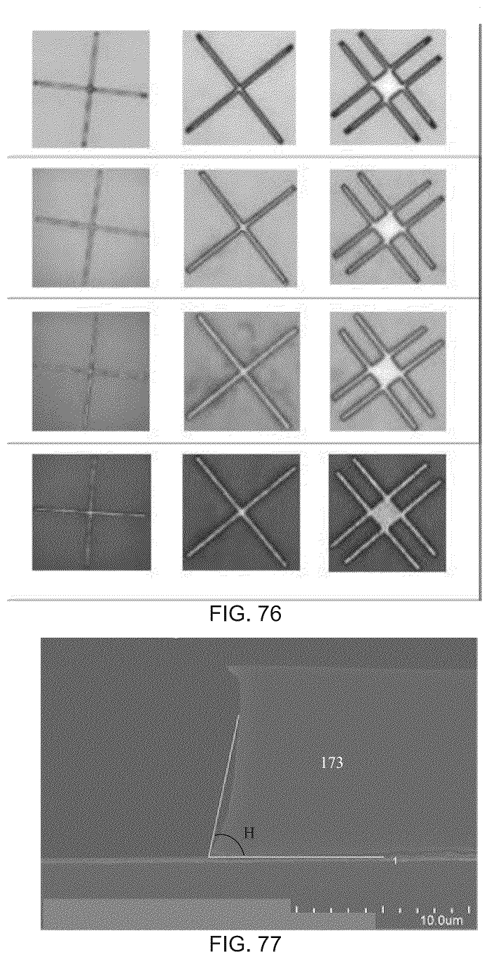

On this basis, FIG. 76 shows the morphologies of the alignment patterns corresponding to that in FIG. 75 after the seed layer 16 is etched. FIG. 76 shows the morphologies of the alignment patterns corresponding to that in FIG. 75 after the seed layer 16 is etched. The three alignment patterns in the first row are the morphologies of the alignment patterns in a case of no dummy conductive patterns 13 provided. The three alignment patterns in the second row are the morphologies of the alignment patterns in a case where the dummy conductive pattern 13 is provided and a width of the dummy conductive pattern 13 is 2 mm. The three alignment patterns in the third row are the morphologies of the alignment patterns in a case of the dummy conductive pattern 13 is provided and a width of the dummy conductive pattern 13 is 5 mm. The three alignment patterns in the fourth row are the morphologies of the alignment patterns in a case of the dummy conductive pattern 13 is provided and a width of the dummy conductive pattern 13 is 8 mm. It can be seen according to the morphology comparison in the above figures that, as the width of the dummy conductive block 134 increases, the morphology of the alignment pattern becomes clearer.

In order to more clearly understand the actual manufacturing process of the display apparatus 001 in the embodiments of the present disclosure, the actual manufacturing process of the display apparatus 001 is introduced below in a case where the connection lines 15 and the signal lines 12 are located in the same conductive layer.

A motherboard substrate 002 is provided, and the motherboard substrate 002 is cleaned to remove dust and other impurities on the motherboard substrate 002. The motherboard substrate 002 has a first surface S, and the first surface S is provided with a buffer layer 20 thereon. A seed layer 16 is formed on the buffer layer 20 by sputtering, and a photoresist is applied onto the seed layer 16 by coating to form a photoresist layer 17. The photoresist layer 17 is exposed and developed to form a plurality of first openings 171, a plurality of second openings 172, a plurality of third openings, a plurality of first opening portions, a plurality of second opening portions, a plurality of third opening portions, a plurality of fourth opening portions and a plurality of fifth opening portions in the photoresist layer 17. Electroplating is performed to form routing sub-patterns 12Z in the first openings 171, dummy conductive sub-patterns in the second openings 172, connecting sub-lines and pad sub-units in the third openings, and corresponding alignment patterns in the first opening portions, the second opening portions, the third opening portions, the fourth opening portions and the fifth opening portions. The seed layer 16 is then etched, so that the routing sub-patterns 12Z and portions of the seed layer 16 thereunder form the signal lines 12, the connecting sub-lines and portions of the seed layer 16 thereunder form the connection lines 15, and the pad sub-units and portions of the seed layer 16 thereunder form the pad units 14. Then, the motherboard substrate 002 is precisely cut along a first annular cutting line 009 outside the process edge region U using the cutting alignment pattern 006, and the process edge region U and the processing region 003 are cut and retained, where the first annular cutting line 009 surrounds the process edge region U.

Then, a photosensitive white ink material is coated on a side of the signal lines 12 and the connection lines 15 away from the first surface S. After the photosensitive white ink material is cured, a photosensitive white ink layer is formed on the signal lines 12 and the connection lines 15. The photosensitive white ink layer is exposed and developed to form a plurality of fourth openings in the photosensitive white ink layer. The fourth openings correspond to the positions of the pad units 14, so that the pad units 14 are exposed. Then, a thermosetting white ink material is further disposed around the fourth opening to reduce an opening area of the fourth opening.

Then, a nickel-gold layer is formed on a surface of a portion of the pad unit 14 exposed by the fourth opening. The nickel-gold layer may prevent oxidation of the pad unit 14 and also facilitate the subsequent fixation of the pad unit 14 with components such as the light-emitting device 2 through reflow soldering. After the nickel-gold layer is formed, necessary electrical performance tests are performed on the nickel-gold layer to ensure the normal provision of the nickel-gold layer. Then, the pad unit 14 is fixedly connected to the light-emitting device 2 and the driver chip IC through a reflow soldering process. Then, the connection between the light-emitting device 2 and the pad unit 14 and between the driver chip IC and the pad unit 14 are tested, and the light-emitting device 2 and the driver chip IC with poor connection are located and reworked. Furthermore, a protection structure may further be provided for the light-emitting device 2 and/or the driver chip IC.

Then, the motherboard substrate 002 is cut along a second annular cutting line 0010 between the process edge region U and the processing region 003 to remove the process edge region U and retain the processing region 003 only. Next, the flexible printed circuit board is bonded together with the bonding pins 18 in the peripheral region 1b and subjected to an aging treatment, so as to produce the light-emitting substrate 01. The display panel 02 is then provided on a light-exit surface of the light-emitting substrate 01, and supporting portions are provided between the light-emitting substrate 01 and the display panel 02 to support the display panel 02, so as to form the display apparatus 001. Then, the display apparatus 001 is subjected to a factory inspection. The second annular cutting line 0010 surrounds the processing region 003.

During actual manufacture, when the motherboard substrate 002 is coated with the photoresist, either positive photoresist or negative photoresist may be used.

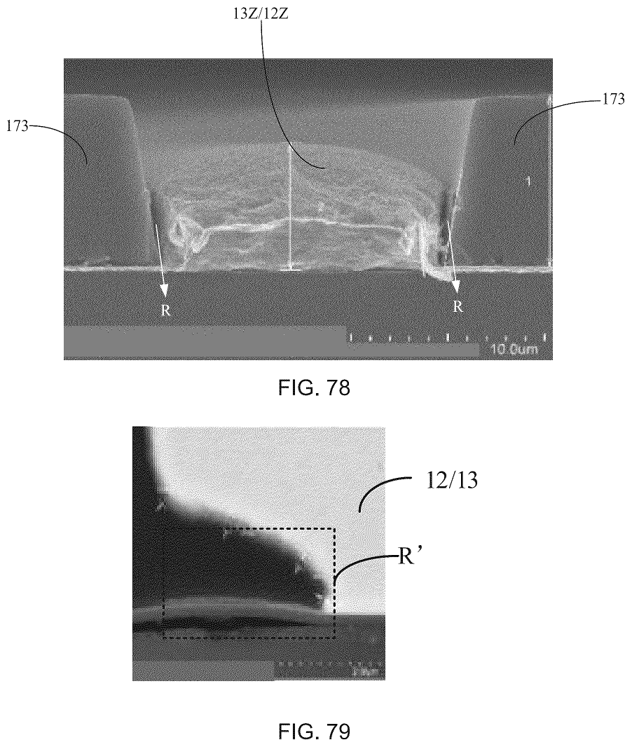

For example, as shown in FIGS. 77 to 79, for the positive photoresist, after the photoresist layer 17 is exposed and developed, a plurality of photoresist retaining walls 173 with right trapezoidal cross-sections will be formed, and an angle H of a bottom angle of the right trapezoid is in a range of 80° to 90°, inclusive. Each two adjacent photoresist retaining walls 173 has a first opening 171, a second opening 172, a third opening, a first opening portion, a second opening portion, a third opening portion, a fourth opening portion or a fifth opening portion formed therebetween. Then, a routing sub-pattern 12Z, a dummy conductive sub-pattern 13Z and the like are formed in the first opening 171, the second opening 172, the third opening, the first opening portion, the second opening portion, the third opening portion, the fourth opening portion or the fifth opening portion by electroplating. However, since the photoresist retaining wall 173 has a right trapezoidal cross-section shape, after electroplating, a gap R as shown in FIG. 78 will appear between the routing sub-pattern 12Z and the photoresist retaining wall 173 or between the dummy conductive sub-pattern 13Z and the photoresist retaining wall 173, and in a portion proximate to the first surface S. When the photoresist retaining wall 173 is removed and the seed layer 16 is etched, the gap R will become large, such as a region R′ shown in FIG. 79. Thus, the service life of the connection line 15 or the signal line 12 will be affected.

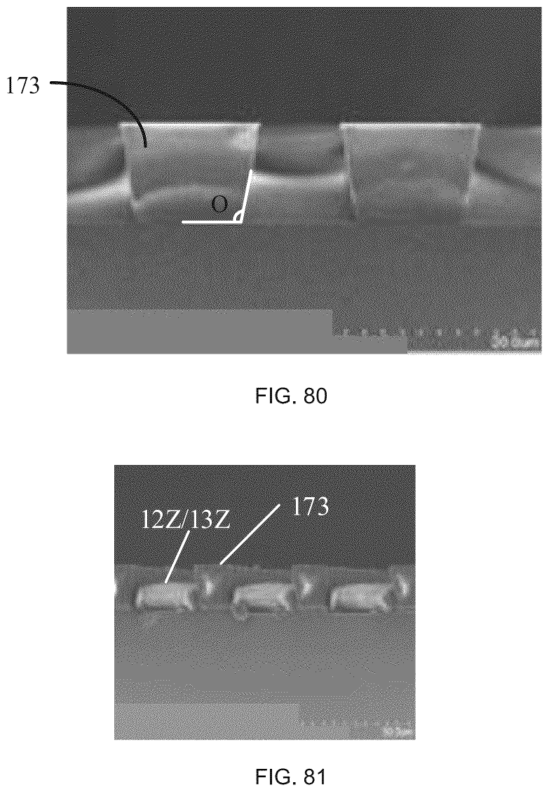

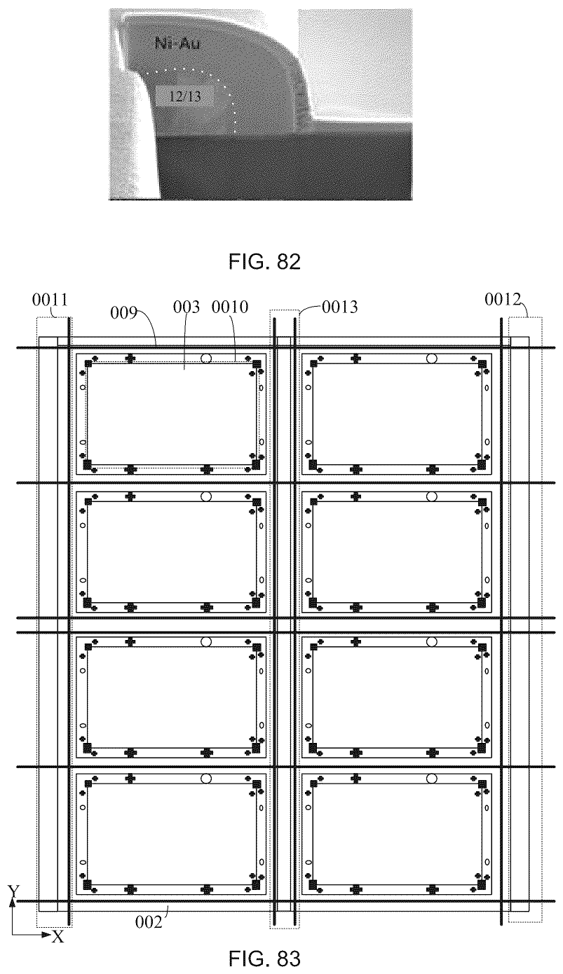

For example, as shown in FIGS. 80 to 82, for the negative photoresist, after the photoresist layer 17 is exposed and developed, a plurality of photoresist retaining walls 173 with inverted trapezoidal cross-sections will be formed. As shown in FIG. 81, an angle O of a bottom angle of the inverted trapezoid is about 102°. Thus, after electroplating, the routing sub-pattern 12Z and the dummy conductive sub-pattern 13Z have right trapezoidal cross-section shapes. As shown in FIG. 82, after the seed layer 16 is subsequently etched, the formed signal line 12 and dummy conductive pattern 13 will not have gaps, thereby ensuring the service lives of the connection line 15 and the signal line 12.

In addition, as shown in FIG. 83, during manufacture, since a clamp is needed to clamp a first electrode region 0011 and a second electrode region 0012 of the substrate 11 and make the clamp in contact with the seed layer 16, when the photoresist layer 17 is exposed and developed, part of the photoresist located in the first electrode region 0011 and the second electrode region 0012 is needed to be removed, so that the clamp may be in contact with the seed layer 16.

A mask is required during exposure and development. In the electroplating scheme, the photoresist on the seed layer 16 is a positive photoresist. Therefore, when the mask is designed, portions of the mask without shielding patterns provided correspond to positions of the signal lines 12, the connection lines 15 and the bonding patterns.

Since there are a plurality of processing regions 003 on the motherboard substrate 002, a plurality of wiring substrates 1 will be formed at one time. During exposure and development of the photoresist layer 17, a size of the mask can only meet the requirements of processing the photoresist layer 17 in a processing region 003 at the same time. Thus, as shown in FIG. 83, when a portion of the photoresist layer 17 in a processing region 003 is exposed and developed, the exposure and development processes will also be performed in the middle region 0013 of the motherboard substrate 002, so that a portion of the seed layer 16 in the middle region 0013 will also be exposed. In the subsequent electroplating process, the copper layer will also be deposited by electroplating in the middle region 0013.

Based on this, when the mask is used for processing, a baffle is needed to block a portion of the photoresist layer 17 corresponding to the middle region 0013, so as to avoid exposure and development of a portion of the photoresist layer 17 in the middle region 0013, avoid decomposition under light of the portion of the photoresist layer 17 in the middle region 0013, and further prevent the middle region 0013 from forming a layer of copper by electroplating, thereby reducing the waste of the copper material, and also ensuring smooth cutting of the motherboard substrate 002 to avoid breakage of the motherboard substrate 002.

For example, a dimension of the first electrode region 0011 in the first direction is in a range of 20 mm to 25 mm, inclusive. For example, the dimension of the first electrode region 0011 in the first direction is 20 mm, 22 mm, 23 mm, 24 mm or 25 mm.

For example, a dimension of the middle region 0013 in the first direction is in a range of 20 mm to 25 mm, inclusive. For example, the dimension of the middle region 0013 in the first direction is 20 mm, 21 mm, 23 mm, 24 mm or 25 mm.

In some embodiments, as shown in FIG. 84, the first vertical sub-segment 12D11 is widened by 77 μm in a negative direction of the first direction, so that a distance between the first vertical sub-segment 12D11 and the second annular cutting line 0010 is 0.6 mm. Therefore, the first vertical sub-segment 12D11 may also serve as the dummy conductive pattern 13 to improve the thickness uniformity of the connection lines 15, the signal lines 12 and the bonding pins 18.

In order to well understand a role played by the dummy conductive pattern 13 in the manufacturing process of the wiring substrate 1, the experimental demonstration is carried out again to prove that the provision of the dummy conductive pattern 13 may improve the thickness uniformity of the connection lines 15, the signal lines 12, the bonding patterns and the alignment patterns.

For example, in a case where a motherboard substrate 002 is provided with six processing regions 003 therein and the six processing regions 003 are arranged in three rows and two columns, if the distances between the dummy conductive portions 131 and the wires to be plated are different, the thickness uniformity of the wires to be plated at different positions in the processing region 003 is studied. The data in Tables 7 to 9 are obtained.

TABLE 7

| | Distance | | | | | | | | | | | |
|---|---|---|---|---|---|---|---|---|---|---|---|---|
| | between | | | | | | | | | | | |
| | a dummy | | | | | | | | | | | Average |
| | conductive | | | | | | | | | | | thickness |
| | portion | | | | | | | | | Maximum | Minimum | of a |
| | 131 and | | | | | | | | Uniformity | thickenss | thickness | plurality |
| | a wire to | Thickness of a wire to be plated | | | | | | | of wires | of wires | of wires | of wires |
| | be plated | Line | Line | Line | Line | Line | Line | Line | to be | to be | to be | to be |
| Location | (mm) | 1 | 2 | 3 | 4 | 5 | 6 | 7 | plated | plated | plated | plated |
| Short | 0.76 | 9.0 | 9.0 | 8.7 | 8.9 | 9.1 | 9.1 | 9.2 | 2.8% | 9.2 | 8.7 | 9.0 |
| side | 2 | 8.7 | 8.5 | 7.9 | 8.5 | 8.5 | 8 | 8.4 | 4.8% | 8.7 | 7.9 | 8.4 |
| | 5 | 9.8 | 9.3 | 8.8 | 9 | 8.8 | 8.6 | 8.8 | 6.5% | 9.8 | 8.6 | 9.0 |

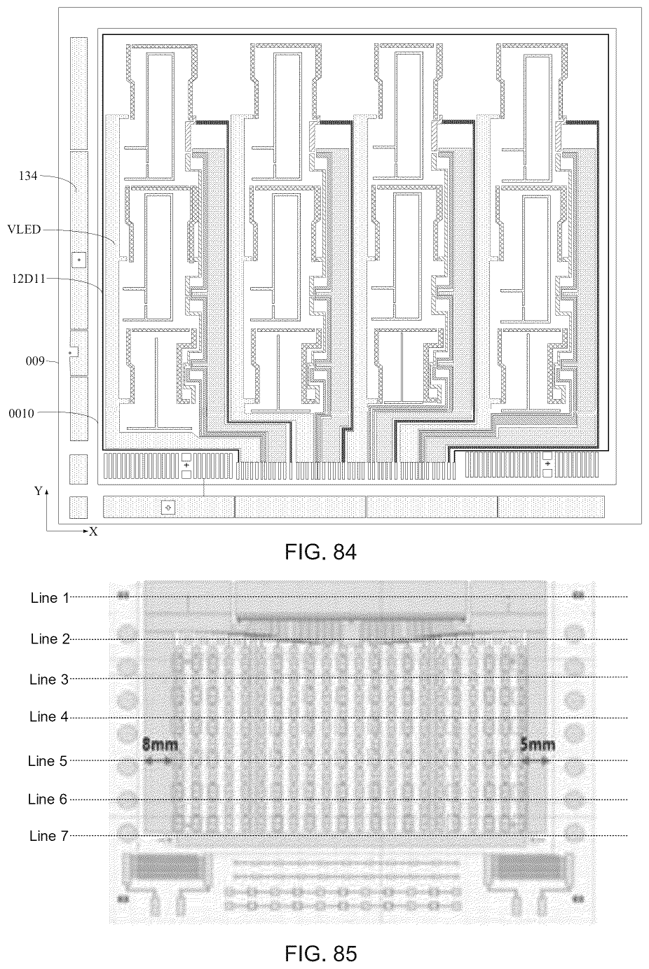

As shown in FIG. 85, lines 1 to 7 represent the division of the short side (vertical side) of the substrate 11, and a distance between two adjacent lines is 5 mm. In a case where a distance between the dummy conductive portion 131 and the wire to be plated is 0.76 mm, the lines 1 to 7 intersect with the wires to be plated on the substrate 11. A point is taken from each of intersection lines of the lines 1 to 7 with the wires to be plated to obtain 7 values, the maximum value of the 7 values is 9.2 μm, the minimum value of the 7 values is 8.7 μm, and the average value of the 7 values is calculated to be 9.0. On this basis, the film thickness uniformity is calculated to be 2.8%.

Similarly, in a case where the distance between the dummy conductive portion 131 and the wire to be plated is 2 mm, the lines 1 to 7 intersect with the wires to be plated on the substrate 11. A point is taken from each of intersection lines of the lines 1 to 7 with the wires to be plated to obtain 7 values, the maximum value of the 7 values is 8.7 μm, the minimum value of the 7 values is 7.9 μm, and the average value of the 7 values is calculated to be 8.4. On this basis, the film thickness uniformity of the wires to be plated is calculated to be 4.8%.

Similarly, in a case where the distance between the dummy conductive portion 131 and the wire to be plated is 5 mm, the lines 1 to 7 intersect with the wires to be plated on the substrate 11. A point is taken from each of intersection lines of the lines 1 to 7 with the wires to be plated to obtain 7 values, the maximum value of the 7 values is 9.8 μm, the minimum value of the 7 values is 8.6 μm, and the average value of the 7 values is calculated to be 8.4. On this basis, the film thickness uniformity of the wires to be plated is calculated to be 6.5%.

It can be seen based on the above data that as the distance between the wire to be plated and the dummy conductive portion 131 decreases, the uniformity of the wires to be plated decreases from 6.5% to 2.8%. Furthermore, in a case where the distance between the dummy conductive portion 131 and the wire to be plated is 0.76 μm, a thickness value at a point where the outermost line 1 intersects with the wire to be plated is not the maximum value, and the edge effect during electroplating is also improved.

TABLE 8

| | Distance | | | | | | | | | | | |
|---|---|---|---|---|---|---|---|---|---|---|---|---|
| | between | | | | | | | | | | | |
| | a dummy | | | | | | | | | | | Average |
| | conductive | | | | | | | | | | | thickness |
| | portion | | | | | | | | | Maximum | Minimum | of a |
| | 131 and | | | | | | | | Uniformity | thickness | thickness | plurality |
| | a wire to | Thickness of a wire to be plated | | | | | | | of wires | of wires | of wires | of wires |
| | be plated | Line | Line | Line | Line | Line | Line | Line | to be | to be | to be | to be |
| Location | (mm) | 1 | 2 | 3 | 4 | 5 | 6 | 7 | plated | plated | plated | plated |
| Long | 0.6 | 9.9 | 9.8 | 9.7 | 9.6 | 9.5 | 9.4 | 9.5 | 2.6% | 9.9 | 9.4 | 9.6 |
| side | 2 | 10.2 | 9.7 | 9.6 | 9.5 | 9.4 | 9.3 | 9.3 | 4.6% | 10.2 | 9.3 | 9.6 |
| | 4 | 9 | 8.7 | 8.6 | 8.4 | 8.4 | 8.4 | 8.4 | 3.4% | 9.0 | 8.4 | 8.6 |
| | 7 | 10.1 | 9.4 | 8.9 | 8.8 | 8.7 | 8.7 | 8.4 | 9.2% | 10.1 | 8.4 | 9.0 |

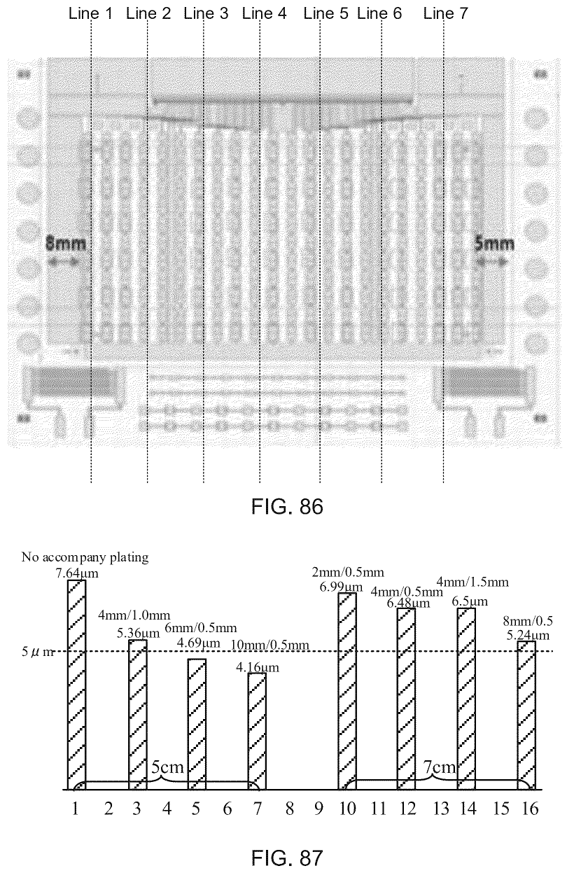

As shown in FIG. 86, lines 1 to 7 represent the division of the long side (horizontal side) of the substrate 11, and a distance between two adjacent lines is 5 mm. In a case where a distance between the dummy conductive portion 131 and the wire to be plated is 0.6 mm, the lines 1 to 7 intersect with the wires to be plated on the substrate 11. A point is taken from each of intersection lines of the lines 1 to 7 with the wires to be plated to obtain 7 values, the maximum value of the 7 values is 9.9 μm, the minimum value of the 7 values is 9.4 μm, and the average value of the 7 values is calculated to be 9.6. On this basis, the film thickness uniformity is calculated to be 2.6%.

Similarly, in a case where a distance between the dummy conductive portion 131 and the wire to be plated is 2 mm, the lines 1 to 7 intersect with the wires to be plated on the substrate 11. A point is taken from each of intersection lines of the lines 1 to 7 with the wires to be plated to obtain 7 values, the maximum value of the 7 values is 10.2 μm, the minimum value of the 7 values is 9.3 μm, and the average value of the 7 values is calculated to be 9.6. On this basis, the film thickness uniformity of the wires to be plated is calculated to be 4.6%.

Similarly, in a case where a distance between the dummy conductive portion 131 and the wire to be plated is 4 mm, the lines 1 to 7 intersect with the wires to be plated on the substrate 11. A point is taken from each of intersection lines of the lines 1 to 7 with the wires to be plated to obtain 7 values, the maximum value of the 7 values is 9.0 μm, the minimum value of the 7 values is 8.4 μm, and the average value of the 7 values is calculated to be 8.6. On this basis, the film thickness uniformity of the wires to be plated is calculated to be 3.4%.

Similarly, in a case where a distance between the dummy conductive portion 131 and the wire to be plated is 7 mm, the lines 1 to 7 intersect with the wires to be plated on the substrate 11. A point is taken from each of intersection lines of the lines 1 to 7 with the wires to be plated to obtain 7 values, the maximum value of the 7 values is 10.1 μm, the minimum value of the 7 values is 8.4 μm, and the average value of the 7 values is calculated to be 9.0. On this basis, the film thickness uniformity of the wires to be plated is calculated to be 9.2%.

It can be seen based on the above data that as the distance between the wire to be plated and the dummy conductive portion 131 decreases, the uniformity of the wires to be plated decreases from 9.2% to 2.6%. Furthermore, in a case where the distance between the dummy conductive portion 131 and the wire to be plated is 0.6 μm, a thickness value at a point where the outermost line 1 intersects with the wire to be plated is not the maximum value, and the edge effect during electroplating is also improved.

TABLE 9

| | Distance | | | | | | | | | | | |
|---|---|---|---|---|---|---|---|---|---|---|---|---|
| | between | | | | | | | | | | | |
| | a dummy | | | | | | | | | | | Average |
| | conductive | | | | | | | | | | | thickness |
| | portion | | | | | | | | | Maximum | Minimum | of a |
| | 131 and | | | | | | | | Uniformity | thickness | thickness | plurality |
| | a wire to | Thickness of a wire to be plated | | | | | | | of wires | of wires | of wires | of wires |
| | be plated | Line | Line | Line | Line | Line | Line | Line | to be | to be | to be | to be |
| Location | (mm) | 1 | 2 | 3 | 4 | 5 | 6 | 7 | plated | plated | plated | plated |
| Peripheral | 0.6 | 7.2 | 7.3 | 7.3 | 6.8 | 7.0 | 6.7 | 7.1 | 4.3% | 7.3 | 6.7 | 7.1 |
| region | 2 | 7.3 | 7.3 | 7.4 | 7.1 | 6.7 | 7.1 | 6.7 | 5.0% | 7.4 | 6.7 | 7.1 |
| 1b | 4 | 6.9 | 6.8 | 6.4 | 6.4 | 6.6 | 6.5 | 7.0 | 4.5% | 7.0 | 6.4 | 6.7 |
| | 7 | 5.9 | 6.5 | 6.4 | 6.1 | 6.1 | 6.2 | 6.8 | 7.1% | 6.8 | 5.9 | 6.3 |

As shown in FIG. 85, lines 1 to 7 represent the division of the peripheral region 1b of the substrate 11, and a distance between two adjacent lines is 5 mm. In a case where a distance between the dummy conductive portion 131 and the wire to be plated is 0.6 mm, each of the lines 1 to 7 intersects with the wires to be plated on the substrate 11. A point is taken from each of intersection lines of the lines 1 to 7 with the wires to be plated to obtain 7 values, the maximum value of the 7 values is 7.3 μm, the minimum value of the 7 values is 6.7 μm, and the average value of the 7 values is calculated to be 7.1. On this basis, the film thickness uniformity is calculated to be 4.3%.

Similarly, in a case where a distance between the dummy conductive portion 131 and the wire to be plated is 2 mm, each of the lines 1 to 7 intersects with the wires to be plated on the substrate 11. A point is taken from each of intersection positions of the lines 1 to 7 with the wires to be plated to obtain 7 values, the maximum value of the 7 values is 7.4 μm, the minimum value of the 7 values is 6.7 μm, and the average value of the 7 values is calculated to be 7.1. On this basis, the film thickness uniformity of the wires to be plated is calculated to be 5.0%.

Similarly, in a case where a distance between the dummy conductive portion 131 and the wire to be plated is 4 mm, the lines 1 to 7 intersect with the wires to be plated on the substrate 11. A point is taken from each of intersection lines of the lines 1 to 7 with the wires to be plated to obtain 7 values, the maximum value of the 7 values is 7.0 μm, the minimum value of the 7 values is 6.4 μm, and the average value of the 7 values is calculated to be 6.7. On this basis, the film thickness uniformity of the wires to be plated is calculated to be 4.5%.

Similarly, in a case where a distance between the dummy conductive portion 131 and the wire to be plated is 7 mm, the lines 1 to 7 intersect with the wires to be plated on the substrate 11. A point is taken from each of intersection lines of the lines 1 to 7 with the wires to be plated to obtain 7 values, the maximum value of the 7 values is 6.8 μm, the minimum value of the 7 values is 5.9 μm, and the average value of the 7 values is calculated to be 9.0. On this basis, the film thickness uniformity of the wires to be plated is calculated to be 7.1%.

It can be seen based on the above data that as the distance between the wire to be plated and the dummy conductive portion 131 decreases, the uniformity of the wires to be plated decreases from 7.1% to 4.3%.

It can be seen in combination with the data in Tables 7 to 9 above that as the distance between the dummy conductive portion 131 and the wire to be plated decreases, the thickness uniformity of the wires to be plated increases.

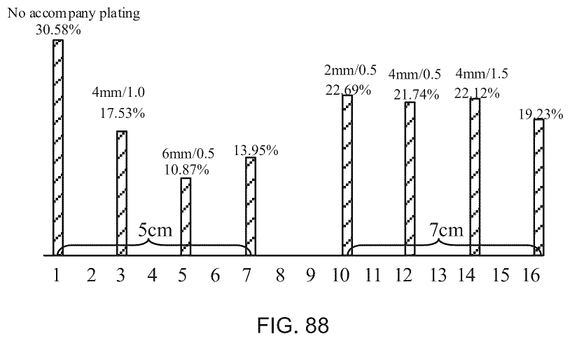

As shown in FIG. 67, there are six rows and four columns, totaling twenty-four, of processing regions 003 arranged on a motherboard substrate 002, a left side edge of a processing region 003 in the first column is 5 cm away from a left side edge of the motherboard substrate 002, a distance between a processing regions 003 in the second column and a processing regions 003 in the third column is 7 cm, and a right side edge of a processing region 003 in the fourth column is 5 cm away from a right side edge of the motherboard substrate 002. In this case, the thickness uniformity of the wires to be plated on the entire motherboard substrate 002 is studied to obtain a bar chart as shown in FIG. 88.

From left to right, the first column shape represents a case where no dummy conductive portion 131 is provided, and in this case, the thickness uniformity of the wires to be plated is 30.58%. The second column shape represents a case where a distance between the wire to be plated and the dummy conductive portion 131 is 4 mm and a width of the dummy conductive portion 131 itself is 1.0 mm, and the thickness uniformity of the wires to be plated is 17.53%. The third column shape represents a case where a distance between the wire to be plated and the dummy conductive portion 131 is 6 mm and a width of the dummy conductive portion 131 itself is 0.5 mm, and the thickness uniformity of the wires to be plated is 10.87%. The fourth column shape represents a case where a distance between the wire to be plated and the dummy conductive portion 131 is 10 mm and a width of the dummy conductive portion 131 itself is 0.5 mm, and the thickness uniformity of the wires to be plated is 13.95%. The fifth column shape represents a case where a distance between the wire to be plated and the dummy conductive portion 131 is 2 mm and a width of the dummy conductive portion 131 itself is 0.5 mm, and the thickness uniformity of the wires to be plated is 22.69%. The sixth column shape represents a case where a distance between the wire to be plated and the dummy conductive portion 131 is 4 mm and a width of the dummy conductive portion 131 itself is 0.5 mm, and the thickness uniformity of the wires to be plated is 21.74%. The seventh column shape represents a case where a distance between the wire to be plated and the dummy conductive portion 131 is 4 mm and a width of the dummy conductive portion 131 itself is 1.5 mm, and the thickness uniformity of the wires to be plated is 22.12%. The eighth column shape represents a case where a distance between the wire to be plated and the dummy conductive portion 131 is 8 mm and a width of the dummy conductive portion 131 itself is 0.5 mm, and the thickness uniformity of the wires to be plated is 19.23%.

It can be seen from the above experimental results that for the wires to be plated in the first column of processing regions 003 and the wires to be plated in the fourth column of processing regions 003, the thickness uniformity of the wires to be plated is optimal in a case where a distance between the wire to be plated and the dummy conductive portion 131 is 6 mm and the width of the dummy conductive portion 131 itself is 0.5 mm.

Furthermore, the first column shape, the second column shape, the third column shape and the fourth column shape each represent the accompanying plating performed in a region with a blank width of 5 cm. The fifth column shape, the sixth column shape, the seventh column shape and the eighth column shape each represent the accompanying plating performed in a region with a blank width of 7 cm. It will be noted that the blank width refers to a width of a region where no metal wire (the signal line 12 and the connection line 15) is provided. It can be seen from the above experimental results that the larger the blank region, the larger the width of the required dummy conductive pattern, and the better the thickness uniformity of the wires to be plated.

For the wires to be plated in the second column of processing regions 003 and the wires to be plated in the third column of processing regions 003, the thickness uniformity of the wires to be plated is optimal in a case where a distance between the wire to be plated and the dummy conductive portion 131 is 8 mm and the width of the dummy conductive portion 131 itself is 0.5 mm.

Then, a study is conducted on whether to provide a dummy conductive pattern and a difference between an actual thickness and a theoretical thickness of the wire to be plated. The theoretical thickness of the wire to be plated is set to 5 μm, as shown in FIG. 87. From left to right, the first column shape represents a case where no dummy conductive portion 131 is provided, and in this case, the actual thickness of the wire to be plated is 7.46 μm. The second column shape represents a case where a distance between the wire to be plated and the dummy conductive portion 131 is 4 mm and a width of the dummy conductive portion 131 itself is 1.0 mm, and the actual thickness of the wire to be plated is 5.36 μm. The third column shape represents a case where a distance between the wire to be plated and the dummy conductive portion 131 is 6 mm and a width of the dummy conductive portion 131 itself is 0.5 mm, and the actual thickness of the wire to be plated is 4.69 μm. The fourth column shape represents a case where a distance between the wire to be plated and the dummy conductive portion 131 is 10 mm and a width of the dummy conductive portion 131 itself is 0.5 mm, and the actual thickness of the wire to be plated is 4.16 μm. The fifth column shape represents a case where a distance between the wire to be plated and the dummy conductive portion 131 is 2 mm and a width of the dummy conductive portion 131 itself is 0.5 mm, and the actual thickness of the wire to be plated is 6.99 μm. The sixth column shape represents a case where a distance between the wire to be plated and the dummy conductive portion 131 is 4 mm and a width of the dummy conductive portion 131 itself is 0.5 mm, and the actual thickness of the wire to be plated is 6.48 μm. The seventh column shape represents a case where a distance between the wire to be plated and the dummy conductive portion 131 is 4 mm and a width of the dummy conductive portion 131 itself is 1.5 mm, and the actual thickness of the wire to be plated is 6.5 μm. The eighth column shape represents a case where a distance between the wire to be plated and the dummy conductive portion 131 is 8 mm and a width of the dummy conductive portion 131 itself is 0.5 mm, and the actual thickness of the wire to be plated is 5.24 μm.

It can be seen from the above experimental comparison that for the wires to be plated in the first column of processing regions 003 and the wires to be plated in the fourth column of processing regions 003, the actual thickness of the wire to be plated is closest to the theoretical thickness of the wire to be plated in a case where a distance between the wire to be plated and the dummy conductive portion 131 is 4 mm and the width of the dummy conductive portion 131 itself is 1.0 mm.

Furthermore, the first column shape, the second column shape, the third column shape and the fourth column shape each represent the accompanying plating performed in a region with a blank width of 5 cm. The fifth column shape, the sixth column shape, the seventh column shape and the eighth column shape each represent the accompanying plating performed in a region with a blank width of 7 cm. It will be noted that the blank width refers to a width of a region where no metal wire (the signal line 12 and the connection line 15) is provided. It can be seen from the above experimental results that the larger the blank region, the larger the width of the required dummy conductive pattern, and the better the thickness uniformity of the wires to be plated.

For the wires to be plated in the second column of processing regions 003 and the wires to be plated in the third column of processing regions 003, the actual thickness of the wire to be plated is closest to the theoretical thickness of the wire to be plated in a case where a distance between the wire to be plated and the dummy conductive portion 131 is 8 mm and the width of the dummy conductive portion 131 itself is 0.5 mm.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. A wiring substrate, comprising:
a substrate having a first surface;
a plurality of signal lines located on the first surface, wherein the plurality of signal lines are arranged at intervals in a first direction and extend in a second direction; the first direction intersects the second direction; and
a plurality of dummy conductive patterns located on the first surface, wherein at least part of the plurality of dummy conductive patterns are located in a same layer as the plurality of signal lines; a dummy conductive pattern is disposed between two adjacent signal lines, and the dummy conductive pattern is insulated from the two adjacent signal lines.

2. The wiring substrate according to claim 1, further comprising:
a plurality of pad units located on the first surface, a pad unit including multiple device pad groups; and
a plurality of connection lines located on the first surface, wherein the connection lines include first connection lines and second connection lines, the pad unit and a signal line are configured to be connected by a first connection line, and the multiple device pad groups in a same pad unit are configured to be connected by a second connection line; wherein
the plurality of connection lines are arranged in a plurality of columns; in the second direction, the dummy conductive pattern is disposed between two adjacent connection lines in a same column, and the dummy conductive pattern is insulated from the connection lines.

3. The wiring substrate according to claim 2, wherein the second connection line includes a plurality of connection sub-segments, a connection sub-segment is located between two adjacent device pad groups, and the connection sub-segment connects the two adjacent device pad groups; and
at least part of the dummy conductive pattern is located in a region surrounded by a same second connection line.

4. The wiring substrate according to claim 3, wherein the plurality of connection sub-segments include:
a plurality of first connection sub-segments and a second connection sub-segment located between two adjacent first connection sub-segments; the first connection sub-segments extend in the second direction, and the second connection sub-segment extends in the first direction; wherein
in the first direction, the dummy conductive pattern is located between the two adjacent first connection sub-segments of a same second connection line; and/or
in the second direction, the dummy conductive pattern is located between the second connection sub-segment and the first connection line that are adjacent.

5. The wiring substrate according to claim 4, wherein the dummy conductive pattern located between the two adjacent first connection sub-segments of the same second connection line in the first direction includes at least one first dummy conductive portion; the first dummy conductive portion extends in the second direction; and
in the first direction, the two adjacent first connection sub-segments and the first dummy conductive portion are arranged at equal intervals.

6. The wiring substrate according to claim 5, wherein in the first direction, projections of the two adjacent first connection sub-segments and the first dummy conductive portion in the second direction at least partially overlap.

7. The wiring substrate according to claim 4, wherein in the second direction, in a case where the dummy conductive pattern is located between the second connection sub-segment and the first connection line that are adjacent, the second connection sub-segment and the first connection line that are adjacent belong to two adjacent connection lines;
the dummy conductive pattern located between the second connection sub-segment and the first connection line that are adjacent includes at least one second dummy conductive portion; the second dummy conductive portion extends in the second direction; and
in the first direction, the two adjacent signal lines and the second dummy conductive portion are arranged at equal intervals.

8. The wiring substrate according to claim 7, wherein projections of the second dummy conductive portion and the first connection sub-segments in the second direction are at least partially staggered.

9. The wiring substrate according to claim 4, wherein the dummy conductive pattern further includes at least one third dummy conductive portion; the third dummy conductive portion extends in the first direction; the third dummy conductive portion is located between the second connection sub-segment and the first connection line that are adjacent; and the second connection sub-segment and the first connection line that are adjacent belong to two adjacent connection lines in the second direction; and
in the second direction, the second connection sub-segment and the first connection line that are adjacent, and the third dummy conductive portion are arranged at equal intervals.

10. The wiring substrate according to claim 4, wherein the dummy conductive pattern further-includes at least one fourth dummy conductive portion; the fourth dummy conductive portion extends in the first direction; the fourth dummy conductive portion is located between the second connection sub-segment and the first connection line that are adjacent; and the second connection sub-segment and the first connection line that are adjacent belong to a same connection line; and
in the second direction, the second connection sub-segment and the first connection line, and the fourth dummy conductive portion are arranged at equal intervals.

11. The wiring substrate according to claim 2, wherein the dummy conductive pattern includes at least one dummy conductive portion; and the plurality of signal lines, the plurality of connection lines and the dummy conductive portion are disposed in a same layer.

12. The wiring substrate according to claim 11, wherein in the second direction, a plurality of dummy conductive portions are disposed between two adjacent connection lines, and at least two dummy conductive portions are connected.

13. A method for manufacturing a wiring substrate, comprising:
providing a substrate, the substrate having a first surface; and
forming a plurality of signal lines and a plurality of dummy conductive patterns simultaneously on the first surface using a same patterning process, wherein the plurality of signal lines are arranged at intervals in a first direction and extend in a second direction, the first direction intersects the second direction; a dummy conductive pattern is disposed between two adjacent signal lines, and the dummy conductive pattern is insulated from the two adjacent signal lines.

14. The method according to claim 13, wherein forming the plurality of signal lines and the plurality of dummy conductive patterns simultaneously on the first surface using the same patterning process, includes:
forming a seed layer on the first surface;
forming a photoresist layer on the seed layer, wherein the photoresist layer has a plurality of first openings and a plurality of second openings, the first openings correspond to signal lines to be formed, and the second openings correspond to dummy conductive patterns to be formed; and
forming the signal lines in the first openings and the dummy conductive patterns in the second openings simultaneously using an electroplating process.

15. A light-emitting substrate, comprising:
the wiring substrate according to claim 1, and
a plurality of light-emitting devices, the plurality of light-emitting devices being disposed on the wiring substrate.

16. A display apparatus, comprising:
the light-emitting substrate according to claim 15; and
a display panel located on a light-exit side of the light-emitting substrate.

17. The wiring substrate according to claim 1, wherein the wiring substrate has a peripheral region, and the peripheral region includes a first blank region and a second blank region; and
the wiring substrate further comprises a plurality of alignment patterns located on the first surface, and at least part of the plurality of alignment patterns are located in the first blank region and the second blank region.

18. The wiring substrate according to claim 17, wherein the wiring substrate further has a display region, and the peripheral region is located on at least one side of the display region; and
the wiring substrate further comprises an annular electrostatic release line located on the first surface, wherein the annular electrostatic release line includes a first electrostatic release sub-segment, a second electrostatic release sub-segment and a third electrostatic release sub-segment that are electrically connected in sequence; the first electrostatic release sub-segment and the third electrostatic release sub-segment are located at two opposite sides of the display region in the first direction, and the second electrostatic release sub-segment is located on a side of the display region away from the peripheral region.

19. The wiring substrate according to claim 2, wherein the multiple device pad groups in the pad unit are arranged in an array and connected in series and/or in parallel.

20. The wiring substrate according to claim 19, further comprising a plurality of driver chips disposed on the first surface, wherein a driver chip is configured to control at least one pad unit.
